(19) United States
(12) Patent Application Publication
(10) Pub. No.: US 2013/0135594 A1
(43) Pub. Date: May 30, 2013

(54) LIQUID IMMERSION MEMBER, IMMERSION EXPOSURE APPARATUS, EXPOSURE METHOD, DEVICE MANUFACTURING METHOD, PROGRAM, AND RECORDING MEDIUM

(71) Applicant: Nikon Corporation, Tokyo (JP)

(72) Inventor: Shinji SATO, Fukaya-shi (JP)

(73) Assignee: NIKON CORPORATION, Tokyo (JP)

(21) Appl. No.: 13/682,426

(22) Filed: Nov. 20, 2012

Related U.S. Application Data
(60) Provisional application No. 61/563,679, filed on Nov. 25, 2011.

(51) Int. Cl. G03F 7/20

(52) U.S. Cl. CPC G03F 7/70341
USPC 355/30

(57) ABSTRACT

A liquid immersion member including: a first member provided in at least a portion of the surrounding of an optical member, including a first lower surface which can face an object facing the emission surface, and that forms a first immersion space of a first liquid in an optical path space on an emission surface side and at least a portion of a first space on a first lower surface side; a second member provided outside the first member with respect to the optical path, including a second lower surface which can face the object, and that forms a second immersion space of a second liquid in at least a portion of a second space on a second lower surface side; and a third member that restricts the movement of the first liquid from the first to the second space.

### CROSS-REFERENCE TO RELATED APPLICATION

This application is a non-provisional application claiming priority to and the benefit of U.S. Provisional Application No. 61/563,679, filed Nov. 25, 2011. The entire contents of which are incorporated herein by reference.

### BACKGROUND

The present invention relates to a liquid immersion member, an immersion exposure apparatus, an exposure method, a device manufacturing method, a program, and a recording medium. Among exposure apparatuses used in a photolithography process, for example, an immersion exposure apparatus has been known which exposes a substrate with exposure light through a liquid, which is disclosed in United States Patent Application, Publication No. 2009/0046261.

### SUMMARY

In the immersion exposure apparatus, for example, when the liquid flows out from a predetermined space, an exposure defect is likely to occur. As a result, a device is likely to be defective.

An object of aspects of the invention is to provide a liquid immersion member, an immersion exposure apparatus, and an exposure method capable of preventing the occurrence of an exposure defect. In addition, an object of aspects of the invention is to provide a device manufacturing method, a program, and a recording medium capable of preventing a device from being defective.

According to a first aspect of the invention, there is provided a liquid immersion member that is provided in at least a portion of a surrounding of an optical member including an emission surface from which exposure light is emitted in an immersion exposure apparatus. The liquid immersion member comprises: a first member that is provided in at least a portion of the surrounding of the optical member, that includes a first lower surface which can face an object facing the emission surface, and that forms a first immersion space of a first liquid in an optical path space on an emission surface side and at least a portion of a first space on a first lower surface side; a second member that is provided outside the first member with respect to the optical path, that includes a second lower surface which can face the object, and that forms a second immersion space of a second liquid in at least a portion of a second space on a second lower surface side; and a third member that restricts the movement of the first liquid from the first space to the second immersion space.

According to a second aspect of the invention, there is provided a liquid immersion member that is provided in at least a portion of a surrounding of an optical member including an emission surface from which exposure light is emitted in an immersion exposure apparatus. The liquid immersion member comprises: a first member that is provided in at least a portion of the surrounding of the optical member, that includes a first lower surface which can face an object facing the emission surface, and that forms a first immersion space of a first liquid in an optical path space on an emission surface side and at least a portion of a first space on a first lower surface side; a second member that is provided outside the first member with respect to the optical path, that includes a second lower surface which can face the object, and that forms a second immersion space of a second liquid in at least a portion of a second space on a second lower surface side; and a third member that divides the first liquid moved from the first space to the second immersion space.

According to a third aspect of the invention, there is provided a liquid immersion member that is provided in at least a portion of a surrounding of an optical member including an emission surface from which exposure light is emitted in an immersion exposure apparatus. The liquid immersion member comprises: a first member that is provided in at least a portion of the surrounding of the optical member, that includes a first lower surface which can face an object facing the emission surface, and that forms a first immersion space of a first liquid in an optical path space on an emission surface side and at least a portion of a first space on a first lower surface side; a second member that is provided outside the first member with respect to the optical path, that includes a second lower surface which can face the object, and that forms a second immersion space of a second liquid in at least a portion of a second space on a second lower surface side; and a third member including a suction port that suctions the first liquid moved from the first space to the second immersion space.

According to a fourth aspect of the invention, there is provided a liquid immersion member that is provided in at least a portion of a surrounding of an optical member including an emission surface from which exposure light is emitted in an immersion exposure apparatus. The liquid immersion member comprises: a first member that is provided in at least a portion of the surrounding of the optical member, that includes a first lower surface which can face an object facing the emission surface, and that forms a first immersion space of a first liquid in an optical path space on an emission surface side and at least a portion of a first space on a first lower surface side; a second member that is provided outside the first member with respect to the optical path, that includes a second lower surface which can face the object, and that forms a second immersion space of a second liquid in at least a portion of a second space on a second lower surface side; and a third member that captures the first liquid moved from the first space to the second immersion space.

According to a fifth aspect of the invention, there is provided a liquid immersion member that is provided in at least a portion of a surrounding of an optical member including an emission surface from which exposure light is emitted in an immersion exposure apparatus. The liquid immersion member comprises: a first member that is provided in at least a portion of the surrounding of the optical member, that includes a first lower surface which can face an object facing the emission surface, and that forms a first immersion space of a first liquid in an optical path space on an emission surface side and at least a portion of a first space on a first lower surface side; a second member that is provided outside the first member with respect to the optical path, that includes a second lower surface which can face the object, and that forms a second immersion space of a second liquid in at least a portion of a second space on a second lower surface side; and a guide member that guides the first liquid from the first space to the second immersion space.

According to a sixth aspect of the invention, there is provided a liquid immersion member that is provided in at least a portion of a surrounding of an optical member including an emission surface from which exposure light is emitted in an immersion exposure apparatus. The liquid immersion member comprises: a first member that is provided in at least a portion of the surrounding of the optical member, that includes a first lower surface which can face an object facing the emission surface, and that forms a first immersion space of a first liquid in an optical path space on an emission surface side and at least a portion of a first space on a first lower surface side; and a first recovery port that is provided in the first member so as to face an upper surface of the object and recovers the first liquid. The first lower surface includes a first region that is provided in at least a portion of a surrounding of the first recovery port and that faces the upper surface of the object with a first gap therebetween and a second region that is provided outside the first region with respect to the first recovery port and that faces the upper surface of the object with a second gap less than the first gap therebetween.

According to a seventh aspect of the invention, there is provided a liquid immersion member that is provided in at least a portion of a surrounding of an optical member including an emission surface from which exposure light is emitted in an immersion exposure apparatus. The liquid immersion member comprises: a first member that is provided in at least a portion of the surrounding of the optical member, that includes a first lower surface which can face an object facing the emission surface, and that forms a first immersion space of a first liquid in an optical path space on an emission surface side and at least a portion of a first space on a first lower surface side; a second member that is provided outside the first member with respect to the optical path, that includes a second lower surface which can face the object, and that forms a second immersion space of a second liquid in at least a portion of a second space on a second lower surface side; and a second recovery port that is provided in the second member so as to face an upper surface of the object and that recovers the first liquid and/or the second liquid. The second lower surface includes a third region that is provided in at least a portion of a surrounding of the second recovery port and that faces the upper surface of the object with a third gap therebetween and a fourth region that is provided outside the third region with respect to the second recovery port and that faces the upper surface of the object with a fourth gap less than the third gap therebetween.

According to an eighth aspect of the invention, there is provided an immersion exposure apparatus that exposes a substrate with exposure light through a first liquid and comprises the liquid immersion member according to any one of the first to seventh aspects.

According to a ninth aspect of the invention, there is provided a device manufacturing method including: exposing a substrate using the immersion exposure apparatus according to the eighth aspect; and developing the exposed substrate.

According to a tenth aspect of the invention, there is provided an exposure method that exposes a substrate with exposure light through a first liquid which is filled in an optical path of the exposure light between the substrate and an emission surface of an optical member from which the exposure light is emitted in an immersion exposure apparatus. The exposure method includes: forming a first immersion space of a first liquid in an optical path space on an emission surface side and at least a portion of a first space on a first lower surface side, using a first member that is provided in at least a portion of a surrounding of the optical member such that the optical path of the exposure light between the optical member and the substrate is filled with the first liquid and that includes a first lower surface which can face the substrate facing the emission surface; exposing the substrate through the first liquid in the first immersion space; forming a second immersion space of a second liquid in at least a portion of a second space on a second lower surface side, using a second member that is provided outside the first member with respect to the optical path and that includes a second lower surface which can face the substrate; and restricting the movement of the first liquid from the first space to the second immersion space.

According to an eleventh aspect of the invention, there is provided an exposure method that exposes a substrate with exposure light through a first liquid which is filled in an optical path of the exposure light between the substrate and an emission surface of an optical member from which the exposure light is emitted in an immersion exposure apparatus. The exposure method includes: forming a first immersion space of a first liquid in an optical path space on an emission surface side and on at least a portion of a first space on a first lower surface side, using a first member that is provided in at least a portion of a surrounding of the optical member such that the optical path of the exposure light between the optical member and the substrate is filled with the first liquid and that includes a first lower surface which can face the substrate facing the emission surface; exposing the substrate through the first liquid in the first immersion space; forming a second immersion space of a second liquid in at least a portion of a second space on a second lower surface side, using a second member that is provided outside the first member with respect to the optical path and that includes a second lower surface which can face the substrate; and dividing the first liquid moved from the first space to the second immersion space using a third member.

According to a twelfth aspect of the invention, there is provided an exposure method that exposes a substrate with exposure light through a first liquid which is filled in an optical path of the exposure light between the substrate and an emission surface of an optical member from which the exposure light is emitted in an immersion exposure apparatus. The exposure method includes: forming a first immersion space of a first liquid in an optical path space on an emission surface side and on at least a portion of a first space on a first lower surface side, using a first member that is provided in at least a portion of a surrounding of the optical member such that the optical path of the exposure light between the optical member and the substrate is filled with the first liquid and that includes a first lower surface which can face the substrate facing the emission surface; exposing the substrate through the first liquid in the first immersion space; forming a second immersion space of a second liquid in at least a portion of a second space on a second lower surface side, using a second member that is provided outside the first member with respect to the optical path and that includes a second lower surface which can face the substrate; and suctioning the first liquid moved from the first space to the second immersion space from a suction port of a third member.

According to a thirteenth aspect of the invention, there is provided an exposure method that exposes a substrate with exposure light through a first liquid which is filled in an optical path of the exposure light between the substrate and an emission surface of an optical member from which the exposure light is emitted in an immersion exposure apparatus. The exposure method includes: forming a first immersion space of a first liquid in an optical path space on an emission surface side and at least a portion of a first space on a first lower surface side, using a first member that is provided in at least a portion of a surrounding of the optical member such that the optical path of the exposure light between the optical member and the substrate is filled with the first liquid and that includes a first lower surface which can face the substrate facing the emission surface; exposing the substrate through the first liquid in the first immersion space; forming a second immersion space of a second liquid in at least a portion of a second space on a second lower surface side, using a second member that is provided outside the first member with respect to the optical path and that includes a second lower surface which can face the substrate; and capturing the first liquid moved from the first space to the second immersion space using a third member.

According to a fourteenth aspect of the invention, there is provided an exposure method that exposes a substrate with exposure light through a first liquid which is filled in an optical path of the exposure light between the substrate and an emission surface of an optical member from which the exposure light is emitted in an immersion exposure apparatus. The exposure method includes: forming a first immersion space of a first liquid in an optical path space on an emission surface side and at least a portion of a first space on a first lower surface side, using a first member that is provided in at least a portion of a surrounding of the optical member such that the optical path of the exposure light between the optical member and the substrate is filled with the first liquid and that includes a first lower surface which can face the substrate facing the emission surface; exposing the substrate through the first liquid in the first immersion space; forming a second immersion space of a second liquid in at least a portion of a second space on a second lower surface side, using a second member that is provided outside the first member with respect to the optical path and that includes a second lower surface which can face the substrate; and guiding the first liquid moved from the first space to the second immersion space using a guide member.

According to a fifteenth aspect of the invention, there is provided an exposure method that exposes a substrate with exposure light through a first liquid which is filled in an optical path of the exposure light between the substrate and an emission surface of an optical member from which the exposure light is emitted in an immersion exposure apparatus. The exposure method includes: forming a first immersion space of a first liquid in an optical path space on an emission surface side and at least a portion of a first space on a first lower surface side, using a first member that is provided in at least a portion of a surrounding of the optical member such that the optical path of the exposure light between the optical member and the substrate is filled with the first liquid and that includes a first lower surface which can face the substrate facing the emission surface; recovering the first liquid from a first recovery port that is provided in the first member so as to face an upper surface of the object; and exposing the substrate through the first liquid in the first immersion space. The first lower surface includes a first region that is provided in at least a portion of a surrounding of the first recovery port and that faces the upper surface of the object with a first gap therebetween and a second region that is provided outside the first region with respect to the first recovery port and that faces the upper surface of the object with a second gap less than the first gap therebetween.

According to a sixteenth aspect of the invention, there is provided an exposure method that exposes a substrate with exposure light through a first liquid which is filled in an optical path of the exposure light between the substrate and an emission surface of an optical member from which the exposure light is emitted in an immersion exposure apparatus. The exposure method includes: forming a first immersion space of a first liquid in an optical path space on an emission surface side and at least a portion of a first space on a first lower surface side, using a first member that is provided in at least a portion of a surrounding of the optical member such that the optical path of the exposure light between the optical member and the substrate is filled with the first liquid and that includes a first lower surface which can face the substrate facing the emission surface; forming a second immersion space of a second liquid in at least a portion of a second space on a second lower surface side, using a second member that is provided outside the first member with respect to the optical path and that includes a second lower surface which can face the substrate; recovering the first liquid and/or the second liquid from a second recovery port that is provided in the second member so as to face an upper surface of the object; and exposing the substrate through the first liquid in the first immersion space. The second lower surface includes a third region that is provided in at least a portion of a surrounding of the second recovery port and that faces the upper surface of the object with a third gap therebetween and a fourth region that is provided outside the third region with respect to the second recovery port and that faces the upper surface of the object with a fourth gap less than the third gap therebetween.

According to a seventeenth aspect of the invention, there is provided a device manufacturing method including: exposing a substrate using the exposure method according to any one of the tenth to sixteenth aspects; and developing the exposed substrate.

According to an eighteenth aspect of the invention, there is provided a program that causes a computer to control an immersion exposure apparatus that exposes a substrate with exposure light through a first liquid which is filled in an optical path of the exposure light between the substrate and an emission surface of an optical member from which the exposure light is emitted and to perform: forming a first immersion space of a first liquid in an optical path space on an emission surface side and at least a portion of a first space on a first lower surface side, using a first member that is provided in at least a portion of a surrounding of the optical member such that the optical path of the exposure light between the optical member and the substrate is filled with the first liquid and that includes a first lower surface which can face the substrate facing the emission surface; exposing the substrate through the first liquid in the first immersion space; forming a second immersion space of a second liquid in at least a portion of a second space on a second lower surface side, using a second member that is provided outside the first member with respect to the optical path and that includes a second lower surface which can face the substrate; and restricting the movement of the first liquid from the first space to the second immersion space.

According to a nineteenth aspect of the invention, there is provided a program that causes a computer to control an immersion exposure apparatus that exposes a substrate with exposure light through a first liquid which is filled in an optical path of the exposure light between the substrate and an emission surface of an optical member from which the exposure light is emitted and to perform: forming a first immersion space of a first liquid in an optical path space on an emission surface side and at least a portion of a first space on a first lower surface side, using a first member that is provided in at least a portion of a surrounding of the optical member such that the optical path of the exposure light between the optical member and the substrate is filled with the first liquid and that includes a first lower surface which can face the substrate facing the emission surface; exposing the substrate through the first liquid in the first immersion space; forming a second immersion space of a second liquid in at least a portion of a second space on a second lower surface side, using a second member that is provided outside the first member with respect to the optical path and that includes a second lower surface which can face the substrate; and dividing the first liquid moved from the first space to the second immersion space using a third member.

According to a twentieth aspect of the invention, there is provided a program that causes a computer to control an immersion exposure apparatus that exposes a substrate with exposure light through a first liquid which is filled in an optical path of the exposure light between the substrate and an emission surface of an optical member from which the exposure light is emitted and to perform: forming a first immersion space of a first liquid in an optical path space on an emission surface side and at least a portion of a first space on a first lower surface side, using a first member that is provided in at least a portion of a surrounding of the optical member such that the optical path of the exposure light between the optical member and the substrate is filled with the first liquid and that includes a first lower surface which can face the substrate facing the emission surface; exposing the substrate through the first liquid in the first immersion space; forming a second immersion space of a second liquid in at least a portion of a second space on a second lower surface side, using a second member that is provided outside the first member with respect to the optical path and that includes a second lower surface which can face the substrate; and suctioning the first liquid moved from the first space to the second immersion space from a suction port of a third member.

According to twenty-first aspect of the invention, there is provided a program that causes a computer to control an immersion exposure apparatus that exposes a substrate with exposure light through a first liquid which is filled in an optical path of the exposure light between the substrate and an emission surface of an optical member from which the exposure light is emitted and to perform: forming a first immersion space of a first liquid in an optical path space on an emission surface side and at least a portion of a first space on a first lower surface side, using a first member that is provided in at least a portion of a surrounding of the optical member such that the optical path of the exposure light between the optical member and the substrate is filled with the first liquid and that includes a first lower surface which can face the substrate facing the emission surface; exposing the substrate through the first liquid in the first immersion space; forming a second immersion space of a second liquid in at least a portion of a second space on a second lower surface side, using a second member that is provided outside the first member with respect to the optical path and that includes a second lower surface which can face the substrate; and capturing the first liquid moved from the first space to the second immersion space using a third member.

According to twenty-second aspect of the invention, there is provided a program that causes a computer to control an immersion exposure apparatus that exposes a substrate with exposure light through a first liquid which is filled in an optical path of the exposure light between the substrate and an emission surface of an optical member from which the exposure light is emitted and to perform: forming a first immersion space of a first liquid in an optical path space on an emission surface side and at least a portion of a first space on a first lower surface side, using a first member that is provided in at least a portion of a surrounding of the optical member such that the optical path of the exposure light between the optical member and the substrate is filled with the first liquid and that includes a first lower surface which can face the substrate facing the emission surface; exposing the substrate through the first liquid in the first immersion space; forming a second immersion space of a second liquid in at least a portion of a second space on a second lower surface side, using a second member that is provided outside the first member with respect to the optical path and that includes a second lower surface which can face the substrate; and guiding the first liquid moved from the first space to the second immersion space using a guide member.

According to twenty-third aspect of the invention, there is provided a program that causes a computer to control an immersion exposure apparatus that exposes a substrate with exposure light through a first liquid which is filled in an optical path of the exposure light between the substrate and an emission surface of an optical member from which the exposure light is emitted and to perform: forming a first immersion space of a first liquid in an optical path space on an emission surface side and at least a portion of a first space on a first lower surface side, using a first member that is provided in at least a portion of a surrounding of the optical member such that the optical path of the exposure light between the optical member and the substrate is filled with the first liquid and that includes a first lower surface which can face the substrate facing the emission surface; recovering the first liquid from a first recovery port that is provided in the first member so as to face an upper surface of the object; and exposing the substrate through the first liquid in the first immersion space. The first lower surface includes a first region that is provided in at least a portion of a surrounding of the first recovery port and that faces the upper surface of the object with a first gap therebetween and a second region that is provided outside the first region with respect to the first recovery port and that faces the upper surface of the object with a second gap less than the first gap therebetween.

According to twenty-fourth aspect of the invention, there is provided a program that causes a computer to control an immersion exposure apparatus that exposes a substrate with exposure light through a first liquid which is filled in an optical path of the exposure light between the substrate and an emission surface of an optical member from which the exposure light is emitted and to perform: forming a first immersion space of a first liquid in an optical path space on an emission surface side and at least a portion of a first space on a first lower surface side, using a first member that is provided in at least a portion of a surrounding of the optical member such that the optical path of the exposure light between the optical member and the substrate is filled with the first liquid and that includes a first lower surface which can face the substrate facing the emission surface; forming a second immersion space of a second liquid in at least a portion of a second space on a second lower surface side, using a second member that is provided outside the first member with respect to the optical path and that includes a second lower surface which can face the substrate; recovering the first liquid and/or the second liquid from a second recovery port that is provided in the second member so as to face an upper surface of the object; and exposing the substrate through the first liquid in the first immersion space. The second lower surface includes a third region that is provided in at least a portion of a surrounding of the second recovery port and that faces the upper surface of the object with a third gap therebetween and a fourth region that is provided outside the third region with respect to the second recovery port and that faces the upper surface of the object with a fourth gap less than the third gap therebetween.

According to twenty-fifth aspect of the invention, there is provided a computer readable recording medium that stores the program according to any one of the eighteenth to twenty-fourth aspects.

According to the aspects of the invention, it is possible to prevent the occurrence of an exposure defect. In addition, according to the aspects of the invention, it is possible to prevent the occurrence of a defective device.

### BRIEF DESCRIPTION OF THE DRAWINGS

FIG. 1 is a schematic diagram illustrating an example of an exposure apparatus according to a first embodiment.

FIG. 2 is a diagram illustrating an example of a liquid immersion member according to the first embodiment.

FIG. 3 is a diagram illustrating an example of the liquid immersion member according to the first embodiment, as viewed from the lower side.

FIG. 4 is a side cross-sectional view illustrating a portion of the liquid immersion member according to the first embodiment.

FIG. 5 is a diagram schematically illustrating a portion of the liquid immersion member according to the first embodiment.

FIG. 6 is a side cross-sectional view illustrating a portion of the liquid immersion member according to the first embodiment.

FIG. 7 is a schematic diagram illustrating an example of a bridge phenomenon.

FIG. 8 is a side cross-sectional view illustrating a portion of a liquid immersion member according to a second embodiment.

FIG. 9 is a diagram illustrating a portion of the liquid immersion member according to the second embodiment, as viewed from the lower side.

FIG. 10 is a diagram illustrating a portion of a liquid immersion member according to a third embodiment.

FIG. 11 is a diagram illustrating a portion of the liquid immersion member according to the third embodiment.

FIG. 12 is a diagram illustrating a portion of a liquid immersion member according to a fourth embodiment, as viewed from the lower side.

FIG. 13 is a diagram illustrating a portion of the liquid immersion member according to the fourth embodiment, as viewed from the lower side.

FIG. 14 is a diagram illustrating a portion of a liquid immersion member according to a fifth embodiment.

FIG. 15 is a diagram illustrating a portion of a liquid immersion member according to a sixth embodiment.

FIG. 16 is a diagram illustrating a portion of the liquid immersion member according to the sixth embodiment.

FIG. 17 is a diagram illustrating a portion of a liquid immersion member according to a seventh embodiment.

FIG. 18 is a diagram illustrating a portion of a liquid immersion member according to an eighth embodiment.

FIG. 19 is a diagram illustrating a portion of a liquid immersion member according to a ninth embodiment.

FIG. 20 is a diagram illustrating a portion of a liquid immersion member according to a tenth embodiment.

FIG. 21 is a diagram illustrating a portion of a liquid immersion member according to an eleventh embodiment, as viewed from the lower side.

FIG. 22 is a diagram illustrating a portion of a liquid immersion member according to a twelfth embodiment.

FIG. 23 is a diagram illustrating a portion of a liquid immersion member according to a thirteenth embodiment.

FIG. 24 is a diagram illustrating a portion of a liquid immersion member according to a fourteenth embodiment.

FIG. 25 is a diagram illustrating a portion of a liquid immersion member according to a fifteenth embodiment.

FIG. 26 is a diagram illustrating a portion of the liquid immersion member according to the fifteenth embodiment.

FIG. 27 is a diagram illustrating an example of a liquid immersion member according to a sixteenth embodiment.

FIG. 28 is a diagram illustrating an example of a liquid immersion member according to a seventeenth embodiment.

FIG. 29 is a diagram illustrating an example of a liquid immersion member according to an eighteenth embodiment.

FIG. 30 is a flowchart illustrating an example of a process of manufacturing a microdevice.

### DESCRIPTION OF EMBODIMENTS

Hereinafter, embodiments of the invention will be described with reference to the accompanying drawings, but the invention is not limited thereto. In the following description, an XYZ orthogonal coordinate system is set and the positional relationship between portions will be described with reference to the XYZ orthogonal coordinate system. It is assumed that a predetermined direction in the horizontal plane is the X-axis direction, a direction perpendicular to the X-axis direction in the horizontal plane is the Y-axis direction, and a direction (that is, a vertical direction) perpendicular to the X-axis directions and the Y-axis direction is the Z-axis direction. In addition, it is assumed that the rotational (tilt) directions around the X, Y, and Z axes are the OX, OY, and θZ directions, respectively.

### First Embodiment

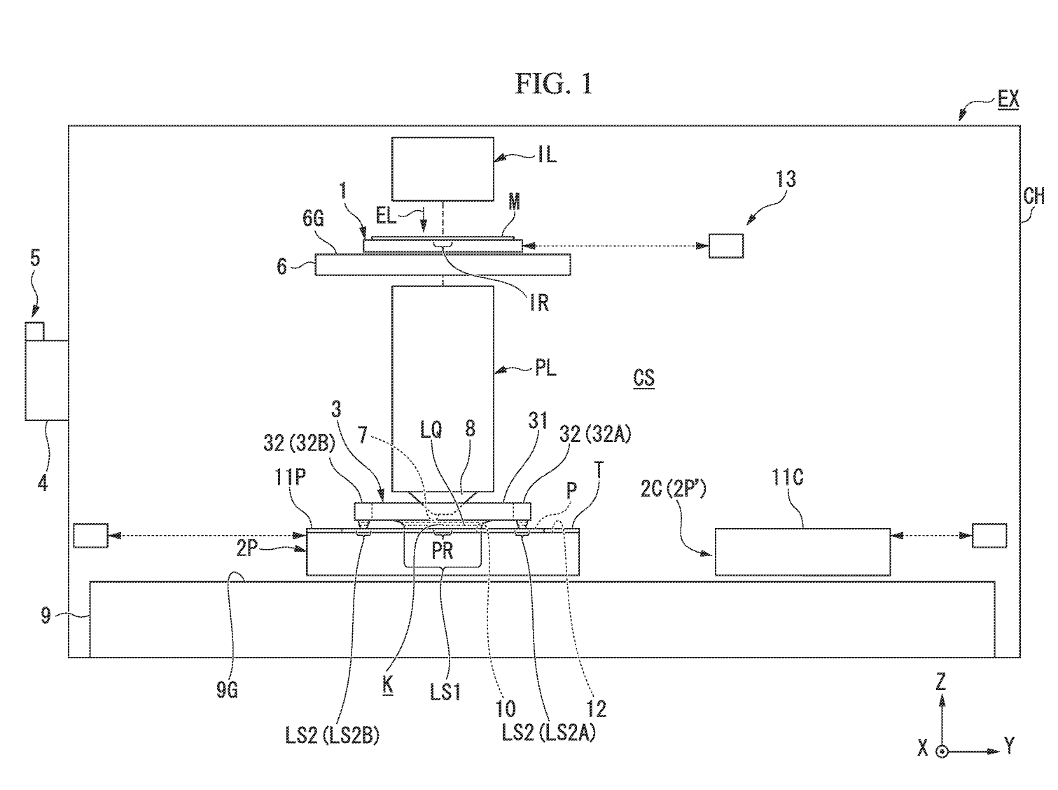

A first embodiment will be described. FIG. 1 is a schematic diagram illustrating an example of an exposure apparatus EX according to the first embodiment. The exposure apparatus EX according to this embodiment is an immersion exposure apparatus that exposes a substrate P with exposure light EL through a liquid LQ. In this embodiment, an immersion space LS1 is formed such that an optical path K of the exposure light EL emitted to the substrate P is filled with the liquid LQ. The term “immersion space” means a portion (a space or a region) that is filled with a liquid. The substrate P is exposed to the exposure light EL which passes through the liquid LQ in the immersion space LS1. In this embodiment, water (pure water) is used as the liquid LQ.

In addition, the exposure apparatus EX according to this embodiment includes a substrate stage and a measurement stage, as disclosed in, for example, the specifications of U.S. Pat. No. 6,897,963 and European Patent Application, Publication No. 1,713,113.

In FIG. 1, the exposure apparatus EX comprises: a mask stage 1 that holds a mask M and that can be moved; a substrate stage 2P that holds the substrate P and that can be moved; a measurement stage 2C that does not hold the substrate P, that has a measurement member and a measurement device for measuring the exposure light EL mounted thereon, and that can be moved; an illumination system IL that illuminates the mask M with the exposure light EL; a projection optical system PL that projects the pattern image of the mask M illuminated with the exposure light EL onto the substrate P; a liquid immersion member 3 that forms the immersion space; a controller 4 that controls the overall operation of the exposure apparatus EX; and a storage device 5 that is connected to the controller 4 and that stores various kinds of information about the exposure. The storage device 5 includes a memory, such as a RAM, a hard disk, and a storage medium, such as a CD-ROM. An operating system (OS) that controls a computer system is installed and a program for controlling the exposure apparatus EX is stored in the storage device 5.

In this embodiment, the immersion space LS1 and an immersion space LS2 (LS2A and LS2B) are formed by the liquid immersion member 3. The immersion space LS1 is formed such that the optical path K of the exposure light EL is filled with the liquid LQ. The immersion space LS2 (LS2A and LS2B) is disposed in a portion of the periphery (surrounding) of the immersion space LS1. In this embodiment, the liquid immersion member 3 includes a first member 31 which forms the immersion space LS1 and a second member 32 (32A and 32B) which forms the immersion space LS2 (LS2A and LS2B).

In addition, the exposure apparatus EX includes a chamber device CH forming an internal space CS in which at least the projection optical system PL, the liquid immersion member 3, the substrate stage 2P, and the measurement stage 2C are arranged. The chamber device CH includes an environmental controller which controls the environment (temperature, humidity, pressure, and the degree of cleanliness) of the internal space CS.

The mask M includes a reticle on which a device pattern to be projected onto the substrate P is formed. The mask M includes a transmissive mask including a transparent plate, such as a glass plate, and a pattern which is made of a shielding material, such as chrome, and is formed on the transparent plate. Furthermore, a reflective mask may be used as the mask M.

The substrate P is used for manufacturing devices. The substrate P includes, for example, a base material, such as a semiconductor wafer, and a photosensitive film which is formed on the base material. The photosensitive film is a film made of a photosensitive material (photoresist). The substrate P may include other films in addition to the photosensitive film. For example, the substrate P may include an antireflection film or a protective film (topcoat film) that protects the photosensitive film.

The illumination system IL emits the exposure light EL to a predetermined illumination region IR. The illumination region IR includes a position which can be irradiated with the exposure light EL emitted from the illumination system IL. The illumination system IL irradiates at least a portion of the mask M disposed in the illumination region IR with the exposure light EL having a uniform illumination distribution. Examples of the exposure light EL emitted from the illumination system IL include deep ultraviolet (DUV) light, such as a bright line (g-line, h-line, or i-line) emitted from, for example, a mercury lamp, and KrF excimer laser light (a wavelength of 248 nm) and vacuum ultraviolet (VUV) light, such as ArF excimer laser light (a wavelength of 193 nm) and F₂ laser light (a wavelength of 157 nm). In this embodiment, ArF excimer laser light, which is ultraviolet light (vacuum ultraviolet light), is used as the exposure light EL.

The mask stage 1 can be moved on a guide surface 6G of a base member 6 including the illumination region IR, with the mask K held thereon. The mask stage 1 is moved by the operation of a driving system including a planar motor which is disclosed in, for example, U.S. Pat. No. 6,452,292. The planar motor includes a moving part which is disposed on the mask stage 1 and a stationary part which is disposed on the base member 6, In this embodiment, the mask stage 1 can be moved in six directions, that is, the X-axis direction, the Y-axis direction, the Z-axis direction, the θX direction, the θY direction, and the θZ direction on the guide surface 6G by the operation of the driving system.

The projection optical system PL emits the exposure light EL to a predetermined projection region PR. The projection region PR includes a position which can be irradiated with the exposure light EL emitted from the projection optical system PL. The projection optical system PL projects the pattern image of the mask M to at least a portion of the substrate P which is disposed in the projection region PR with a predetermined projection magnification. The projection optical system PL according to this embodiment is a reduction system that has a projection magnification of, for example, ¼, ⅕, or ⅛. Furthermore, the projection optical system PL may be a unity magnification system or an enlargement system. In this embodiment, the optical axis of the projection optical system PL is parallel to the Z-axis. In addition, the projection optical system PL may be a dioptric system that does not include catoptric elements, a catoptric system that does not include dioptric elements, or a catadioptric system that includes both catoptric and dioptric elements. In addition, the projection optical system PL may form either an inverted image or an erect image.

The projection optical system PL includes an emission surface 7 from which the exposure light EL is emitted to an imaging plane of the projection optical system PL. The emission surface 7 is provided in a termination optical element 8 which is closest to the imaging plane of the projection optical system PL among a plurality of optical elements of the projection optical system PL. The projection region PR includes a position which can be irradiated with the exposure light EL emitted from the emission surface 7. In addition, in this embodiment, the projection region PR includes a position that faces the emission surface 7. In this embodiment, the emission surface 7 faces the −Z direction and is parallel to the XY plane. Furthermore, the emission surface 7 which faces the −Z direction may be a convex surface or a concave surface. The optical axis of the termination optical element 8 is parallel to the Z-axis. In this embodiment, the exposure light EL emitted from the emission surface 7 travels in the −Z direction.

The substrate stage 2P can be moved on a guide surface 9G of a base member 9 including the projection region PR, while holding the substrate P. The substrate stage 2P is moved by the operation of a driving system including a planar motor which is disclosed in, for example, U.S. Pat. No. 6,452,292. The planar motor includes a moving part which is disposed on the substrate stage 2P and a stationary part which is disposed on the base member 9. In this embodiment, the substrate stage 2P can be moved in six directions, that is, the X-axis direction, the Y-axis direction, the Z-axis direction, the θX direction, the θY direction, and the θZ direction on the guide surface 9G by the operation of the driving system. Furthermore, the driving system that moves the substrate stage 2P may also not include the planar motor. For example, the driving system may include a linear motor.

The substrate stage 2P includes a substrate holding portion 10 which releasably holds the substrate P. The substrate holding portion 10 holds the lower surface (rear surface) of the substrate P such that the upper surface (front surface) of the substrate P faces the +Z direction. In this embodiment, the upper surface of the substrate P held by the substrate holding portion 10 and an upper surface 11P of the substrate stage 2P disposed around the substrate P are arranged in the same plane (they are flush with one other). The upper surface 11P is flat. In this embodiment, the upper surface of the substrate P which is held by the substrate holding portion 10 and the upper surface 11P of the substrate stage 2P are substantially parallel to the XY plane.

Furthermore, the upper surface 11P of the substrate stage 2P and the upper surface of the substrate P held by the substrate holding portion 10 may also not be arranged in the same plane. At least one of the upper surface of the substrate P and the upper surface 11P of the substrate stage 2P may also not be parallel to the XY plane. In addition, the upper surface 11P may also not be flat. For example, the upper surface 11P may include a curved surface.

In this embodiment, the substrate stage 2P includes a cover member holding portion 12 which releasably holds a cover member T, as disclosed in, for example, the specifications of United States Patent Application, Publication No. 2007/0177125 and United States Patent Application, Publication No. 2008/0049209. The cover member holding portion 12 holds the lower surface of the cover member T. In this embodiment, the upper surface 11P of the substrate stage 2P includes the upper surface of the cover member T held by the cover member holding portion 12. Furthermore, the cover member T may also not be releasable. In this case, the cover member holding portion 12 may be omitted. In addition, the upper surface 11P of the substrate stage 2P may include, for example, the surfaces of sensors and measurement members mounted on the substrate stage 2P.

The measurement stage 2C on which the measurement member and the measurement device for measuring the exposure light EL are mounted can be moved on the guide surface 9G of the base member 9 including the projection region PR. The measurement stage 2C is moved by the operation of a driving system including a planar motor which is disclosed in, for example, the specification of U.S. Pat. No. 6,452,292. The planar motor includes a moving part which is disposed on the measurement stage 2C and a stationary part which is disposed on the base member 9. In this embodiment, the measurement stage 2C can be moved in six directions, that is, the X-axis direction, the Y-axis direction axial, the Z-axis direction, the θX direction, the θY direction, and the θZ direction on the guide surface 9G by the operation of the driving system. Furthermore, the driving system that moves the measurement stage 2C may also not include the planar motor. For example, the driving system may include a linear motor.

In this embodiment, the upper surface 11C of the measurement stage 2C is substantially parallel to the XY plane.

In this embodiment, a measurement system 13 measures the positions of the mask stage 1, the substrate stage 2P, and the measurement stage 2C. The measurement system 13 includes at least one of an interferometer system and an encoder system. The interferometer system includes a unit that emits measurement light to a measurement mirror of the mask stage 1 and measures the position of the mask stage 1, and a unit that emits measurement light to a measurement mirror of the substrate stage 2P and a measurement mirror of the measurement stage 2C and measures the positions of the substrate stage 2P and the measurement stage 2C. The encoder system includes an irradiation device that emits measurement light, a light receiving device that receives the measurement light, and an encoder head, as disclosed in, for example, the specification of United States Patent Application, Publication No. 2007/0288121. The irradiation device emits the measurement light to a lattice (a scale or a grid line) of a scale member which is arranged on the substrate stage 2P, the light receiving device receives the measurement light transmitted from the lattice, and the encoder head measures the position of the lattice.

When an exposing process is performed on the substrate P or when a predetermined measurement process is performed, the controller 4 controls the positions of the mask stage 1 (mask M), the substrate stage 2P (substrate P), and the measurement stage 2C (measurement member) on the basis of the measurement result of the measurement system 13,

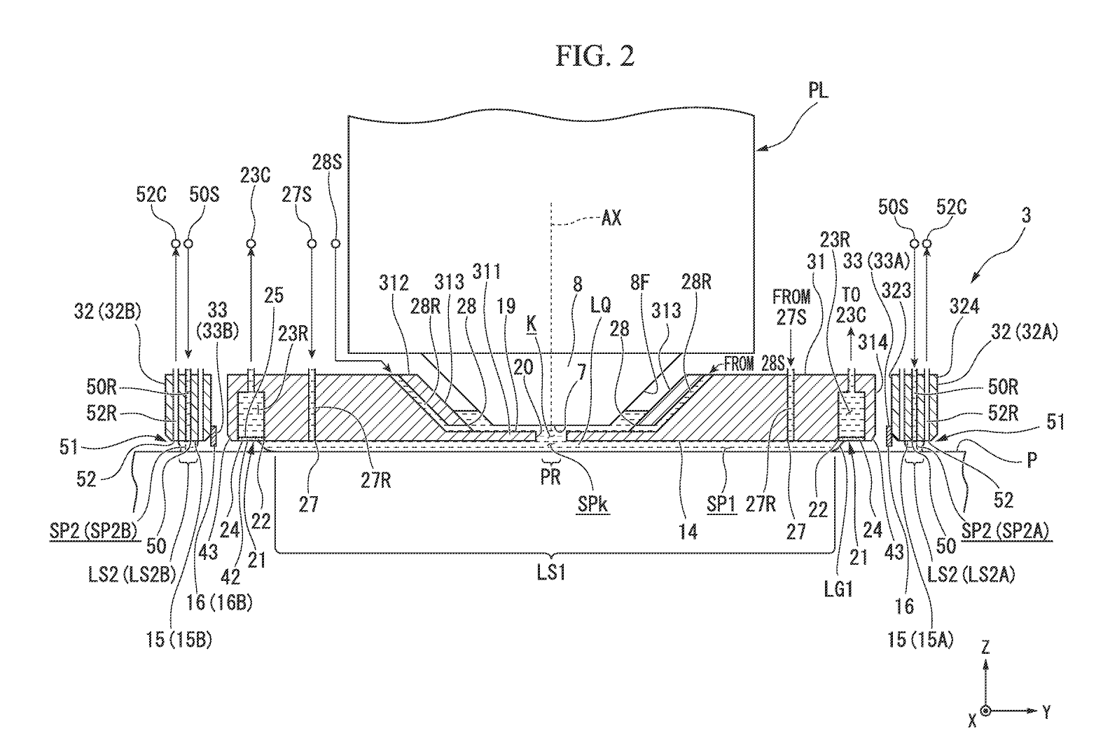

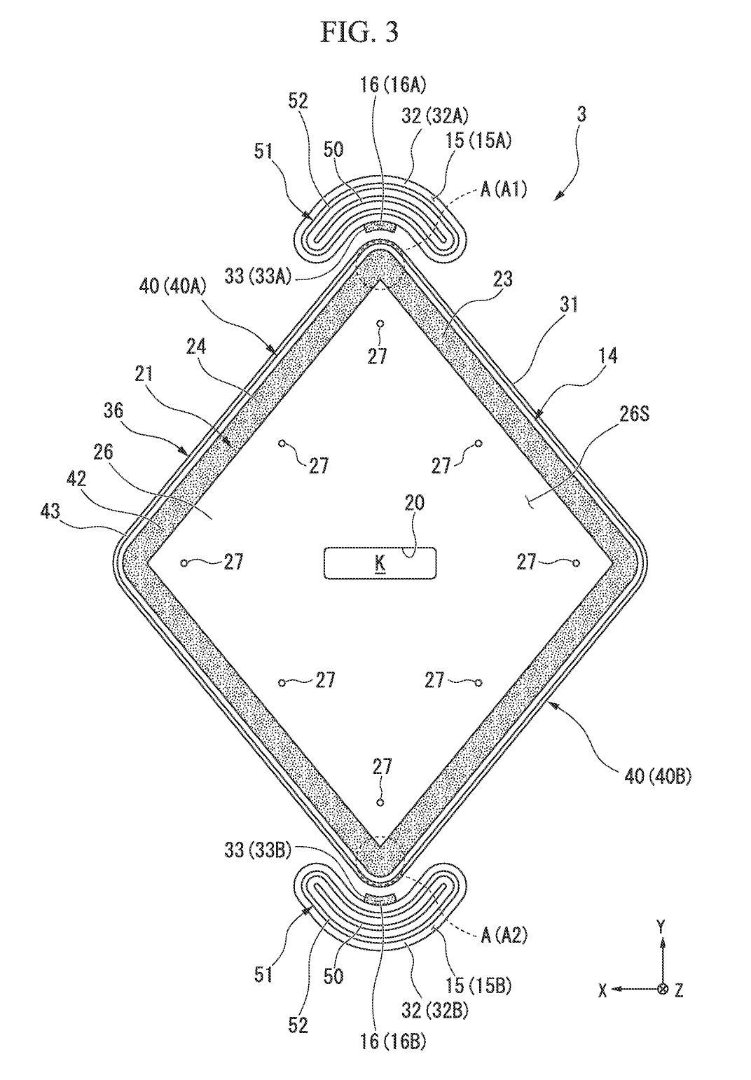

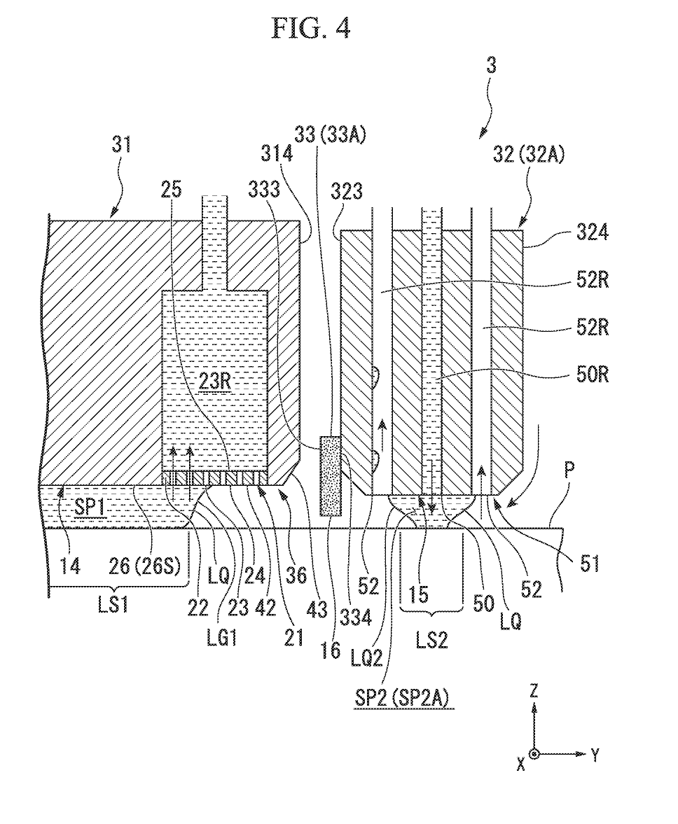

Next, the liquid immersion member 3 according to this embodiment will be described. FIG. 2 is a side cross-sectional view that is parallel to the YZ plane and illustrates an example of the liquid immersion member 3 according to this embodiment. FIG. 3 is a diagram illustrating the liquid immersion member 3, as viewed from the lower side (−Z side). FIG. 4 is a partial enlarged view of FIG. 2.

In this embodiment, the liquid immersion member 3 is arranged in at least a portion of the periphery of the termination optical element 8. Furthermore, in this embodiment, the liquid immersion member 3 is arranged in at least a portion of the periphery of the optical path K of the exposure light EL which passes through the liquid LQ between the termination optical element 8 and an object disposed in the projection region PR.

In this embodiment, the periphery of the optical path K includes a space (region) of the optical path K in the circumferential direction. In other words, the periphery of the optical path K includes an annular space (region) surrounding the optical path K. In this embodiment, a portion of the space around the optical path K means a portion of the annular space surrounding the optical path K. The space around the optical path K means a space around the optical axis (the optical axis AX of the termination optical element 8) of the projection optical system PL. A portion of the space of the optical path K means a portion of the annular space which extends in the circumferential direction of the optical axis AX.

In this embodiment, an object that can be arranged in the projection region PR includes an object which faces the emission surface 7. In this embodiment, the object includes at least one of the substrate stage 2P (cover member T), the substrate P held by the substrate stage 2P (substrate holding portion 10), and the measurement stage 2C. In the exposure of the substrate P, the immersion space LS1 is formed such that the optical path K of the exposure light EL emitted to the substrate P is filled with the liquid LQ. When the substrate P is irradiated with the exposure light EL, the immersion space LS1 is formed such that only a portion of the surface of the substrate P including the projection region PR is immersed in the liquid LQ.

In the following description, it is assumed that the object which faces the emission surface 7 is the substrate P. As described above, the object which faces the emission surface 7 may be at least one of the substrate stage 2P and the measurement stage 2C, or objects other than the substrate P, the substrate stage 2P, and the measurement stage 2C may face the emission surface 7.

In this embodiment, the liquid immersion member 3 comprises: a first member 31 that is arranged in at least a portion of the periphery of the termination optical element 8, that includes a lower surface 14 which can face the substrate P (object), and that forms the immersion space LS1 of the liquid LQ in a space SPk including the optical path K on the side of the emission surface 7 and at least a portion of a space SP1 on the side of the lower surface 14; a second member 32 that is arranged outside the first member 31 with respect to the optical path K (the optical axis AX of the termination optical element 8), that includes a lower surface 15 which can face the substrate P (object), and that forms the immersion space LS2 of the liquid LQ in at least a portion of a space SP2 on the side of the lower surface 15; and a third member 33 that divides the liquid LQ flowing from the space SP1 to the immersion space LS2.

In this embodiment, the space SPk includes a space between the emission surface 7 and the upper surface of the substrate P. The space SP1 includes a space between the lower surface 14 and the upper surface of the substrate P. The space SP2 includes a space between the lower surface 15 and the upper surface of the substrate P.

In this embodiment, the first member 31 is arranged in at least a portion of the periphery of the termination optical element 8. In addition, the first member 31 is arranged in at least a portion of the periphery of the optical path K of the exposure light EL emitted from the emission surface 7. In this embodiment, the first member 31 includes an inner surface 313, at least a portion of which faces a side surface 8F of the termination optical element 8. In this embodiment, the first member 31 includes an outer surface 314, at least a portion of which faces the second member 32. At least a portion of the second member 32 faces the outer surface 314. The outer surface 314 is connected to the outer edge of the lower surface 14.

In this embodiment, the first member 31 is an annular member. In this embodiment, a portion of the first member 31 is arranged around the termination optical element 8. In this embodiment, a portion of the first member 31 is arranged around the optical path K of the exposure light EL between the termination optical element 8 and the substrate P.

The first member 31 may also not be an annular member. For example, the first member 31 may be provided in a portion of the periphery of the termination optical element 8 and the optical path K. In addition, the first member 31 may also not be arranged in at least a portion of the periphery of the termination optical element 8. For example, the first member 31 may be arranged in at least a portion of the periphery of the optical path K between the emission surface 7 and the substrate P and may also not be arranged around the termination optical element 8. The first member 31 may also not be arranged in at least a portion of the periphery of the optical path K between the emission surface 7 and the substrate P. For example, the first member 31 may be arranged in at least a portion of the periphery of the termination optical element 8 and may also not be arranged around the optical path K between the emission surface 7 and the object.

The liquid LQ can be held between the termination optical element 8 and the substrate P. The liquid LQ can be held between the substrate P and the emission surface 7 facing the substrate P. The liquid LQ can be held between the first member 31 and the substrate P. The liquid LQ can be held between the substrate P and the lower surface 14 facing the substrate P. The immersion space LS1 is formed by the liquid LQ held between the substrate P, and the termination optical element 8 and the first member 31. The immersion space LS1 is formed by the liquid LQ which is held between one side, that is, the emission surface 7 and the lower surface 14, and the other side, that is, the upper surface of the substrate P such that the optical path K of the exposure light EL between the termination optical element 8 and the substrate P is filled with the liquid LQ.

The first member 31 forms the immersion space LS1 of the liquid LQ in the space SPk on the side of the emission surface 7 such that the optical path K is filled with the liquid LQ. In addition, in this embodiment, the first member 31 forms the immersion space LS1 of the liquid LQ in at least a portion of the space SP1 on the side of the lower surface 14.

For example, in the exposure of the substrate P, the first member 31 forms the immersion space LS1 such that the optical path K of the exposure light EL emitted to the substrate P is filled with the liquid LQ. When the exposure light EL is emitted to the substrate P, the immersion space LS1 is formed such that a portion of the surface of the substrate P including the projection region PR is covered with the liquid LQ.

In this embodiment, at least a portion of the interface (a meniscus or an edge) LG1 of the liquid LQ in the immersion space LS1 is formed between the lower surface 14 and the upper surface of the substrate P. That is, the exposure apparatus EX according to this embodiment uses a so-called local liquid immersion method. A gas space is disposed outside the immersion space LS1 (outside the interface LG1).

In this embodiment, the first member 31 includes an opposite portion 311 at least a part of which faces the emission surface 7 and a main portion 312 at least a part of which faces the side surface 8F of the termination optical element 8. The side surface 8F is arranged around the emission surface 7. The exposure light EL is not emitted from the side surface 8F. In this embodiment, the side surface 8F is inclined upward to the outside with respect to the radiation direction for the optical path K. In addition, the radiation direction for the optical path K includes a radiation direction for the optical axis AX of the termination optical element 8 and a direction perpendicular to the Z-axis.

In this embodiment, the first member 31 includes an upper surface 19 at least a portion of which faces the emission surface 7. The upper surface 19 is arranged in the opposite portion 311. In addition, the first member 31 includes a hole (opening) 20 which faces the emission surface 7. The exposure light EL emitted from the emission surface 7 can be irradiated to the substrate P through the opening 20. The upper surface 19 is arranged around the upper end of the opening 20. The lower surface 14 is arranged around the lower end of the opening 20. The opening 20 is formed so as to connect the upper surface 19 and the lower surface 14. In this embodiment, the upper surface 19 may be substantially perpendicular to the optical axis AX or it may be inclined with respect to a plane perpendicular to the optical axis AX. For example, the upper surface 19 may be inclined upward to the outside with respect to the radiation direction for the optical axis AX.

The second member 32 is arranged outside the first member 31 with respect to the optical path K. In this embodiment, the first member 31 and the second member 32 are different from each other. The second member 32 is arranged in a portion of the periphery of the first member 31. The second member 32 is arranged such that at least a portion thereof faces the outer surface 314 of the first member 31. In this embodiment, the second member 32 includes an inner surface 323 at least a portion of which faces the outer surface 314, and an outer surface 324.

In this embodiment, the second member 32 is arranged in a portion of the annular space facing the outer surface 314 of the first member 31. In other words, the second member 32 is arranged so as to face the outer surface 314 of the first member 31 in a portion of the space around the optical path K (first member 31).

The liquid LQ can be held between the second member 32 and the substrate P. The liquid LQ can be held between the substrate P and the lower surface 15 facing the substrate P. The immersion space LS2 is formed by the liquid LQ held between the second member 32 and the substrate P. The immersion space LS2 is formed in a portion of the periphery of the immersion space LS1 by the liquid LQ held between the lower surface 15, which is one side, and the upper surface of the substrate P, which is the other side. In this embodiment, the immersion space LS2 is formed in a portion of the annular space facing the interface LG1 of the immersion space LS1. In other words, the immersion space LS2 is formed so as to face the interface LG1 of the immersion space LS1 in a portion of the space around the optical path K (immersion space LS1).

In this embodiment, two second members 32 are arranged in the space around the first member 31. In the following description, of the two second members 32, one second member 32 is appropriately referred to as a second member 32A and the other second member 32 is appropriately referred to as a second member 3213. In addition, the lower surface 15 of the second member 32A is appropriately referred to as a lower surface 15A and the lower surface 15 of the second member 32B is appropriately referred to as a lower surface 15B. In addition, the space SP2 formed between the lower surface 15A of the second member 32A and the upper surface of the substrate P (object) is appropriately referred to as a space SP2A and the space SP2 formed between the lower surface 15B of the second member 32B and the upper surface of the substrate P is appropriately referred to as a space SP2B.

In this embodiment, the second member 32A is opposite to the second member 32B with the optical path K interposed therebetween. In this embodiment, the second member 32A is arranged on the +Y side of the first member 31. The second member 3213 is arranged on the −Y side of the first member 31.

In this embodiment, the immersion space LS1 is formed by the first member 31. The immersion space LS1 is formed in the space SPk and at least a portion of the space SP1. The immersion space LS2A is formed by the second member 32A. The immersion space LS2A is formed in at least a portion of the space SP2A. The immersion space LS2B is formed by the second member 32B. The immersion space LS2B is formed in at least a portion of the space SP2B.

In this embodiment, the first member 31 and the second member 32A are separated from each other. The first member 31 and the second member 32B are separated from each other. The second member 32A and the second member 32B are separated from each other. In this embodiment, the immersion space LS1 and the immersion space LS2A are formed so as to be substantially separated from each other. In this embodiment, the immersion space LS1 and the immersion space LS2B are formed so as to be substantially separated from each other. In this embodiment, the immersion space LS2A and the immersion space LS2B are formed so as to be substantially separated from each other. For example, when the object facing the liquid immersion member 3 is stationary, the immersion space LS1, the immersion space LS2A, and the immersion space LS2B are formed so as to be separated from one another.

In this embodiment, the immersion space LS2 (LS2A and LS2B) is smaller than the immersion space LS1. In this embodiment, the immersion space LS2A and the immersion space LS2B have substantially the same size. The size of the immersion space includes the volume of the liquid forming the immersion space. In addition, the size of the immersion space includes the weight of the liquid forming the immersion space. The size of the immersion space includes, for example, the area of the immersion space in the plane (XY plane) parallel to the front surface (upper surface) of the substrate P. In addition, the size of the immersion space includes, for example, the dimensions of the immersion space in a predetermined direction (for example, the X-axis direction or the Y-axis direction) in the plane (XY plane) parallel to the front surface (upper surface) of the substrate P. In this embodiment, in the plane (XY plane) parallel to the front surface (upper surface) of the substrate P, the immersion space LS2 (LS2A and LS2B) is smaller than the immersion space LS1. The immersion space LS2A may be larger or smaller than the immersion space LS2B.

The third member 33 is different from the first member 31 and the second member 32. The third member 33 includes a lower surface 16 which can face the upper surface of the substrate P. The liquid LQ is not held between the third member 33 and the substrate P. The third member 33 includes an inner surface 333 at least a portion of which faces the outer surface 314, and an outer surface 334 at least a portion of which faces the inner surface 323.

The third member 33 is arranged between the first member 31 and the second member 32. The third member 33 is arranged between the immersion space LS1 and the immersion space LS2. The third member 33 is arranged so as to contact the liquid LQ between the first member 31 and the second member 32 (between the space SP1 and the space SP2).

In this embodiment, the lower surface 16 of the third member 33 is arranged closer to the substrate P than the lower surface 14 of the first member 31. That is, the distance between the lower surface 16 and the upper surface of the substrate P is less than that between the lower surface 14 and the upper surface of the substrate P. In other words, the lower surface 16 is arranged below (on the −Z side of) the lower surface 14.

In this embodiment, the lower surface 16 of the third member 33 is arranged closer to the substrate P than the lower surface 15 of the second member 32. That is, the distance between the lower surface 16 and the upper surface of the substrate P is less than that between the lower surface 15 and the upper surface of the substrate P. In other words, the lower surface 16 is arranged below (on the −Z side of) the lower surface 15 in the Z-axis direction. That is, in this embodiment, among the lower surface 14, the lower surface 15, and the lower surface 16, the lower surface 16 is the lowest.

In this embodiment, in the Z-axis direction, the lower surface 14 of the first member 31 is arranged substantially at the same position (height) as that of the lower surface 15 of the second member 32. In other words, the distance between the lower surface 14 and the upper surface of the substrate P is substantially equal to that between the lower surface 15 and the upper surface of the substrate P. The lower surface 15 of the second member 32 may be arranged below (on the −Z side of) or above (on the +Z side of) the lower surface 14 of the first member 31.

In this embodiment, at least a portion of the lower surface 14 is substantially parallel to the XY plane. In this embodiment, at least a portion of the lower surface 15 is substantially parallel to the XY plane. In addition, in this embodiment, at least a portion of the lower surface 16 is substantially parallel to the XY plane.

At least a portion of the lower surface 14 may be inclined with respect to the XY plane or it may include a curved surface. At least a portion of the lower surface 15 may be inclined with respect to the XY plane or it may include a curved surface. At least a portion of the lower surface 16 may be inclined with respect to the XY plane or it may include a curved surface.

In this embodiment, the lower surface 14 and the lower surface 15A are disposed at different positions (heights) in the Z-axis direction. For example, as shown in FIG. 4, the lower surface 15A may be lower or higher than the lower surface 14. That is, the distance between the lower surface 14 and the surface of the object may be more or less than that between the lower surface 15A and the surface of the object. In addition, the lower surface 15B may be lower or higher than the lower surface 14.

The height of the lower surface 14 may be substantially equal to that of the lower surface 15A. The height of the lower surface 14 may be substantially equal to that of the lower surface 15B. The height of the lower surface 14, the height of the lower surface 15A, and the height of the lower surface 15B may be substantially equal to one another. That is, the distance between the lower surface 14 and the surface of the object, the distance between the lower surface 15A and the surface of the object, and the distance between the lower surface 15B and the surface of the object may be substantially equal to one another.

In this embodiment, the lower surface 14 has a substantially rectangular shape in the XY plane which is substantially parallel to the upper surface of the substrate P (object). For example, as shown in FIG. 3, in this embodiment, the corners (vertexes) of the rectangular lower surface 14 are rounded. In this embodiment, the corners of the lower surface 14 are arranged on the +Y, −Y, +X, and −X sides of the optical path K.

In this embodiment, the lower surface 15A is arranged along the corner of the lower surface 14 on the +Y side in the XY plane. The lower surface 15B is arranged along the corner of the lower surface 14 on the −Y side.

In this embodiment, two third members 33 are arranged in the space around the first member 31. In the following description, of the two third members 33, one third member 33 is appropriately referred to as a third member 33A and the other third member 33 is appropriately referred to as a third member 33B. In addition, the lower surface 16 of the third member 33A is appropriately referred to as a lower surface 16A and the lower surface 16 of the third member 3313 is appropriately referred to as a lower surface 16B.

In this embodiment, the third member 33A is opposite to the third member 33B with the optical path K interposed therebetween. In this embodiment, the third member 33A is arranged on the +Y side of the first member 31. The third member 3313 is arranged on the −Y side of the first member 31. In this embodiment, the third member 33A is arranged between the first member 31 and the second member 32A. The third member 33B is arranged between the first member 31 and the second member 32B.

In this embodiment, in the XY plane, the lower surface 16A is arranged on the corner of the lower surface 14 on the +Y side between the corner on the +Y side and the lower surface 15A. The lower surface 15B is arranged on the corner of the lower surface 14 on the −Y side between the corner on the −Y side and the lower surface 1513.

In this embodiment, the third member 33 includes a porous member. In this embodiment, the third member 33 includes a porous member made of, for example, titanium. The porous member 33 can be formed using, for example, a sintering method.

In this embodiment, at least a portion of the third member 33 repels the liquid LQ. In this embodiment, the contact angle of the surface of the third member 33 with respect to the liquid LQ is greater than, for example, 90 degrees. The contact angle of the surface of the third member 33 with respect to the liquid LQ may be equal to or greater than, for example, 100 degrees, or it may be equal to or greater than 110 degrees.

In this embodiment, a liquid-repellant material including fluorine is coated on at least a portion of the surface of the third member 33. That is, a film including the liquid-repellant material is arranged on at least a portion of the surface of the third member 33. The liquid-repellant material may be, for example, PFA (tetra fluoro ethylene-perfluoro alkylvinyl ether copolymer), PTFE (poly tetra fluoro ethylene), PEEK (polyetheretherketone), or Teflon (registered trademark). In addition, the third member 33 may be made of a liquid-repellant material including fluorine.

The surface of the third member 33 may be lyophilic to the liquid LQ. For example, the contact angle of the surface of the third member 33 with respect to the liquid LQ may be less than 90 degrees or it may be equal to or less than 80 degrees or 70 degrees.

In this embodiment, the third member 33 is supported by the second member 32. In this embodiment, at least a portion of the third member 33 is connected to the inner surface 323 of the second member 32. The third member 33 may be supported by the first member 31 so as to be arranged between the first member 31 and the second member 32. In addition, the third member 33 may be supported by members other than the first member 31 and the second member 32 so as to be arranged between the first member 31 and the second member 32.

In this embodiment, the exposure apparatus EX comprises a supporting member (not shown) that supports the first member 31 and the second member 32. In this embodiment, the first member 31 and the second member 32 are supported by one supporting member (frame member). The supporting member may be connected to a supporting mechanism that supports the projection optical system PL. The supporting member may be separated from the supporting mechanism that supports the projection optical system PL. The first member 31 and the second member 32 may be supported by different supporting members.

In this embodiment, the first member 31 includes a liquid recovery portion 21 that is arranged so as to face the upper surface of the substrate P (object) and can recover (suction) the liquid LQ.

In this embodiment, the main portion 312 includes an internal space 23R having an opening 22 at the lower end. The first member 31 includes a porous member 24 that is provided in the opening 22. The opening 22 is formed so as to face the space SP1. The porous member 24 is arranged so as to face the space SP1. The porous member 24 includes a plurality of holes (openings or pores) through which the liquid LQ can pass. The porous member 24 includes, for example, a mesh filter. The mesh filter is a porous member in which a plurality of small holes are formed in a mesh shape.

The liquid recovery portion 21 includes at least a portion of a lower surface 42 of the porous member 24 which is arranged so as to face the upper surface of the substrate P (object). In this embodiment, the porous member 24 is a plate-shaped member. The porous member 24 includes the lower surface 42 which faces the space SP1, an upper surface 25 that faces the internal space 23R, and a plurality of holes which are formed so as to connect the upper surface 25 and the lower surface 42. The liquid recovery portion 21 can recover the liquid LQ (liquid LQ in the space SP1) on the substrate P (object) facing the lower surface 42 through the holes of the porous member 24. In this embodiment, the plurality of holes of the porous member 24 function as recovery ports 23 which can recover the liquid LQ in the space SP1. In this embodiment, the lower surface 42 functions as a recovery surface in which the recovery ports 23 for recovering the liquid LQ are formed. The liquid LQ recovered through the holes (recovery ports 23) of the porous member 24 flows through the internal space (recovery passageway) 23R.

In this embodiment, only the liquid LQ is substantially recovered through the porous member 24 and the recovery of gas is restricted. The controller 4 adjusts the difference between pressure (the pressure of the space SP1) on the side of the lower surface 42 of the porous member 24 and pressure (the pressure of the recovery passageway 23R) on the side of the upper surface 25 such that the liquid LQ in the space SP1 flows to the recovery passageway 23R through the holes of the porous member 24 and gas does not pass through the holes of the porous member 24. An example of a technology for recovering only the liquid which has passed through the porous member is disclosed in, for example, the specification of U.S. Pat. No. 7,292,313.

Both the liquid LQ and gas may be recovered (suctioned) through the porous member 24.

In this embodiment, the first member 31 includes a flat portion 26S that is arranged so as to face the upper surface of the substrate P and is adjacent to the liquid recovery portion 21.

In this embodiment, the flat portion 26S includes a lower surface 26 that is arranged adjacent to the lower surface 42 of the porous member 22. At least a portion of the lower surface 26 is flat. The lower surface 26 cannot transmit the liquid LQ and the liquid LQ can be held between the lower surface 26 and the substrate P.

In this embodiment, the first member 31 includes an inclined plane 43 that is arranged outside the lower surface 42 with respect to the optical path K. The inclined plane 43 is arranged outside the lower surface 42 with respect to the optical path K so as to face the space SP1. The inclined plane 43 is inclined upward toward the outside in the radiation direction for the optical path K (optical axis AX).

In this embodiment, the lower surface 14 of the first member 31 includes the lower surface 26, the lower surface 42 of the porous member 24, and the inclined plane 43.

In this embodiment, the lower surface 26 and the lower surface 42 are lyophilic to the liquid LQ. In this embodiment, the contact angle of the lower surface 26 and the lower surface 42 with respect to the liquid LQ is equal to or less than, for example, 90 degrees. In addition, the contact angle of the lower surface 26 and the lower surface 42 with respect to the liquid LQ may be equal to or less than, for example, 80 degrees or 70 degrees. In this embodiment, the lower surface 26 and the lower surface 42 include, for example, a titanium surface.

In this embodiment, the inclined plane 43 repels the liquid LQ. In this embodiment, the contact angle of the inclined plane 43 with respect to the liquid LQ is greater than, for example, 90 degrees. In addition, the contact angle of the inclined plane 43 with respect to the liquid LQ may be equal to or greater than 100 degrees or 110 degrees. In this embodiment, the inclined plane 43 includes a film made of a liquid-repellant material, such as fluorine. The liquid-repellant material may be, for example, PFA (Tetra fluoro ethylene-perfluoro alkylvinyl ether copolymer), PTFE (Poly tetra fluoro ethylene), PEEK (polyetheretherketone), or Teflon (registered trademark).

In this embodiment, at least a part of the liquid recovery portion 21 is arranged in a circumferential portion 36 of the first member 31. In this embodiment, the circumferential portion 36 includes the lower surface 42 of the porous member 24. In addition, in this embodiment, the circumferential portion 36 includes the inclined plane 43. In this embodiment, the edge 41 of the first member 31 includes the edge of the circumferential portion 36. In addition, the edge 41 of the first member 31 includes the edge of the lower surface 14. The edge of the lower surface 14 includes the edge of the lower surface 42 of the porous member 24. In addition, the edge of the lower surface 14 includes the edge of the inclined plane 43.

In this embodiment, the lower surface 26 is arranged closer to the optical path K than the lower surface 42. In this embodiment, the lower surface 42 is arranged in at least a portion of the periphery of the lower surface 26. In this embodiment, the lower surface 26 is arranged around the lower end of the opening 20. The lower surface 42 is arranged around the lower surface 26.

In this embodiment, the first member 31 comprises a supply port 27 that is provided so as to face the upper surface of the substrate P (object) and can supply the liquid LQ. The supply port 27 is arranged in at least a portion of the lower surface 14 of the first member 31 so as to face the space SP1. In this embodiment, the supply port 27 can supply the liquid LQ to the space SP1. The supply port 27 may also not be provided.

In this embodiment, the supply port 27 is provided in the lower surface 26. The lower surface 26 is arranged around the supply port 27. In this embodiment, a plurality of supply ports 27 are provided around the optical path K (opening 20). The liquid recovery portion 21 is arranged outside the supply port 27 in the radiation direction for the optical path K. In this embodiment, the supply port 27 is arranged adjacent to the liquid recovery portion 21. The plurality of supply ports 27 are arranged along the inner edge of the lower surface 42 of the porous member 24.

In addition, the first member 31 includes a supply port 28 that can supply the liquid LQ. The supply port 28 is provided in at least a portion of the inner surface 313 of the first member 31 so as to face the space SPk which faces the emission surface 7. In this embodiment, the supply port 28 can supply the liquid LQ to the space SPk. The space SPk includes a space between the emission surface 7 and the upper surface 19. In this embodiment, a plurality of supply ports 28 are provided around the optical path K (space SPk). In addition, the supply port 28 may be provided so as to face the side surface 8F of the termination optical element 8.

The supply port 28 is connected to a liquid supply device 28S that can supply the liquid LQ through a supply passageway 28R formed in the first member 31. The liquid supply device 28S can supply the liquid LQ which is clean and whose temperature has been adjusted. The supply port 28 supplies the liquid LQ from the liquid supply device 28S to the space SPk. At least a portion of the liquid LQ supplied from the supply port 28 to the space SPk flows to the space SP1 through the opening 20.

The supply port 27 is connected to the liquid supply device 27S which can supply the liquid LQ through the supply passageway 27R formed in the first member 31. The liquid supply device 27S can supply the liquid LQ which is clean and whose temperature has been adjusted. The supply port 27 supplies the liquid LQ from the liquid supply device 27S to the space SP1.

At least a portion of the liquid LQ in the space SP1 is recovered from the holes of the porous member 24. As described above, in this embodiment, the holes of the porous member 24 function as the recovery ports 23 which can recover the liquid LQ in the space SP1. The recovery ports 23 are connected to a liquid recovery device 23C which can recover (suction) the liquid LQ through the recovery passageway 23R formed in the first member 31. The liquid recovery device 23C includes, for example, a vacuum system and can recover (suction) the liquid LQ.

The liquid supply device 27S, the liquid supply device 28S, and the liquid recovery device 23C are controlled by the controller 4. In this embodiment, the liquid LQ is recovered from the recovery ports 23 in parallel with the supply of the liquid LQ from the supply port 28. In this way, the immersion space LS1 is formed by the liquid LQ between the termination optical element 8 and the first member 31 which are arranged on one side and the substrate P which is arranged on the other side. In addition, in this embodiment, the supply of the liquid LQ from the supply port 28 is performed in parallel with the recovery of the liquid LQ from the recovery ports 23 and the supply of the liquid LQ from the supply port 27. In this embodiment, the immersion space LS1 is formed by the liquid LQ supplied from the supply port 28. In addition, in this embodiment, the immersion space LS1 is formed by the liquid LQ supplied from the supply port 27.

The second member 32 (32A and 32B) comprises a supply port 50 which can supply the liquid LQ. In this embodiment, the supply port 50 can face the upper surface of the substrate P (object). The supply port 50 is provided in at least a portion of the lower surface 15 of the second member 32 so as to face the space SP2. In this embodiment, the supply port 50 can supply the liquid LQ to the space SP2.

The second member 32 includes a fluid recovery portion 51 that can recover a fluid. The fluid includes at least one of a liquid and gas. In this embodiment, the fluid recovery portion 51 can face the upper surface of the substrate P (object). The fluid recovery portion 51 is provided in at least a portion of the lower surface 15 of the second member 32 so as to face the space SP2. In this embodiment, the fluid recovery portion 51 can recover the liquid LQ in the space SP2. In addition, the fluid recovery portion 51 can recover gas in the space SP2. In this embodiment, the fluid recovery portion 51 includes a recovery port 52 that is provided in at least a portion of the lower surface 15 so as to face the space SP2.

In this embodiment, at least a part of the fluid recovery portion 51 (recovery port 52) is arranged outside the first member 31 in the radiation direction for the optical path K. In this embodiment, at least a part of the fluid recovery portion 51 (recovery port 52) is arranged between the first member 31 and the supply port 50.

In this embodiment, at least a part of the fluid recovery portion 51 (recovery port 52) is arranged outside the supply port 50 with respect to the first member 31. In this embodiment, at least a part of the fluid recovery portion 51 (recovery port 52) is arranged outside the supply port 50 in the radiation direction for the optical path K.

In this embodiment, the fluid recovery portion 51 (recovery port 52) is provided so as to surround the supply port 50.

In this embodiment, the supply port 50 has a slit shape. The recovery port 52 between the first member 31 and the supply port 50 has a slit shape which is substantially parallel to the supply port 50. The recovery port 52 arranged outside the supply port 50 with respect to the first member 31 has a slit shape which is substantially parallel to the supply port 50.

A plurality of recovery port 52 may be provided around the supply port 50. That is, a plurality of recovery port 52 may be discretely arranged around the supply port 50.

The supply port 50 is connected to the liquid supply device 50S which can supply the liquid LQ through the supply passageway 50R formed in the second member 32. The liquid supply device 50S can supply the liquid LQ which is clean and whose temperature has been adjusted. The supply port 50 supplies the liquid LQ from the liquid supply device 50S to the space SP2.

At least a portion of the liquid LQ in the space SP2 is recovered from the fluid recovery portion 51 (recovery port 52). The fluid recovery portion 51 (recovery port 52) of the second member 32 can recover the liquid LQ from the space SP1 between the first member 31 and the object.

The recovery port 52 is connected to the liquid recovery device 52C which can recover (suction) the liquid LQ through the recovery passageway 52R formed in the second member 32. The liquid recovery device 52C includes, for example, a vacuum system and can recover (suction) the liquid LQ. In addition, the recovery port 52 can recover gas in the space SP2.

The liquid supply device 50S and the liquid recovery device 52C are controlled by the controller 4. In this embodiment, the liquid LQ is supplied from the supply port 50. In this way, the immersion space LS2 is formed by the liquid LQ between the second member 32 which is arranged on one side and the substrate P which is arranged on the other side. That is, in this embodiment, the immersion space LS2 is formed by the liquid LQ supplied from the supply port 50. In this embodiment, the liquid LQ is recovered from the recovery port 52 in parallel with the supply of the liquid LQ from the supply port 50 to form the immersion space LS2.

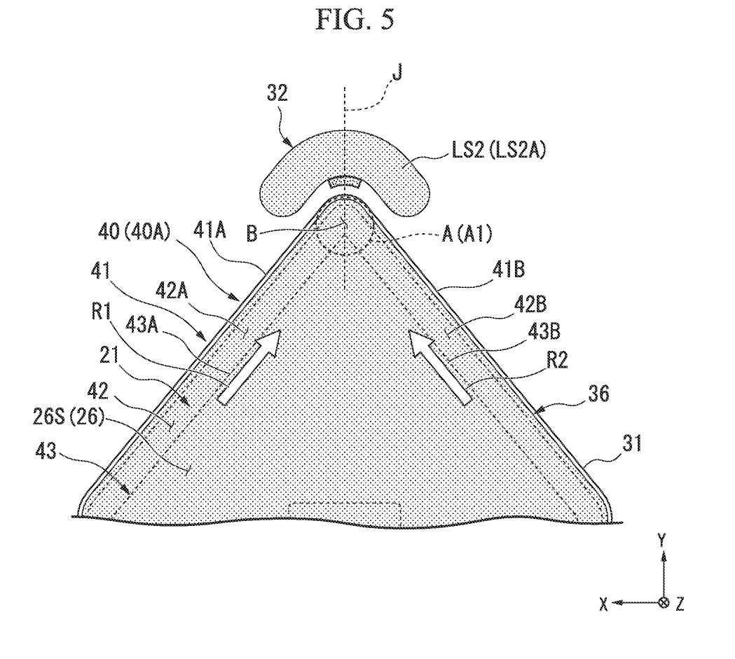

FIG. 5 is a schematic diagram illustrating the first member 31, the second member 32 (32A), the third member 33 (33A), a portion of the immersion space LS1, and the immersion space LS2 (LS2A), as viewed from the lower side. In this embodiment, the second member 32A and the second member 32B have substantially the same structure. The third member 33A and the third member 33B have substantially the same structure. Next, the second member 32 (32A), the third member 33 (33A), and the immersion space LS2 (LS2A) which are arranged on the +Y side of the first member 31 will be mainly described.

In this embodiment, the liquid immersion member 3 comprises a guide portion 40 which guides at least a portion of the liquid LQ in the immersion space LS1 to a guide space A which is a partial space around the optical path K.

In this embodiment, the guide portion 40 includes a guide portion 40A that guides the liquid LQ to a guide space A1 and a guide portion 4013 that guides the liquid LQ to a guide space A2. The guide space A 1 and the guide space A2 are separated from each other. In this embodiment, the guide space A 1 is opposite to the guide space A2 with the optical path K interposed therebetween. In this embodiment, the guide space A 1 is a partial space which is disposed on the +Y side of the optical path K in the space SP1 around the optical path K. The guide space A2 is a partial space which is disposed on the −Y side of the optical path K in the space SP1 around the optical path K.

In this embodiment, the immersion space LS2 (LS2A and LS2B) is formed adjacent to the guide space A (A 1 and A2). The immersion space LS2A is formed adjacent to the guide space A1. The immersion space LS2B is formed adjacent to the guide space A2.

In this embodiment, the guide portion 40A and the guide portion 40B have substantially the same structure. Next, the guide space A (A1) which is adjacent to the immersion space LS2A formed by the second member 32A and the guide portion 40 (40A) which guides the liquid LQ to the guide space A (A1) will be described.

In this embodiment, at least a part of the guide portion 40 is arranged in the first member 31.

In this embodiment, the guide space A includes a part (portion) of the space SP1 between the lower surface 14 of the first member 31 and the upper surface of the object (for example, the substrate P) facing the lower surface 14. The guide space A may also not include the part (portion) of the space SP1 between the lower surface 14 of the first member 31 and the upper surface of the object (for example, the substrate P) facing the lower surface 14.

In this embodiment, the guide space A includes a space between a portion (region) B of the lower surface 14 and the substrate P. The guide space A is adjacent to the portion B. In this embodiment, the guide space A includes a space between the substrate P and a part of the circumferential portion 36 of the first member 31.

The circumferential portion 36 of the first member 31 includes the edge of the lower surface 14. The guide space A includes a space between the substrate P and the portion B which is provided in a part of the circumferential portion 36 of the lower surface 14.

The guide space A may also not be the space between the substrate P (object) and a part of the circumferential portion 36 of the lower surface 14. For example, the guide space A may be a space between the substrate P (object) and a portion of the inside of the circumferential portion 36 of the lower surface 14. For example, the guide space A may be a space between a portion of the center of the lower surface 14 and the substrate P (object). That is, the portion 13 of the lower surface 14 is provided in a region different from the circumferential portion 36 of the lower surface 14. For example, the portion B may be provided inside the circumferential portion 36 or at the center of the lower surface 14.

In this embodiment, the guide space A is defined between the optical path K and the immersion space LS2 formed by the liquid immersion member 32. In this embodiment, at least a portion of the liquid immersion member 32 is arranged adjacent to the guide space A. The liquid immersion member 32 is provided outside the guide space A (portion B) with respect to the optical path K and is arranged in the vicinity of the guide space A so as to be adjacent to the guide space A (portion B). For example, the guide space A is formed so as to include a virtual line connecting the optical path K and the immersion space LS2 (liquid immersion member 32). The guide space A may also not include a part (portion) of the space SP1 between the lower surface 14 of the first member 31 and the upper surface of the object (for example, the substrate P) facing the lower surface 14.

The guide space A may include a space outside the space SP1 between the lower surface 14 and the substrate P (object). For example, the guide space A may include at least a portion of the space SP2 between the lower surface 15 of the liquid immersion member 32 and the upper surface of the substrate P (object). In addition, the guide space A may include a space below a gap between the outer surface 314 of the first member 31 and the inner surface 323 of the second member 32.

In this embodiment, at least a part of the guide portion 40 is arranged in the first member 31. In this embodiment, at least a part of the guide portion 40 is arranged in the lower surface 14 of the first member 31 which can face the substrate P (object). The guide portion 40 can guide at least a portion of the liquid LQ in the immersion space LS1 between the lower surface 14 and the substrate P (object) to the guide space A.

In this embodiment, the guide portion 40 includes, for example, the edge 41 of the first member 31. The edge 41 of the liquid immersion member 31 can guide at least a portion of the liquid LQ in the immersion space LS1 to the guide space A.

At least a portion of the liquid LQ in the immersion space LS1 is guided to the edge 41 of the liquid immersion member 31 and flows to the guide space A.

In this embodiment, the guide portion 40 includes, for example, at least a part of the liquid recovery portion 21. In this embodiment, the guide portion 40 includes, for example, at least a portion of the lower surface 42 of the porous member 24. The lower surface 42 of the porous member 24 can guide at least a portion of the liquid LQ in the immersion space LS1 to the guide space A.

At least a portion of the liquid LQ in the immersion space LS1 is guided to the lower surface 42 of the porous member 24 and flows to the guide space A. In this embodiment, the guide portion 40 includes, for example, a boundary 43 between the liquid recovery portion 21 and the flat portion 26S. In this embodiment, the boundary 43 includes the boundary between the lower surface 42 and the lower surface 26.

In this embodiment, the state (surface state) of the lower surface 42 is different from the state (surface state) of the lower surface 26. The lower surface 42 is arranged around the lower end of the hole of the porous member 24. The lower surface 42 is uneven. The lower surface 42 and the lower surface 26 may have different contact angles with respect to the liquid LQ. For example, the contact angle of the lower surface 42 with respect to the liquid LQ may be less than the contact angle of the lower surface 26 with respect to the liquid LQ. The contact angle of the lower surface 42 with respect to the liquid LQ may be more than the contact angle of the lower surface 26 with respect to the liquid LQ. In addition, the contact angle of the lower surface 42 with respect to the liquid LQ may be equal to the contact angle of the lower surface 26 with respect to the liquid LQ.

The boundary 43 can guide at least a portion of the liquid LQ in the immersion space LS1 to the guide space A. The lower surface 42 and the lower surface 26 may have different heights. That is, the boundary 43 may have a difference in level.

At least a portion of the liquid LQ in the immersion space LS1 is guided by the boundary 43 and flows to the guide space A.

In this embodiment, the guide space A includes a space between at least a part of the liquid recovery portion 21 and the substrate P (object). In this embodiment, the portion B includes a portion of the lower surface 42 of the porous member 24 and the guide space A includes a space between at least a portion of the lower surface 24 of the porous member 24 and the object.

In this embodiment, at least a portion of the edge 41 extends to the guide space A in a line shape. For example, in FIG. 5, portions 41A and 41B of the edge 41 extend to the guide space A in a line shape.

In this embodiment, at least a portion of the lower surface 42 of the porous member 24 extends to the guide space A in a strip shape. For example, in FIG. 5, portions 42A and 42B of the lower surface 42 extend to the guide space A in a strip shape.

In this embodiment, at least a portion of the boundary 43 extends to the guide space A in a line shape. For example, in FIG. 5, portions 43A and 43B of the boundary 43 extend to the guide space A in a line shape.

In this embodiment, the portion 41A of the edge 41 is arranged so as to extend from the +X side of the axis J passing through the space SP2 to the guide space A in the plane (the XY plane) which is substantially parallel to the upper surface of the substrate P (object). In addition, the portion 41B of the edge 41 is arranged so as to extend from the −X side of the axis J passing through the space SP2 to the guide space A in the plane (the XY plane) which is substantially parallel to the upper surface of the substrate P (object).

The axis J includes a virtual axis (virtual line) passing through the space SP2. The axis J passing through the space SP2 passes through the immersion space LS2. The axis J connects the optical path K and the space SP2 (immersion space LS2) in the XY plane. The axis J connects, for example, the optical path K and the center of the space SP2 (immersion space LS2) in the X-axis direction. In this embodiment, the axis J is substantially parallel to the Y-axis.

In this embodiment, in the plane (XY plane) which is substantially parallel to the substrate P (object), the gap between the portion 41A and the portion 41B in a direction (X-axis direction) perpendicular to the axis J is reduced toward the guide space A.

In this embodiment, the gap between the portion 41A and the portion 41B is reduced as the distance from the optical path K increases.

In this embodiment, the portion 42A of the lower surface 42 is arranged so as to extend from the +X side of the axis J to the guide space A in the plane (XY plane) which is substantially parallel to the upper surface of the substrate P (object). The portion 4213 of the lower surface 42 is arranged so as to extend from the −X side of the axis J to the guide space A in the plane (XY plane) which is substantially parallel to the upper surface of the substrate P (object).

In this embodiment, in the plane (XY plane) which is substantially parallel to the upper surface of the substrate P (object), the gap between the portion 42A and the portion 42B in the direction (X-axis direction) perpendicular to the axis J is reduced toward the guide space A.

In this embodiment, the gap between the portion 42A and the portion 42B is reduced as the distance from the optical path K increases.

In this embodiment, the portion 43A of the boundary 43 is arranged so as to extend from the +X side of the axis J to the guide space A in the plane (XY plane) which is substantially parallel to the upper surface of the substrate P (object). The portion 43B of the boundary 43 is arranged so as to extend from the −X side of the axis J to the guide space A in the plane (XY plane) which is substantially parallel to the upper surface of the substrate P (object).

In this embodiment, in the plane (XY plane) which is substantially parallel to the upper surface of the substrate P (object), the gap between the portion 43A and the portion 43B in the direction (X-axis direction) perpendicular to the axis J is reduced toward the guide space A.

In this embodiment, the gap between the portion 43A and the portion 43B is reduced as the distance from the optical path K increases.

In this embodiment, at least a part of the fluid recovery portion 51 (recovery port 52) is arranged outside the portion B in the radiation direction for the optical path K.

In this embodiment, the axis J passes through the supply port 50. Furthermore, in this embodiment, the axis J passes through the fluid recovery portion 51 (recovery port 52) between the liquid immersion member 31 and the supply port 50. In this embodiment, the axis J passes through the fluid recovery portion 51 (recovery port 52) which is disposed outside the supply port 50 with respect to the liquid immersion member 31.

In this embodiment, the lower surface 15 is arranged so as to surround a part of the portion B. In addition, in this embodiment, the lower surface 16 is arranged so as to surround a part of the portion B.

Next, a method of exposing the substrate P using the exposure apparatus EX having the above-mentioned structure will be described.

The controller 4 performs a process of loading an unexposed substrate P to the substrate holding portion 10. In order to load the unexposed substrate P to the substrate holding portion 10, the controller 4 moves the substrate stage 2P to a substrate exchange position which is away from the liquid immersion member 3. For example, when the exposed substrate P has been held by the substrate holding portion 10, the exposed substrate P is unloaded from the substrate holding portion 10 and then the unexposed substrate P is loaded to the substrate holding portion 10.

At the substrate exchange position, a process of exchanging the substrate P can be performed. The process of exchanging the substrate P includes at least one of a process of unloading the exposed substrate P held by the substrate holding portion 10 from the substrate holding portion 10 and a process of loading the unexposed substrate P to the substrate holding portion 10. The controller 4 moves the substrate stage 2P to the substrate exchange position which is away from the liquid immersion member 3 and performs the process of exchanging the substrate P.

During at least a portion of the period for which the substrate stage 2P is separated from the liquid immersion member 3, the controller 4 arranges the measurement stage 2C at a predetermined position with respect to the liquid immersion member 3 and holds the liquid LQ between the termination optical element 8 and the first liquid immersion member 31, and the measurement stage 2C to form the immersion space LS1. That is, the controller 4 forms the immersion space LS1 of the liquid LQ on the side of the emission surface 7 of the termination optical element 8 using the liquid immersion member 31, with the termination optical element 8 and the liquid immersion member 31 facing the measurement stage 2C.

The controller 4 recovers the liquid LQ from the recovery port 23 in parallel to the supply of the liquid LQ from the supply port 28. In this way, the immersion space LS1 is formed. In this embodiment, the controller 4 supplies the liquid LQ from the supply port 27 in parallel to the supply of the liquid LQ from the supply port 28 and the recovery of the liquid LQ from the recovery port 23.

The liquid LQ is supplied from the supply port 27 to adjust, for example, the shape of the interface LG1. For example, the liquid LQ is supplied from the supply port 27 to adjust the shape of the interface LG1 when the object is moved in the XY plane, with the immersion space LS1 is formed between the object, and the termination optical element 8 and the liquid immersion member 31.

While the immersion space LS1 is formed, the amount of liquid supplied from the supply port 27 per unit time may be constant or variable. In addition, the amounts of liquid supplied from a plurality of supply ports 27 per unit time may be equal to or different from each other. For example, while the immersion space LS1 is formed, control may be performed such that the amount of liquid supplied from each of the plurality of supply ports 27 per unit time varies depending on the moving direction of the object (substrate P) in the XY plane.

With the immersion space LS1 formed by the supply of the liquid LQ from the supply port 28 and the recovery of the liquid LQ from the recovery port 23, the supply of the liquid LQ from the supply port 27 may be stopped. In addition, the supply port 27 may also not be provided.

The controller 4 forms the immersion space LS2 (LS2A and LS2B) of the liquid LQ in a portion of the periphery of the immersion space LS1 using the liquid immersion member 32 (32A and 32B). The immersion space LS2 (LS2A and LS2B) is formed by the liquid LQ supplied from the supply port 50.

For a portion of the period for which the substrate stage 2P is separated from the liquid immersion member 3, if necessary, a measurement process is performed using the measurement member (measurement device) mounted on the measurement stage 2C. When the measurement process is performed using the measurement member (measurement device), the controller 4 arranges the measurement stage 2C so as to face the termination optical element 8 and the liquid immersion member 31 and forms the immersion space LS1 such that the optical path K between the termination optical element 8 and the measurement member is filled with the liquid LQ. The controller 4 emits the exposure light EL to the measurement member through the projection optical system PL and the liquid LQ to perform the measurement process using the measurement member. The result of the measurement process is reflected in the exposure process of the substrate P.

After the unexposed substrate P is loaded to the substrate holding portion 10 and the measurement process using the measurement member (measurement device) ends, the controller 4 moves the substrate stage 2P to the projection region PR and forms the immersion space LS1 of the liquid LQ between the substrate stage 2P (substrate P), and the termination optical element 8 and the liquid immersion member 31.

While the substrate stage 2P is being moved from the substrate exchange position to the projection region PR (exposure position), information about the position of the substrate P (substrate stage 2P) may be detected using a detection system including an encoder system, an alignment system, and a surface position detection system which is disclosed in, for example, the specification of United States Patent Application, Publication No. 2007/0288121.

In this embodiment, as disclosed in the specifications of United States Patent Application, Publication No, 2006/0023186 and United States Patent Application, Publication No. 2007/0127006, the controller 4 can move the substrate stage 2P and the measurement stage 2C in the XY plane relative to the termination optical element 8 and the liquid immersion member 3 while making at least one of the substrate stage 2P and the measurement stage 2C face the termination optical element 8 and the liquid immersion member 31, with the upper surface of the substrate stage 2P contacting or approaching the upper surface of the measurement stage 2C, such that the immersion space LS1 of the liquid LQ is continuously formed between at least one of the substrate stage 2P and the measurement stage 2C, and the termination optical element 8 and the liquid immersion member 31.

In this way, a state is changed from the state in which the immersion space LS1 is formed between the measurement stage 2C, and the termination optical element 8 and the liquid immersion member 31 to the state in which the immersion space LS1 is formed between the substrate stage 2P, and the termination optical element 8 and the liquid immersion member 31, while the leakage of the liquid LQ is prevented. In addition, the controller 4 may change the state from the state in which the immersion space LS1 is formed between the substrate stage 2P, and the termination optical element 8 and the liquid immersion member 31 to the state in which the immersion space LS1 is formed between the measurement stage 2C, and the termination optical element 8 and the liquid immersion member 31

In the following description, an operation of synchronously moving the substrate stage 2P and the measurement stage 2C in the XY plane relative to the termination optical element 8 and the liquid immersion member 3, with the upper surface 11P of the substrate stage 2P approaching or contacting the upper surface 11C of the measurement stage 2C is appropriately referred to as a “scrum movement operation”.

After the immersion space LS1 of the liquid LQ is formed between the substrate stage 2P (substrate P), and the termination optical element 8 and the liquid immersion member 31 and the immersion space LS2 is formed in a portion of the periphery of the immersion space LS1, the controller 4 starts the process of exposing the substrate P.

When the process of exposing the substrate P is performed, the controller 4 arranges the substrate stage 2P so as to face the termination optical element 8 and the liquid immersion member 3 and forms the immersion space LS1 of the liquid LQ on the side of the emission surface 7 of the termination optical element 8 using the liquid immersion member 31 such that the optical path K between the termination optical element 8 and the substrate P is filled with the liquid LQ. The controller 4 directs the illumination system IL to emit the exposure light EL. The illumination system IL emits the exposure light EL to the mask M. The exposure light EL from the mask M is emitted to the substrate P through the projection optical system PL and the liquid LQ. In this way, the substrate P is exposed with the exposure light EL which passes through the liquid LQ of the immersion space LS1 and the pattern image of the mask M is projected onto the substrate P.

The exposure apparatus EX according to this embodiment is a scanning-type exposure apparatus (a so-called scanning stepper) which projects the pattern image of the mask M onto the substrate P while synchronous moving the mask M and the substrate P in a predetermined scanning direction. In this embodiment, the scanning direction (synchronous moving direction) of the substrate P is the Y-axis direction and the scanning direction (synchronous moving direction) of the mask M is also the Y-axis direction. The controller 4 irradiates the substrate P with the exposure light EL through the projection optical system PL and the liquid LQ in the immersion space LS1 on the substrate P, while moving the substrate P in the Y-axis direction with respect to the projection region PR of the projection optical system PL and moving the mask M in the Y-axis direction with respect to the illumination region IR of the illumination system IL in synchronization with the movement of the substrate P in the Y-axis direction.

In this embodiment, a plurality of shot regions, which are exposure target regions, are arranged on the substrate P in a matrix. In the exposure of the substrate P, the immersion space LS1 is formed on the substrate P such that the optical path K of the exposure light EL on the side of the emission surface 7 of the termination optical element 8 is filled with the liquid LQ. The controller 4 sequentially exposes the plurality of shot regions on the substrate P which is held by the substrate holding portion 10 with the exposure light EL through the liquid LQ in the immersion space LS1. The plurality of shot regions of the substrate P are exposed by the exposure light EL which passes through the liquid LQ.

In order to expose, for example, the first shot region of the substrate P, the controller 4 irradiates a shot region S1 with the exposure light EL through the projection optical system PL and the liquid LQ in the immersion space LS1 on the substrate P, while moving the substrate P (first shot region) in the Y-axis direction with respect to the projection region PR of the projection optical system PL and moving the mask M in the Y-axis direction with respect to the illumination region IR of the illumination system IL in synchronization with the movement of the substrate P in the Y-axis direction. In this way, the pattern image of the mask M is projected onto the first shot region of the substrate P and the first shot region is exposed with the exposure light EL emitted from the emission surface 7. After the exposure of the first shot region ends, in order to start the exposure of the next second shot region, the controller 4 moves the substrate P in a predetermined direction (for example, the X-axis directions or a direction which is inclined with respect to the X-axis directions in the XY plane) in the XY plane with the immersion space LS1 being formed, thereby moving the second shot region to an exposure start position. Then, the controller 4 starts the exposure of the second shot region.

The controller 4 sequentially exposes the plurality of shot regions of the substrate P while repeatedly performing an operation of exposing the shot region while moving the shot region in the Y-axis direction with respect to the projection region PR and an operation of moving the next shot region to the exposure start position after the exposure of the shot region ends.

In the following description, an operation of moving the substrate P in the Y-axis direction with respect to the termination optical element 8 in order to expose the shot region is appropriately referred to as a scanning movement operation. In addition, an operation of, after the exposure of a given shot region ends, moving the substrate P relative to the termination optical element 8 such that the next shot region is disposed at the exposure start position in order to expose the next shot region is appropriately referred to as a stepping movement operation.

In this embodiment, during the scanning movement operation, the immersion space LS2 is continuously formed in a portion of the periphery of the immersion space LS1. In addition, in this embodiment, during the stepping movement operation, the immersion space LS2 is continuously formed in a portion of the periphery of the immersion space LS1.

The controller 4 moves the substrate P (substrate stage 2P) on the basis of the exposure conditions of the plurality of shot regions on the substrate P. The exposure conditions of the shot regions are defined by, for example, exposure control information which is called an exposure recipe. The exposure control information is stored in the storage device 5. The controller 4 sequentially exposes the plurality of shot regions while moving the substrate P under predetermined movement conditions, on the basis of the exposure conditions stored in the storage device 5. The movement conditions of the substrate P (object) include at least one of a movement velocity, a movement distance, and a locus of movement with respect to the optical path K (first immersion space LS1).

As described above, in this embodiment, the guide portion 40 that guides at least a portion of the liquid LQ forming the immersion space LS1 to the guide space A is provided. Therefore, when an object, such as the substrate P, is moved in the Y-axis direction parallel to the axis J, with the immersion space LS1 being formed, at least a portion of the liquid LQ in the immersion space LS1 is guided to the guide space A.

For example, as shown in FIG. 5, when the object is moved in the +Y direction, at least a portion of the liquid LQ forming the immersion space LS1 flows to the space SP1 by the movement of the object. At least a portion of the liquid LQ forming the immersion space LS1 which flows with the movement of the object in the +Y direction flows, for example, in the directions indicated by arrows R1 and R2 and is then guided to the guide space A (A1) adjacent to the immersion space LS2 (LS2A) by the guide portion 40.

For example, at least a portion of the liquid LQ forming the immersion space LS1 flows in the direction indicated by the arrow R1 and is guided to the guide space A by at least a part of the portion 41A, the portion 42A, and the portion 43A of the guide portion 40. In addition, at least a portion of the liquid LQ forming the immersion space LS1 flows in the direction indicated by the arrow R2 and is guided to the guide space A1 by at least a part of the portion 41B, the portion 42B, and the portion 43B of the guide portion 40.

Even when the object is moved in directions other than the +Y direction, the guide portion 40 can guide the liquid LQ to the guide space A (A1). That is, when the object is moved in a direction including a component of the +Y direction, the guide portion 40 can guide the liquid LQ to the guide space A (A1). For example, when the object is moved in the +X direction while being moved in the +Y direction, the guide portion 40 can guide the liquid LQ to the guide space A (A1). In addition, when the object is moved in the −X direction while being moved in the +Y direction, the guide portion 40 can guide the liquid LQ to the guide space A (A1). As such, the guide portion 40 can guide at least a portion of the liquid LQ forming the immersion space LS1 which flows with the movement of the object including movement to the +Y direction to the guide space A.

Similarly, when the object is moved in the −Y direction or a direction including the component of the −Y direction, the guide portion 40 can guide at least a portion of the liquid LQ forming the immersion space LS1 to the guide space A (A2) adjacent to the immersion space LS2 (LS2B).

In a predetermined operation of the exposure apparatus EX, when the object is moved under predetermined movement conditions with the immersion space LS1 being formed, at least a portion of the liquid LQ in the immersion space LS1 is likely to flow to the outside of the space SP1.

For example, in the scrum movement operation of the exposure apparatus EX, at least a portion of the liquid LQ in the first immersion space LS1 is likely to flow to the outside of the space SP1.

For example, in the scanning movement operation of the exposure apparatus EX, at least a portion of the liquid LQ in the first immersion space LS1 is likely to flow to the outside of the space SP1.

In the stepping movement operation of the exposure apparatus EX, at least a portion of the liquid LQ in the first immersion space LS1 is likely to flow to the outside of the space SP1.

For example, in at least one of the scrum movement operation, the scanning movement operation, and the stepping movement operation, the object is likely to be moved in the Y-axis direction under the conditions which do not satisfy predetermined permissible conditions capable of maintaining the first immersion space LS1 of the liquid LQ between the first liquid immersion member 31 and the object.

For example, in a predetermined operation, the object is likely to be moved in the Y-axis direction by a distance longer than a predetermined permissible distance capable of maintaining the first immersion space LS1 of the liquid LQ between the first liquid immersion member 31 and the object.

In a predetermined operation, the object is likely to be moved in the Y-axis direction at a speed higher than a predetermined permissible speed capable of maintaining the first immersion space LS1 of the liquid LQ between the first liquid immersion member 31 and the object.

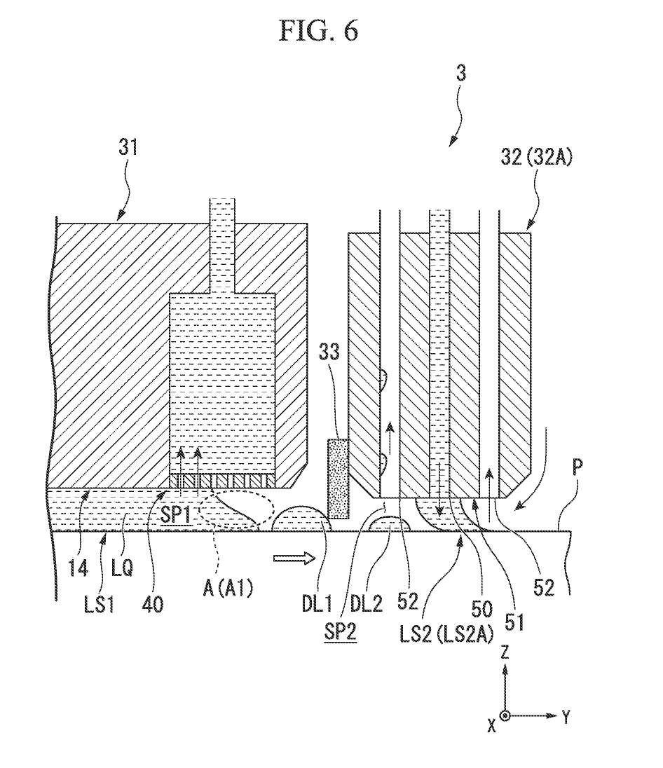

FIG. 6 is a diagram schematically illustrating an example of the state in which an object, such as the substrate P, is moved in the Y-axis direction under the conditions which do not satisfy the predetermined permissible conditions capable of maintaining the immersion space LS1 of the liquid LQ between the first member 31 and the object.

As shown in FIG. 6, for example, when the object is moved in the Y-axis direction under the conditions which do not satisfy the predetermined permissible conditions, at least a portion of the liquid LQ in the immersion space LS1 is likely to flow to the outside of the space SP1.

In this embodiment, when the object is moved in the +Y direction, the liquid LQ in the immersion space LS1 is guided to the guide space A (A1) by the guide portion 40. Therefore, when the object is moved in the +Y direction under the conditions which do not satisfy permissible conditions, the liquid LQ in the immersion space LS1 is likely to be collected to the guide space A (A1) and then flow from the guide space A (A1) to the outside of the space SP1. That is, at least a portion of the liquid LQ in the space SP1 is likely to flow out from the space SP1 through the guide space A (A1). In other words, when the object is moved in the +Y direction, the liquid LQ in the immersion space LS1 is likely to be collected to the guide space A (A1) and then flow to the +Y side of the guide space A (A1).

In this embodiment, the immersion space LS2 (LS2A) of the liquid LQ is formed by the liquid immersion member 32 (32A) so as to be adjacent to the guide space A (A1). In this embodiment, in a predetermined operation of the exposure apparatus EX, the liquid immersion member 32 (32A) is arranged adjacent to the liquid immersion member 31 in the Y-axis direction in which the object is moved. The immersion space LS2 (LS2A) is arranged so as to be adjacent to the guide space A (A1) on the +Y side of the guide space A (A1).

Therefore, the liquid LQ which has flowed from the space SP1 through the guide space A (A1) is moved to the immersion space LS2. In this way, the immersion space LS2 prevents the liquid LQ, which has flowed to the outside of the space SP1 from flowing to the outside of the space SP2.

That is, in this embodiment, the immersion space LS2 prevents the outflow of the liquid LQ which has leaked from the space SP1 without being completely recovered by the recovery port 23. For example, the liquid LQ which has flowed to the outside of the space SP1 is integrated with the liquid LQ of the immersion space LS2 in the space SP2. In addition, the liquid LQ which has flowed to the outside of the space SP1 is recovered by, for example, the recovery port 52 between the liquid immersion member 31 and the supply port 50. The recovery port 52 recovers the liquid LQ from the space SP1 and the liquid LQ from the immersion space LS2.

In this embodiment, the immersion space LS2 is smaller than the immersion space LS1. Therefore, even when the object is moved to the space SP1 in the Y-axis direction under the conditions which do not satisfy predetermined permissible conditions capable of maintaining the immersion space LS1 of the liquid LQ, the outflow of the liquid LQ in the immersion space LS2 from the space SP2 is prevented.

In this embodiment, the third member 33 (33A) is arranged between the space SP1 (guide space A) and the space SP2. The liquid LQ flowing from the space SP1 to the immersion space LS2 of the space SP2 comes into contact with the third member 33. The flow (movement) of the liquid LQ from the space SP1 to the space SP2 (immersion space LS2) is restricted. For example, the liquid LQ which has flowed from the space SP1 is divided between the space SP1 and the space SP2 (immersion space SP2). For example, a droplet DL1 of the liquid LQ which has flowed out from the space SP1 comes into contact with the third member 33 and is divided into a plurality of droplets DL2. For example, the droplet DL1 with a weight (or dimensions) W1 which has flowed out from the space SP1 comes into contact with the third member 33 and is changed to the droplet DL2 with a weight (dimensions) W2 less than the weight (dimensions) W1. As such, in this embodiment, the weight (dimensions) of the droplet DL1 of the liquid LQ which is moved from the space SP1 to the space SP2 is reduced by the third member 33.

The third member 33 may absorb at least a portion of the liquid LQ (droplet DL1) from the space SP1 to restrict the movement of the liquid LQ from the space SP1 to the space SP2 (immersion space LS2). For example, the third member 33 may absorb at least a portion of the liquid LQ (droplet DL1) from the space SP1 to reduce the weight (dimensions) of the liquid LQ (droplet) moved from the space SP1 to the space SP2 (immersion space LS2). For example, when the third member 33 includes a porous member, the third member 33 may come into contact with the liquid LQ (droplet) to reduce the weight (mass) of the liquid LQ (droplet) moved from the space SP1 to the space SP2 (immersion space LS2). When the third member 33 does not include a porous member, it may divide the liquid LQ (droplet) or it may absorb at least a portion of the liquid LQ (droplet).

The third member 33 may capture at least a portion of the liquid LQ (droplet) from the space SP1 to restrict the movement of the liquid LQ from the space SP1 to the space SP2 (immersion space LS2). For example, the third member 33 may capture at least a portion of the liquid LQ (droplet DL1) from the space SP1 to reduce the weight (dimensions) of the liquid LQ (droplet) moved from the space SP1 to the space SP2 (immersion space LS2). In this embodiment, the third member 33 is arranged at a position where it can come into contact with the liquid LQ (droplet) from the space SP1. Therefore, the third member 33 can capture at least a portion of the liquid LQ (droplet) moved from the space SP1 to the space SP2 (immersion space LS2). In addition, the third member 33 may capture the entire liquid LQ (droplet) moved from the space SP1 to the space SP2 (immersion space LS2).

When the liquid LQ is moved from the space SP1 to the immersion space LS2 and enters the immersion space LS2, the weight (dimensions) of the liquid LQ (droplet) is reduced before the liquid LQ (droplet) enters (is integrated with) the immersion space LS2. In this way, for example, when the liquid LQ enters the immersion space LS2, a change in the shape of the immersion space LS2 is prevented. In addition, when the liquid LQ is integrated with the immersion space LS2, the weight (dimensions) of the liquid LQ (droplet) from the space SP1 is reduced. In this way, the liquid LQ from the space SP1 is smoothly integrated with the liquid LQ in the immersion space LS2.

For example, when the liquid LQ (droplet) with a large weight (dimensions) comes into contact with the immersion space LS2, the shape of the interface LG2 of the immersion space LS2 is likely to be changed or at least a portion of the liquid LQ in the immersion space LS2 is likely to flow out from the space SP2. In this embodiment, since the amount of liquid LQ (droplet) which comes into contact with the immersion space LS2 is reduced, for example, it is possible to recover the liquid LQ flowing from the space SP1 and the liquid LQ in the immersion space LS2 through the recovery port 52 while preventing a change in the shape of the immersion space LS2 or the outflow of at least a portion of the liquid LQ in the immersion space LS2 from the space SP2.

The liquid LQ may also not be divided by the third member 33. For example, only the flow of the liquid LQ may be restricted such that the height of the liquid LQ from the space SP1 is reduced.

The third member 33 may also not be a porous member. For example, when the absorption of the liquid LQ by the third member 33 is not needed, the third member 33 may also not be a porous member.

The lower surface of the third member 33 may be inclined. For example, the lower surface of the third member 33 may be inclined downward to the outside in the radiation direction for the optical axis AX. For example, in FIG. 4, the lower surface of the third member 33 may be inclined such that the height of the lower surface of the third member 33 is gradually reduced in the +Y-axis direction. In this case, the third member 33 may also not be a porous member.

When the third member 33 is a porous member, a heater may be provided in the porous member or a suction device (vacuum device) may be connected to the porous member, in order to dry the porous member.

In this embodiment, the circumferential portion 36 of the lower surface 14 includes the inclined plane 43. That is, the distance between the lower surface 14 (inclined plane 43) in the circumferential portion 36 and the upper surface of the substrate P (object) is more than the distance between the lower surface 14 (26, 42) at the center of the inside of the circumferential portion 36 and the upper surface of the substrate P (object). Therefore, the liquid LQ from the space SP1 can be moved from the space SP1 to the space SP2 without being captured between the circumferential portion 36 of the lower surface 14 and the upper surface of the substrate P (object).

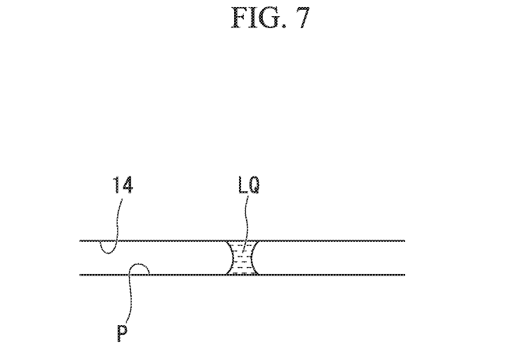

For example, as shown in the schematic diagram of FIG. 7, when the distance between the lower surface 14 and the upper surface of the substrate P (object) is short, a phenomenon (remaining phenomenon) in which the liquid LQ is captured between the circumferential portion 36 of the lower surface 14 and the upper surface of the substrate P (object) is likely to occur outside the immersion space LS1. The phenomenon in which the liquid LQ is captured between the lower surface 14 and the upper surface of the substrate P (object) is also called a bridge phenomenon. In this embodiment, the occurrence of the bridge phenomenon is prevented since the inclined plane 43 is provided in the circumferential portion 36 of the lower surface 14 and the distance between the circumferential portion 36 of the lower surface 14 and the upper surface of the substrate P (object) is enlarged.

In this embodiment, since the inclined plane 43 repels the liquid LQ, the occurrence of the bridge phenomenon is prevented.

The state of the third member 33A and the liquid LQ when the substrate P (object) is moved in the +Y direction has been described above. When the substrate P (object) is moved in the −Y direction, the third member 33 restricts the flow (movement) of the liquid LQ from the space SP1 to the space SP2 (immersion space LS2) and the liquid LQ which has passed through the gap between the third member 33B and the substrate P (object) is recovered from the recovery port 52 of the second member 32B. A description of the state of the liquid LQ when the third member 33B and the substrate P (object) are moved in the −Y direction will be omitted.

As described above, in this embodiment, since the third member 33 is provided, it is possible to divide the liquid LQ moved to the space SP2, reduce the amount of liquid LQ moved to the space SP2, and/or reduce the height of the liquid LQ moved to the space SP when the liquid flows from the space SP1. Therefore, the liquid LQ which has not been completely recovered from the recovery port 23 and has leaked from the space SP1 can be reliably recovered from the recovery port 52. Therefore, the liquid LQ is prevented from flowing to the outside of the space SP2 and is prevented from remaining on the upper surface of the object (for example, the substrate P) facing the liquid immersion member 3. Therefore, the occurrence of an exposure defect and a device is prevented from being defective.

In this embodiment, the first member 31 and the second member 32 may be integrated with each other. That is, at least a portion of the first member 31 and the second member 32 may be connected to each other. A temperature adjusting device that adjusts the temperature of the integrated first and second members 31 and 32 may be provided. In addition, the first member 31 and the third member 33 may be integrated with each other. That is, at least a portion of the first member 31 and the third member 33 may be connected to each other. In addition, a temperature adjusting device that adjusts the temperature of the integrated first and third members 31 and 33 may be provided.

### Second Embodiment

Next, a second embodiment will be described. In the following description, components which are the same as or similar to those in the above-described embodiment are denoted by the same reference numerals and a description thereof is abbreviated or omitted here.

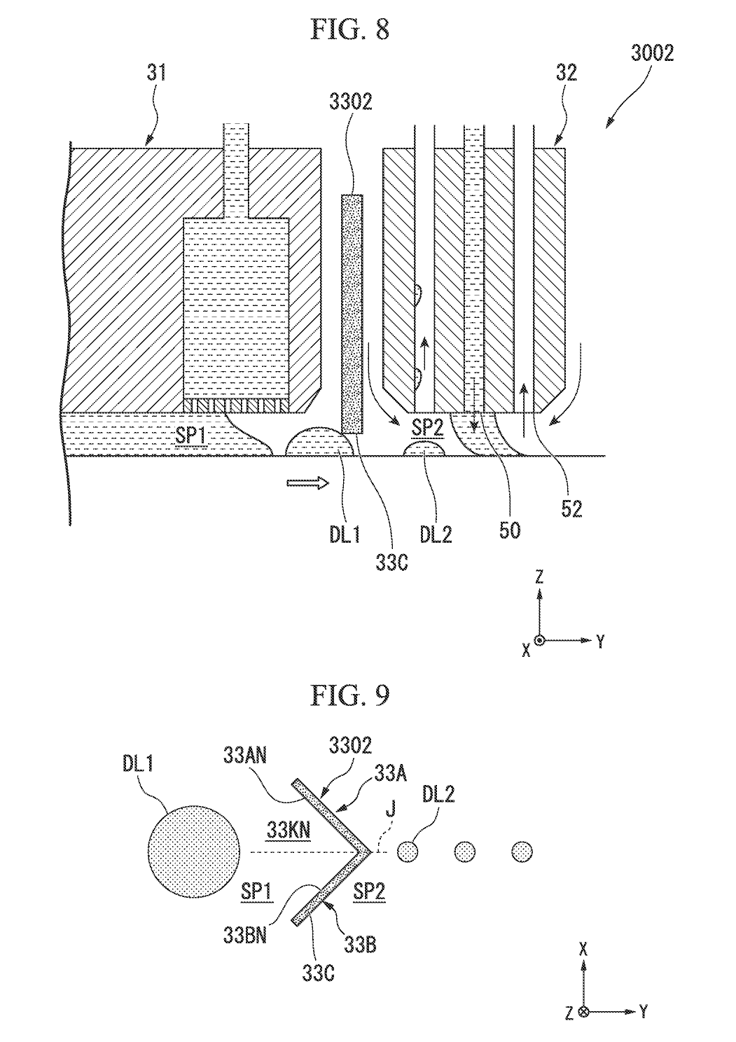

FIG. 8 is a side view illustrating an example of a liquid immersion member 3002 according to the second embodiment. In FIG. 8, the liquid immersion member 3002 includes a first member 31, a second member 32, and a third member 3302 that is provided between the first member 31 and the second member 32. In this embodiment, the third member 3302 is separated from the first member 31. In addition, the third member 3302 is separated from the second member 32.

FIG. 9 is a diagram illustrating the third member 3302, as viewed from the lower side. As shown in FIG. 9, the third member 3302 includes a portion 33A that extends from the +X side of an axis J passing through a space SP2 to the space SP2 in the plane (XY plane) which is substantially parallel to the upper surface of a substrate P (object) with reference to the axis J and a portion 3313 that extends from the −X side of the axis J to the space SP2.

In this embodiment, in the plane (XY plane) substantially parallel to the substrate P (object), the gap between the portion 33A and the portion 3313 in a direction (X-axis direction) perpendicular to the axis J is reduced toward the space SP2.

In this embodiment, the gap between the portion 33A and the portion 3313 is reduced as the distance from an optical path K increases.

In this embodiment, at least a portion of the surface of the third member 3302 repels a liquid LQ. In this embodiment, the contact angle of the surface of the third member 3302 with respect to the liquid LQ is greater than, for example, 90 degrees.

The contact angle of the surface of the third member 3302 with respect to the liquid LQ may be equal to or greater than, for example, 100 degrees or 110 degrees.

In this embodiment, a liquid-repellant material including fluorine is coated on at least a portion of the surface of the third member 3302. That is, a film including the liquid-repellant material is provided on at least a portion of the surface of the third member 3302. The liquid-repellant material may be, for example, PFA (Tetra fluoro ethylene-perfluoro alkylvinyl ether copolymer), PTFE (Poly tetra fluoro ethylene), PEEK (polyetheretherketone), or Teflon (registered trademark). The third member 3302 may be made of a liquid-repellant material including the fluorine.

The third member 3302 is arranged so as to come into contact with the liquid LQ (droplet DL1) which flows from the space SP1. The third member 3302 restricts the movement of the liquid LQ from the space SP1 to the space SP2 (immersion space LS2). For example, the liquid LQ (droplet DL1) moved from the space SP1 to the space SP2 comes into contact with at least a portion of the third member 3302 and is then divided. In addition, the liquid LQ (droplet DL1) moved from the space SP1 to the space SP2 comes into contact with at least a portion of the third member 3302 and is captured by the third member 3302.

In this embodiment, the third member 3302 guides the liquid LQ which flows from the space SP1 to the space SP2 (immersion space LS2). In this embodiment, the portion 33A includes an inner surface 33AN which faces the space SP1. The portion 33B includes an inner surface 33BN which faces the space SP1. At least a portion of the liquid LQ (droplet DL1) flowing from the space SP1 to an opening 33KN between the end of the inner surface 33AN in the −Y direction and the end of the inner surface 33BN in the −Y direction can be guided by the inner surfaces 33AN and 33BN and then moved to the space SP2 (immersion space LS2). In addition, at least a portion of the liquid LQ (droplet DL1) flowing from the space SP1 may be guided to a lower surface 33D of the third member 3302 which can face the upper surface of the substrate P (object) and then may be moved to the space SP2 (immersion space LS2).

In this embodiment, the third member 3302 may be porous member.

In this embodiment, the first member 31 and the second member 32 may be integrated with each other. That is, at least a portion of the first member 31 and the second member 32 may be connected to each other. In addition, a temperature adjusting device that adjusts the temperature of the integrated first and second members 31 and 32 may be provided.

### Third Embodiment

Next, a third embodiment will be described. In the following description, components which are the same as or similar to those in the above-described embodiments are denoted by the same reference numerals and a description thereof is abbreviated or omitted here.

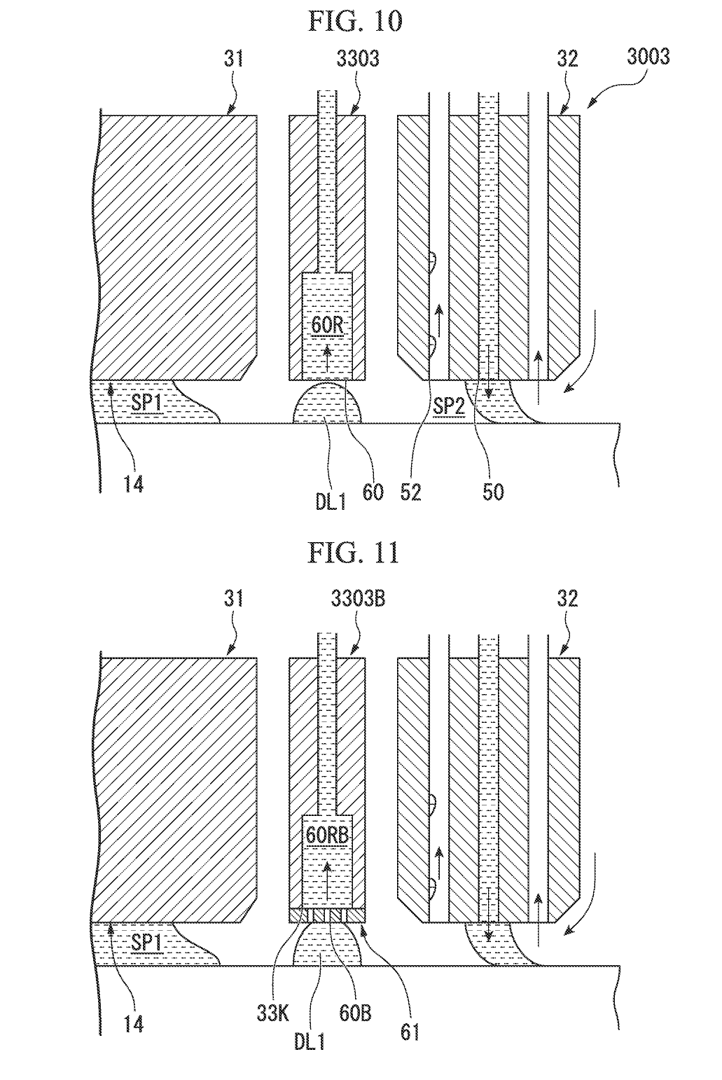

FIG. 10 is a diagram illustrating an example of a liquid immersion member 3003 according to the third embodiment. In FIG. 10, a third member 3303 includes a suction port 60 that suctions at least a portion of a liquid LQ (droplet DL1) flowing from the space SP1. The suction port 60 suctions the liquid LQ flowing from the space SP1 to the space SP2 (immersion space LS2). The third member 3303 restricts the movement of the liquid LQ from the space SP1 to the space SP2.

The suction port 60 is arranged in the lower surface of the third member 3303 so as to face the upper surface of a substrate P (object). The suction port 60 is connected to a liquid suction device through a passageway 60R which is formed in the third member 3303. The liquid suction device can connect the suction port to a vacuum system. When the liquid suction device is operated, at least a portion of the liquid LQ which has flowed from the space SP1 and has come into contact with the suction port 60 is suctioned from the suction port 60. In this way, the weight (dimensions) of the liquid LQ flowing from the space SP1 to the space SP2 (immersion space LS2) is reduced.

As shown in FIG. 11, a second member 3303B may include a porous member 61 that can suction a fluid (the liquid LQ and/or gas). In the example shown in FIG. 11, a hole of the porous member 61 functions as a suction port 60B that can suction a fluid (liquid LQ and/or gas). The third member 3303B includes an opening 33K that faces the upper surface of the substrate P (object). The porous member 61 is arranged in the opening 33K. The liquid suction device forms negative pressure in an internal space 60RB that is formed in the third member 3303B and faces the upper surface of the porous member 61. In this way, at least a portion of the liquid LQ on the lower surface of the porous member 61 which faces the upper surface of the substrate P is recovered from the holes (suction ports 60B) of the porous member 61.

In this embodiment, at least a portion of the first member 31 and the third member 3303 (3303B) may be connected to (integrated with) each other. In addition, at least a portion of the second member 32 and the third member 3303 (3303B) may be connected to (integrated with) each other. A temperature adjusting device that adjusts the temperature of the integrated first and third members 31 and 3303 (3303B) may be provided. In addition, a temperature adjusting device that adjusts the temperature of the integrated second and third members 32 and 3303 (3303B) may be provided.

In the above-described embodiments, the third members (3302, 3303, 3303B) may be movable. For example, the third members (3302, 3303, 3303B) may be movable in the Z-axis direction.

### Fourth Embodiment

Next, a fourth embodiment will be described. In the following description, components which are the same as or similar to those in the above-described embodiments are denoted by the same reference numerals and a description thereof is abbreviated or omitted here.

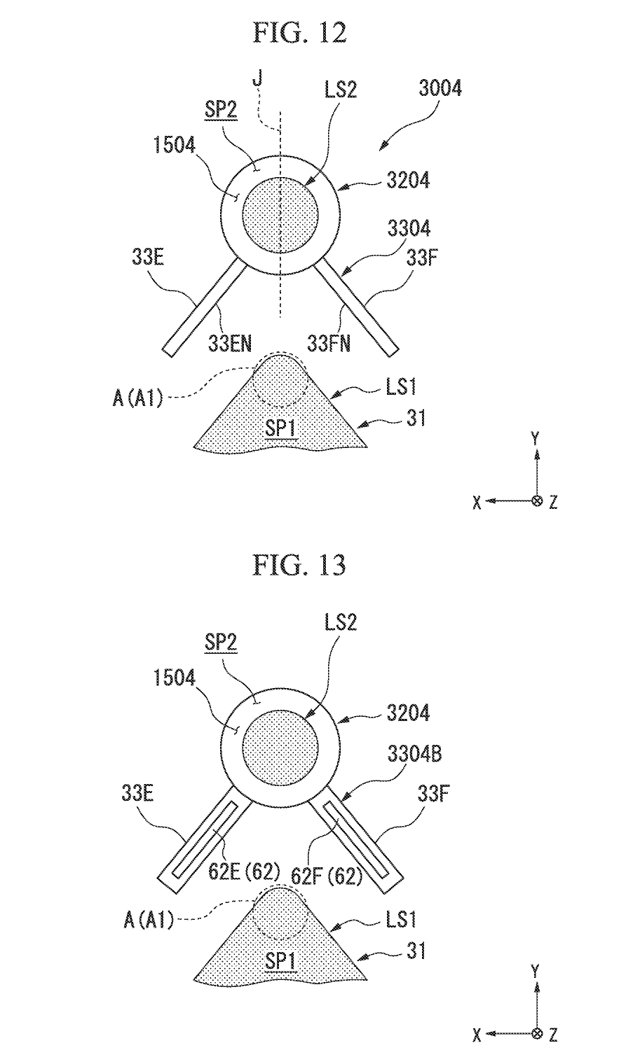

FIG. 12 is a diagram illustrating an example of a liquid immersion member according to the fourth embodiment. In FIG. 12, a liquid immersion member 3004 includes a guide member 3304 that guides a liquid LQ flowing from the space SP1 to a space SP2 (immersion space LS2).

In this embodiment, the guide member 3304 is supported by a second member 3204. In this embodiment, an immersion space LS2 has a substantially circular shape in the XY plane.

The guide member 3304 is arranged between a first member 31 and the second member 3204 so as to come into contact with the liquid LQ flowing from the space SP1.

In this embodiment, the lower surface of the guide member 3304 which can face the upper surface of a substrate P (object) is arranged closer to the substrate P (object) than the lower surface 14 of the first member 31. In addition, the lower surface of the guide member 3304 is arranged closer to the substrate P (object) than the lower surface 1504 of the second member 3204.

The guide member 3304 includes a portion 33E that extends from the +X side of an axis J passing through the space SP2 to the space SP2 in the plane (XY plane) which is substantially parallel to the upper surface of the substrate P (object) with respect to the axis J and a portion 33F that extends from the −X side of the axis J to the space SP2.

In this embodiment, in the plane (XY plane) substantially parallel to the substrate P (object), the gap between the portion 33E and the portion 33F in a direction (X-axis direction) perpendicular to the axis T is reduced toward the space SP2.

In this embodiment, the gap between the portion 33E and the portion 33F is reduced as the distance from the optical path K increases.

In this embodiment, at least a portion of the surface of the guide member 3304 repels the liquid LQ. In this embodiment, the contact angle of the surface of the guide member 3304 with respect to the liquid LQ is greater than, for example, 90 degrees. The contact angle of the surface of the guide member 3304 with respect to the liquid LQ may be equal to or greater than, for example, 100 degrees or 110 degrees.

In this embodiment, a liquid-repellant material including fluorine is coated on at least a portion of the surface of the guide member 3304. That is, a film including the liquid-repellant material is provided on at least a portion of the surface of the guide member 3304. The liquid-repellant material may be, for example, PFA (Tetra fluoro ethylene-perfluoro alkylvinyl ether copolymer), PTFE (Poly tetra fluoro ethylene), PEEK (polyetheretherketone), or Teflon (registered trademark). The guide member 3304 may be made of a liquid-repellant material including fluorine.

The guide member 3304 is arranged so as to come into contact with the liquid LQ which flows from the space SP1. The liquid LQ flowing from the space SP1 comes into contact with at least a portion of the guide member 3304 and is guided to the space SP2 (immersion space SL2).

In this embodiment, the portion 33E includes an inner surface 33EN that faces the space SP1. The portion 33F includes an inner surface 33FN that faces the space SP1. At least a portion of the liquid LQ which has flowed from the space SP1 to an opening between the end of the inner surface 33EN in the −Y direction and the end of the inner surface 33FN in the −Y direction can be guided by the inner surfaces 33EN and 33FN and then moved to the space SP2 (immersion space LS2). In addition, at least a portion of the liquid LQ flowing from the space SP1 may be guided by the lower surface of the guide member 3304 and then moved to the space SP2 (immersion space LS2).

The movement of the liquid LQ flowing from the space SP1 to the space SP2 (immersion space LS2) is likely to be restricted by the guide member 3304. For example, the liquid LQ moved from the space SP1 to the space SP2 is likely to be divided by the guide member 3304. In addition, the liquid LQ moved from the space SP1 to the space SP2 is likely to come into contact with at least a portion of the guide member 3304 and to be captured by the guide member 3304.

In this embodiment, the guide member 3304 may be a porous member.

As shown in FIG. 13, a groove 62 may be formed in the lower surface of a guide member 3304B. The groove 62 includes a portion 62E that is formed in the lower surface of the portion 33E and a portion 62F that is formed in the lower surface of the portion 33F. In this embodiment, the groove 62 (62E and 62F) has a slit shape. At least a portion of the liquid LQ flowing from the space SP1 is guided by the groove 62 and then is moved to the space SP2 (immersion space LS2).

In the above-described embodiments, the first member 31 may be movable. For example, the first member 31 may be movable in the Z-axis direction.

### Fifth Embodiment

Next, a fifth embodiment will be described. In the following description, components which are the same as or similar to those in the above-described embodiments are denoted by the same reference numerals and a description thereof is abbreviated or omitted here.

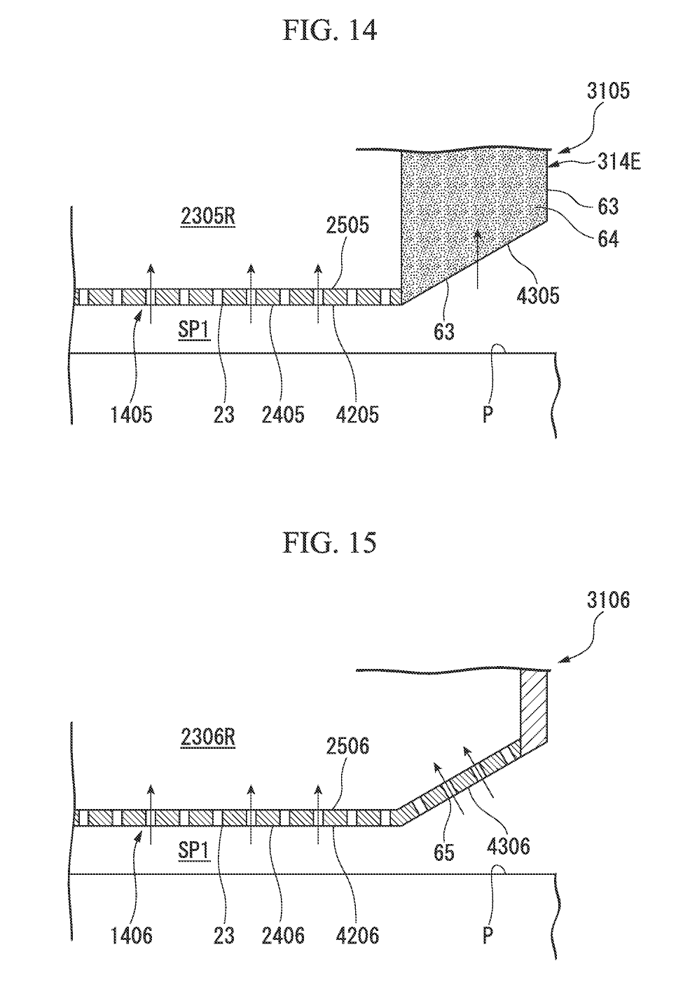

FIG. 14 is a diagram illustrating an example of a lower surface 1405 of a first member 3105 according to the fifth embodiment. In this embodiment, the lower surface 1405 includes a lower surface 4205 of a porous member 2405 in which recovery ports 23 for recovering a liquid LQ are provided and an inclined plane 4305 that is provided outside the lower surface 4205 with respect to an optical path K so as to face a space SP1 and is inclined upward to the outside in a radiation direction for the optical path K.

In this embodiment, the inclined plane 4305 is arranged in an outer edge region including the outer edge of the lower surface 1405. The distance between the inclined plane 4305 and the upper surface of a substrate P (object) is more than the distance between the lower surface 4205 and the upper surface of the substrate P (object).

In this embodiment, the first member 3105 includes recovery ports 63 that are provided in the inclined plane 4305 and can recover the liquid LQ.

In this embodiment, the inclined plane 4305 includes the lower surface of the porous member 64 in which a plurality of recovery ports 63 are formed.

In this embodiment, the porous member 2405 is a plate-shaped member. The porous member 2405 includes the lower surface 4205 that faces the upper surface of the substrate P (object), an upper surface 2505 opposite to the lower surface 4205, and a plurality of holes that are formed so as to connect the lower surface 4205 and the upper surface 2505.

In this embodiment, the porous member 64 and the porous member 2405 have different structures. In this embodiment, the porous member 64 is formed by, for example, a sintering method.

In the following description, the porous member 2405 is appropriately referred to as a mesh member 2405 and the porous member 64 is appropriately referred to as a porous member 64.

In this embodiment, at least a portion of the outer surface 314E of the first member 3105 includes the surface of the porous member 64. In this embodiment, the recovery ports 63 are provided in at least a portion of the outer surface 314E.

A space 2305R which faces the upper surface 2505 of the mesh member 2405 is connected to a liquid recovery device including a vacuum system. The liquid LQ in the space SP1 is recovered from the recovery ports 23 of the mesh member 2405.

The porous member 64 is connected to a fluid suction device including a vacuum system. For example, the liquid LQ which comes into contact with the inclined plane 63 is recovered from the recovery ports 63 provided in the inclined plane 4305.

In this embodiment, since the first member 3105 includes the inclined plane 4305, the occurrence of a so-called bridge phenomenon is prevented. In addition, in this embodiment, since the recovery ports 63 are provided in the inclined plane 4305, at least a portion of the liquid LQ moved from, for example, the space SP1 to the space SP2 (immersion space LS2) can be recovered from the recovery port 63. Therefore, it is possible to reduce the amount (for example, mass) of liquid LQ moved from the space SP1 to the space SP2 (immersion space LS2). In addition, in this embodiment, since the inclined plane 4305 is formed by the porous member 64, it is possible to restrict the movement of the liquid LQ from the space SP1 to the space SP2. For example, at least a portion of the liquid LQ moved from the space SP1 to the space SP2 can be thinned down or divided.

In this embodiment, the recovery ports 63 are connected to the fluid suction device including the vacuum system and the fluid suction device recovers the liquid LQ which comes into contact with the inclined plane 4305 from the recovery ports 63. However, the recovery ports 63 may also not be connected to the fluid suction device. Since the inclined plane 4305 is formed by the porous member 64, it is possible to prevent the occurrence of the bridge phenomenon in the inclined plane 4305. In addition, for example, even when the bridge phenomenon temporarily occurs between the porous member 64 and the substrate P, no foreign material (contaminant) remains on the substrate P and the bridge phenomenon is resolved since the liquid LQ which causes the bridge phenomenon, is absorbed to the porous member 64. In addition, since the outer edge region of the lower surface 1405 is formed by the porous member 64, it is possible to restrict the movement of the liquid LQ from the space SP1 to the space SP2. For example, the porous member 64 can absorb or capture at least a portion of the liquid LQ moved from the space SP1 to the space SP2.

### Sixth Embodiment

Next, a sixth embodiment will be described. In the following description, components which are the same as or similar to those in the above-described embodiments are denoted by the same reference numerals and a description thereof abbreviated or omitted here.

FIG. 15 is a diagram illustrating an example of a first member 3106 according to the sixth embodiment. In FIG. 15, a lower surface 1406 of the first member 3106 includes a lower surface 4206 which is arranged so as to face the upper surface of a substrate P and in which recovery ports 23 for recovering a liquid LQ are provided and an inclined plane 4306 which is provided outside the lower surface 4206 with respect to an optical path K so as to face a space SP1 and is inclined upward to the outside in a radiation direction for the optical path K.

In this embodiment, the first member 3106 includes a plurality of recovery ports 23 which are provided in the lower surface 4206 and can recover the liquid LQ and a plurality of recovery ports 65 which are provided in the inclined plane 4306 and can recover the liquid LQ.

In this embodiment, the inclined plane 4306 is arranged in an outer edge region including the outer edge of the lower surface 1406. The distance between the inclined plane 4306 and the upper surface of the substrate P (object) is more than the distance between the lower surface 4206 and the upper surface of the substrate P (object).

In this embodiment, the lower surface 4206 includes a lower surface of a mesh member 2406 including a plurality of recovery ports 23. The inclined plane 4306 includes a lower surface of a mesh member including a plurality of recovery ports 65. In this embodiment, the mesh member 2406 including the recovery ports 23 and the mesh member including the recovery ports 65 are integrated with each other. In this embodiment, the mesh member 2406 is bent to form the lower surface 4206 and the inclined plane 4306.

A space 2306R which faces an upper surface 2506 of the mesh member 2406 is connected to a liquid recovery device including a vacuum system. The liquid LQ in the space SP1 is recovered from the recovery ports 23 and 65 of the mesh member 2406. At least a portion of the liquid LQ moved from the space SP1 to a space SP2 (immersion space LS2) is recovered from the recovery ports 65 provided in the inclined plane 4306. Therefore, it is possible to restrict the movement of the liquid LQ from the space SP1 to the space SP2 (immersion space LS2). For example, it is possible to reduce the amount (for example, mass) of liquid LQ moved from the space SP1 to the space SP2 (immersion space LS2). In this embodiment, since the inclined plane 4305 is formed by the mesh member 2406, it is possible to capture or divide at least a portion of the liquid LQ moved from the space SP1 to the space SP2. In addition, in this embodiment, the occurrence of a so-called bridge phenomenon is prevented.

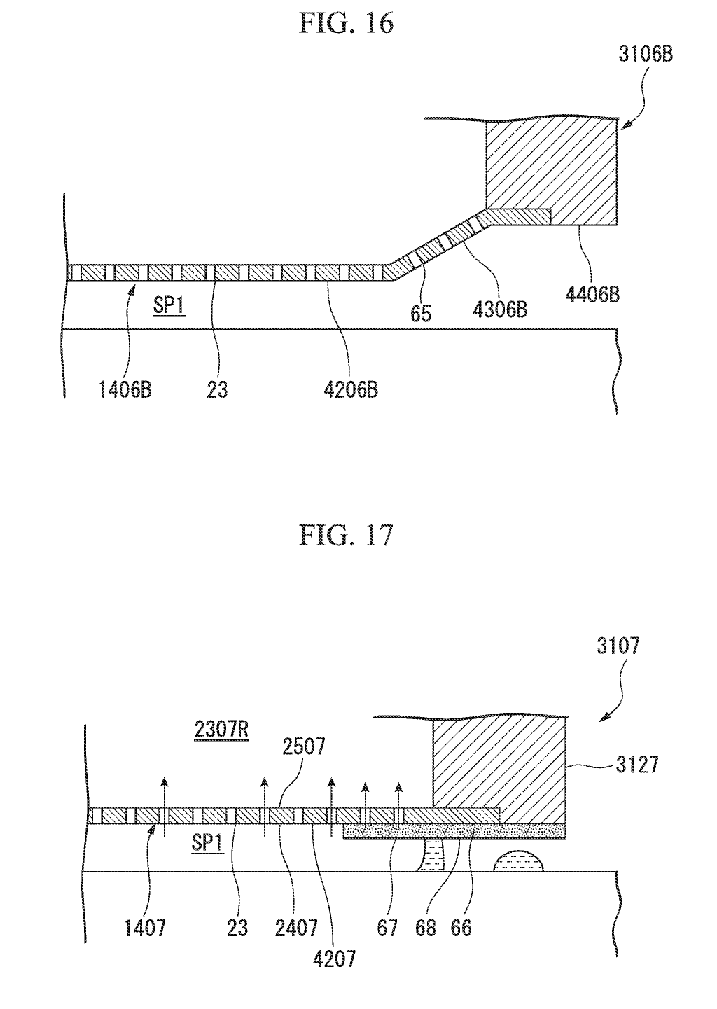

For example, as shown in FIG. 16, a lower surface 1406B of a first member 3106B may include a lower surface 4206B including recovery ports 23, an inclined plane 4306B which is provided outside the lower surface 4206B with respect to the optical path K and includes recovery ports 65, and a lower surface 4406B that is provided outside the inclined plane 4306B with respect to the optical path K and does not include the recovery port. That is, the recovery ports may be provided in an outer edge region including the outer edge of the lower surface 1406B in the lower surface 1406B. The distance between the lower surface 4406B and the upper surface of the substrate P is more than the distance between the lower surface 4206B and the upper surface of the substrate P and the distance between the inclined plane 4306B and the upper surface of the substrate P.

### Seventh Embodiment

Next, a seventh embodiment will be described. In the following description, components which are the same as or similar to those in the above-described embodiments are denoted by the same reference numerals and a description thereof is abbreviated or omitted here.

FIG. 17 is a diagram illustrating an example of a first member 3107 according to the seventh embodiment. In FIG. 17, the first member 3107 includes a mesh member 2407 and a porous member 66 that is connected to an outer edge region of a lower surface 4207 of the mesh member 2407. The lower surface 1407 of the first member 3107 includes the lower surface 4207 of the mesh member 2407 and a lower surface 67 of the porous member 66. In this embodiment, recovery ports 68 which are provided in the outer edge region of the lower surface 1407 include holes of the porous member 66.

In this embodiment, there is a difference in level between the lower surface 4207 of the mesh member 2407 and the lower surface 67 of the porous member 66. In this embodiment, the distance between the lower surface 4207 of the mesh member 2407 and the upper surface of a substrate P (object) is more than the distance between the lower surface 67 of the porous member 66 and the upper surface of the substrate P (object).

In this embodiment, for example, the mesh member 2407 and the porous member 67 are welded to each other.

The mesh member 2407 is supported by a main portion 3127 of the first member 3107. The porous member 66 is supported by at least a portion of the mesh member 2407. In addition, the porous member 66 is supported by at least a portion of the main portion 3127.

An upper surface 2507 of the mesh member 2407 faces a space 2307R. The controller 4 forms negative pressure in the space 2307R in order to recover a liquid LQ in a space SP1 from the recovery ports 23. That is, the controller 4 adjusts the pressure of the space 2307R and/or the space SP1 such that the pressure of the space 2307R is lower than that of the space SP1. In this embodiment, the pressure of the space 2307R is controlled by a liquid recovery device. The pressure of the space SP1 is controlled by a chamber device CH.

When the space 2307R is at negative pressure, at least a portion of the liquid LQ in the space SP1 is recovered from the holes (recovery ports 23) of the mesh member 2407. The liquid LQ recovered from the holes (recovery ports 23) of the mesh member 2407 flows to the space 2307R. In this embodiment, at least a portion of the liquid LQ in the space SP1 is recovered from the holes (recovery ports 68) of the porous member 66. The liquid LQ recovered from the holes (recovery ports 68) of the porous member 66 flows to the space through the holes (recovery ports 23) of the mesh member 2407.

In this embodiment, at least a portion of the liquid LQ in the space SP1 which comes into contact with the lower surface 4207 (recovery port 23) of the mesh member 2407 flows to the space 2307R through the holes (recovery ports 23) of the mesh member 2407. At least a portion of the liquid LQ in the space SP1 which comes into contact with the lower surface 67 (recovery port 68) of the porous member 66 flows to the space through the holes of the porous member 66 and the holes of the mesh member 2407.

As described above, in this embodiment, since the recovery port 68 is provided in the outer edge region of the lower surface 1407, the bridge phenomenon is prevented from occurring. In addition, for example, even when the bridge phenomenon temporarily occurs between the porous member 66 and the substrate P, no foreign material (contaminant) remains on the substrate P and the bridge phenomenon is resolved since the liquid LQ causing the bridge phenomenon, is absorbed by the porous member 66.

In this embodiment, it is possible to restrict the movement of the liquid LQ from the space SP1 to the space SP2. For example, it is possible to divide, capture, or suction the liquid LQ moved from the space SP1 to the space SP2. That is, it is possible reduce the amount of liquid LQ moved from the space SP1 to the space SP2 between the space SP1 and the space SP2.

### Eighth Embodiment

Next, an eighth embodiment will be described. In the following description, components which are the same as or similar to those in the above-described embodiments are denoted by the same reference numerals and a description thereof is abbreviated or omitted here.

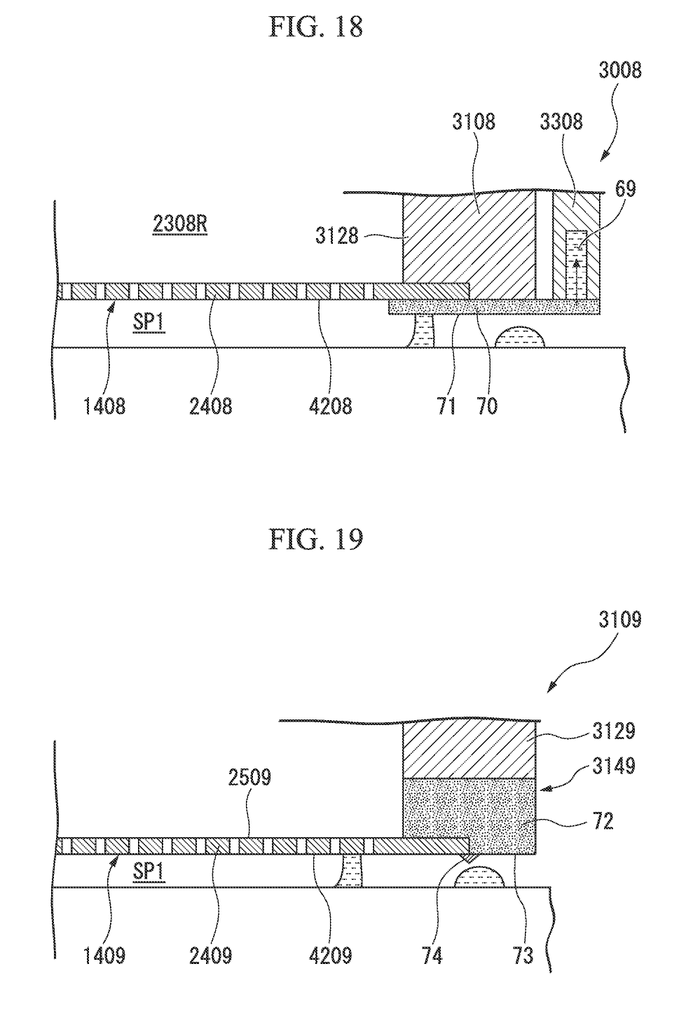

FIG. 18 is a diagram illustrating an example of a liquid immersion member 3008 according to an eighth embodiment. In FIG. 18, the liquid immersion member 3008 includes a first member 3108 having a space 2308R formed therein and a recovery member 3308 that is provided on at least a portion of the periphery of the first member 3108 and that has a space 69 formed therein.

In addition, the liquid immersion member 3008 includes a mesh member 2408 and a porous member 70. A lower surface 1408 of the liquid immersion member 3008 includes a lower surface 4208 of the mesh member 2408 and a lower surface 71 of the porous member 70.

The mesh member 2408 is supported by at least a part of a main portion 3128 of the first member 3108. At least a portion of the porous member 70 is connected to an outer edge region of the lower surface 4208 of the mesh member 2408. In addition, at least a portion of the porous member 70 is supported by the main portion 3128 and the recovery member 3308.

A liquid recovery device including a vacuum system is connected to the space 2308R. The liquid recovery device including the vacuum system is also connected to the space 69. A liquid LQ which has flowed to the space 2308R through holes (recovery ports) of the mesh member 2408 is recovered by a liquid recovery device.

The liquid LQ which has flowed to the space 69 through holes (recovery ports) of the porous member 70 is recovered by the liquid recovery device.

In the example shown in FIG. 18, since the recovery port is provided in the outer edge region of the lower surface 1408, the bridge phenomenon is prevented from occurring. In addition, for example, even when the bridge phenomenon temporarily occurs between the porous member 70 and the substrate P, no foreign material (contaminant) remains on the substrate P and the bridge phenomenon is resolved since the liquid LQ causing the bridge phenomenon, is absorbed by the porous member 70.

In this embodiment, it is possible to restrict the movement of the liquid LQ from the space SP1 to the space SP2. For example, it is possible to divide, capture, or suction the liquid LQ moved from the space SP1 to the space SP2. That is, it is possible to reduce the amount of liquid LQ moved from the space SP1 to the space SP2 between the space SP1 and the space SP2.

### Ninth Embodiment

Next, a ninth embodiment will be described. In the following description, components which are the same as or similar to those in the above-described embodiments are denoted by the same reference numerals and a description thereof is abbreviated or omitted here.

FIG. 19 is a diagram illustrating an example of a first member 3109 according to the ninth embodiment. In FIG. 19, the first member 3109 includes a mesh member 2409 and a porous member 72 at least a portion of which is connected to an outer edge region of an upper surface 2509 of the mesh member 2409. In this embodiment, at least a portion of a lower surface 73 of the porous member 72 is connected to the upper surface 2509 of the mesh member 2409. At least a portion of the upper surface of the porous member 72 is connected to a main portion 3129 of the first member 3109.

In this embodiment, a lower surface 1409 of the first member 3109 includes a lower surface 4209 of the mesh member 2409 and a lower surface 73 of the porous member 72, An outer edge region of the lower surface 1409 includes the lower surface 73 of the porous member 72. In this embodiment, recovery ports provided in the outer edge region of the lower surface 1409 include holes of the porous member 72 which is provided outside the outer edge of the mesh member 2409. In this embodiment, the lower surface 4209 of the mesh member 2409 and the lower surface 73 of the porous member 72 which is provided outside the lower surface 4209 of the mesh member 2409 are substantially flush with each other (arranged in the same plane). The position (height) of the lower surface 4209 of the mesh member 2409 may be different from the position (height) of the lower surface 73 of the porous member 72 in the Z-axis direction.

In this embodiment, the mesh member 2409 and at least a portion of the porous member 72 may be welded to each other. In this embodiment, the outer edge of the lower surface 4209 of the mesh member 2409 is welded to a portion of the lower surface 73 of the porous member 72. The lower surface 73 of the porous member 72 is arranged outside a welded portion 74 in the radiation direction for an optical path K.

The liquid LQ in the space SP1 is recovered from the holes of the mesh member 2409 and/or the holes of the porous member 72.

In this embodiment, at least a portion of an outer surface 3149 of the first member 3109 includes the surface of the porous member 72. That is, the holes (recovery ports) of the porous member 72 are provided in at least a portion of the outer surface 3149.

In this embodiment, since the recovery ports are provided in the outer edge region of the lower surface 1409, the bridge phenomenon is prevented from occurring. In addition, for example, even when the bridge phenomenon temporarily occurs between the porous member 72 and the substrate P, no foreign material (contaminant) remains on the substrate P and the bridge phenomenon is resolved since the liquid LQ causing the bridge phenomenon, is absorbed by the porous member 72.

In this embodiment, it is possible to restrict the movement of the liquid LQ from the space SP1 to the space SP2. For example, it is possible to divide, capture, or suction the liquid LQ moved from the space SP1 to the space SP2. That is, it is possible to reduce the amount of liquid LQ moved from the space SP1 to the space SP2 between the space SP1 and the space SP2.

### Tenth Embodiment

Next, a tenth embodiment will be described. In the following description, components which are the same as or similar to those in the above-described embodiments are denoted by the same reference numerals and a description thereof is abbreviated or omitted here.

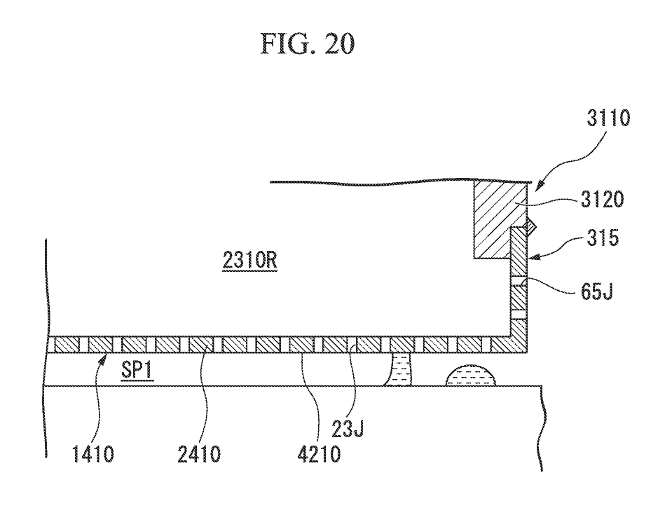

FIG. 20 is a diagram illustrating an example of a first member 3110 according to the tenth embodiment. In FIG. 20, a lower surface 1410 of the first member 3110 includes a lower surface 4210 of a mesh member 2410. In this embodiment, recovery ports 653 which can recover a liquid LQ are provided in at least a portion of an outer surface 315 of the first member 3110.

In this embodiment, an outer edge region including the outer edge of the lower surface 1410 includes the lower surface 4210 of the mesh member 2410. In this embodiment, the mesh member 2410 is bent. The outer surface 315 includes the lower surface (outer surface) of the mesh member 2410. The inner surface of the mesh member 2410 opposite to the outer surface faces a space 2310R.

In this embodiment, the upper end of the outer surface of the mesh member 2410 forming the outer surface 315 is welded to a portion of the outer surface of the main portion 3120 of the first member 3110.

At least a portion of the liquid LQ in the space SP1 is recovered from recovery ports 23J which are provided in the lower surface 4210 of the mesh member 2410 forming the lower surface 1410. In addition, at least a portion of the liquid LQ is recovered from the recovery ports 65J which are provided in the outer surface of the mesh member 2410 forming the outer surface 315. The liquid LQ recovered from the recovery ports 23J and 65J of the mesh member 2410 flows into the space 2310R.

In this embodiment, since the recovery ports 23J are provided in the outer edge region of the lower surface 1410, the bridge phenomenon is prevented from occurring. In addition, in this embodiment, since the recovery ports 65J are provided in the lower end region including the lower end of the outer surface 315, the bridge phenomenon is prevented from occurring by the liquid LQ which is arranged so as to come into contact with, for example, the outer edge of the lower surface 1410 and/or the lower end of the outer surface 315.

In this embodiment, it is possible to restrict the movement of the liquid LQ from the space SP1 to the space SP2. For example, it is possible to divide, capture, or suction the liquid LQ moved from the space SP1 to the space SP2. That is, it is possible to reduce the amount of liquid LQ moved from the space SP1 to the space SP2 between the space SP1 and the space SP2.

### Eleventh Embodiment

Next, an eleventh embodiment will be described. In the following description, components which are the same as or similar to those in the above-described embodiments are denoted by the same reference numerals and a description thereof is abbreviated or omitted here.

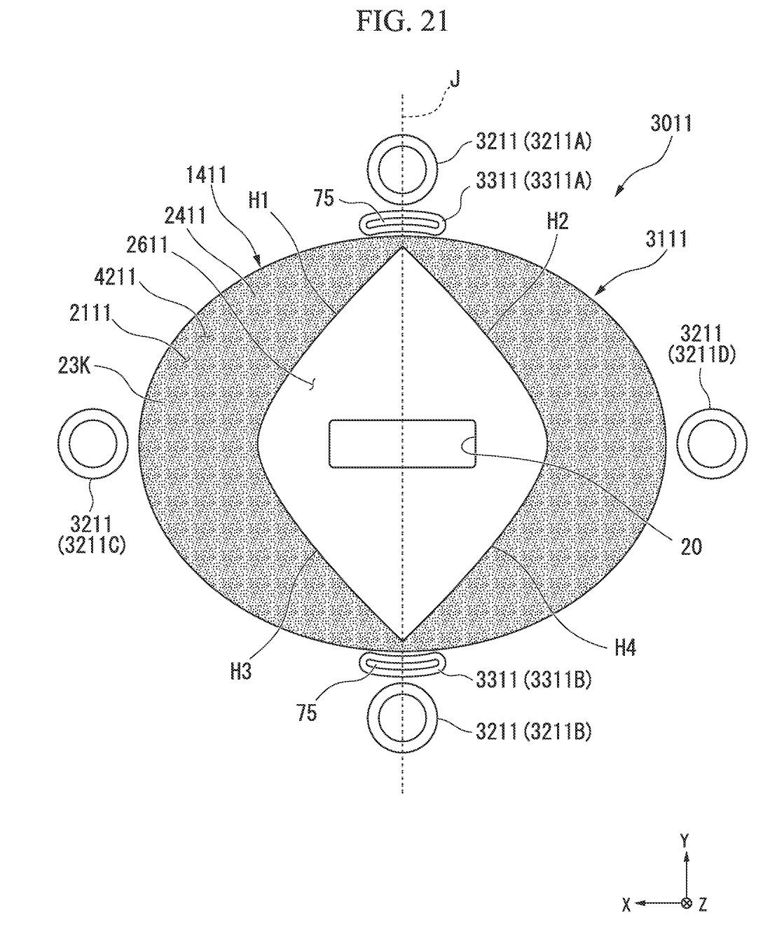

FIG. 21 is a diagram illustrating a liquid immersion member 3011 according to the eleventh embodiment, as viewed from the lower side. In FIG. 21, the outer shape of a lower surface 1411 of a first member 3111 is an ellipse. In this embodiment, the major axis of the elliptical lower surface 1411 is substantially parallel to the X-axis. The major axis may be parallel to the Y-axis.

In this embodiment, the lower surface 1411 includes a surface 2611 that is arranged around an opening 20 through which exposure light EL emitted from an emission surface 7 passes and that cannot recover a liquid LQ and a recovery surface 2111 that is arranged around the surface 2611 and can recover the liquid LQ. In this embodiment, the surface 2611 is a plane. The recovery surface 2111 includes a lower surface 4211 of a porous member 2411 including a plurality of recovery ports 23.

In this embodiment, the surface 2611 includes a first side H1, a second side H2, a third side H3, and a fourth side H4.

The first side H1 is arranged so as to extend from the +X side of an axis J passing through a space SP2 to a guide space A in the plane (XY plane) which is substantially parallel to the upper surface of a substrate P (object). The second side H2 is arranged so as to extend from the −X side of the axis J passing through the space SP2 to the guide space A in the plane (XY plane) which is substantially parallel to the upper surface of a substrate P (object).

In this embodiment, in the plane (XY plane) substantially parallel to the substrate P (object), the gap between the first side H1 and the second side H2 in a direction (X-axis direction) perpendicular to the axis J is reduced toward the guide space A.

The third side H3 is arranged so as to extend from the +X side of the axis J passing through the space SP2 to the guide space A in the plane (XY plane) which is substantially parallel to the upper surface of the substrate P (object). The fourth side H4 is arranged so as to extend from the −X side of the axis J passing through the space SP2 to the guide space A in the plane (XY plane) which is substantially parallel to the upper surface of a substrate P (object).

In this embodiment, in the plane (XY plane) substantially parallel to the substrate P (object), the gap between the third side H3 and the fourth side H4 in the direction (X-axis direction) perpendicular to the axis J is reduced toward the guide space A.

In this embodiment, the angle formed between the first side H1 and the second side H2 is an acute angle. The angle formed by the first side H1 and the second side H2 is acute. In this embodiment, the angle formed the third side H3 and the fourth side H4 is an acute angle. The angle formed by the third side H3 and the fourth side H4 is acute.

In this embodiment, the angle formed by the first side H1 and the third side H3 is an obtuse angle. The angle formed by the first side H1 and the third side H3 is obtuse. In this embodiment, the angle formed by the second side H2 and the fourth side H4 is an obtuse angle. The angle formed by the second side H2 and the fourth side H4 is obtuse.

In this embodiment, an outer edge region including the outer edge of the lower surface 1411 includes the lower surface 4211 (recovery surface 2111) of the porous member 2411. In this embodiment, the outer shape of the lower surface 4211 of the porous member 2411 in the XY plane is an ellipse.

In this embodiment, four second members 3211 are provided around the first member 3111. In this embodiment, the second members 3211 includes a second member 3211A that is provided on the +Y side of the optical path K, a second member 3211B that is provided on the −Y side of the optical path K, a second member 3211C that is provided on the +X side of the optical path K, and a second member 3211D that is provided on the −X side of the optical path K. In this embodiment, the shape (outer shape) of an immersion space LS2 formed by the second members 3211 in the XY plane is almost a circle.

In this embodiment, a third member 3311 includes a third member 3311A that is provided between the first member 3111 and the second member 3211A arranged on the +Y side of the optical path K and a third member 3311B that is provided between the first member 3111 and the second member 3211B arranged on the −Y side of the optical path K. In this embodiment, the third member 3311 is not provided between the first member 3111 and the second member 3211C arranged on the +X side of the optical path K and between the first member 3111 and the second member 3211D arranged on the −X side of the optical path K. However, the third member 3311 may be provided therebetween.

In this embodiment, the third member 3311 includes a suction port 75 that suctions a fluid. The suction port 75 is provided at a position where it can face the substrate P. In this embodiment, the suction port 75 has a slit shape extending in the X-axis direction. The third member 3311 may include the porous member or the guide member according to the above-described embodiments.

In this embodiment, the occurrence of an exposure defect and a device is prevented from being defective. In this embodiment, the second members 3211 for forming the immersion space LS2 are provided on the +X and −X sides of the optical path K in addition to the +Y and −Y sides of the optical path K. Therefore, for example, even when the substrate P is moved in the X-axis direction and the liquid LQ flows from the space SP1 in at least one of the +X direction and the −X direction, with the immersion space LS1 being formed, recovery ports 52 of the second member 3211 can recover the liquid LQ flowing from the space SP1. The recovery ports 52 can recover the liquid LQ flowing from the space SP1 and the liquid LQ in the immersion space LS2.

### Twelfth Embodiment

Next, a twelfth embodiment will be described. In the following description, components which are the same as or similar to those in the above-described embodiments are denoted by the same reference numerals and a description thereof is abbreviated or omitted here.

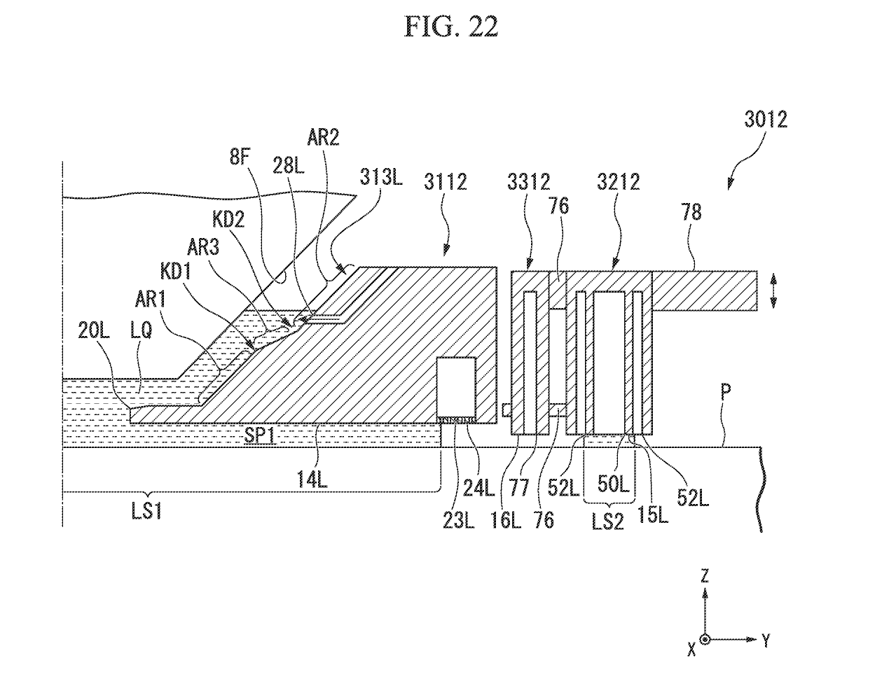

FIG. 22 is a diagram illustrating an example of a liquid immersion member 3012 according to the twelfth embodiment. In FIG. 22, the liquid immersion member 3012 includes a first member 3112, a second member 3212, and a third member 3312 that is provided between the first member 3112 and the second member 3212.

In this embodiment, an inner surface 313L of the first member 3112 which faces a side surface 8F of a termination optical element 8 includes a first region AR1, a second region AR2 that is provided above the first region AR1, and a third region AR3 that is provided between the first region AR1 and the second region AR2 and faces a direction different from the direction in which the first region AR1 and the second region AR2 face. In this embodiment, an angular portion KD1 is formed between the first region AR1 and the third region AR3. An angular portion KD2 is formed between the third region AR3 and the second region AR2.

In this embodiment, a supply port 28L that supplies a liquid LQ to an optical path K is provided in the second region AR2. The liquid LQ supplied from the supply port 28L flows through at least a portion of the gap between the side surface 8F and the inner surface 313L and is then supplied to a space SP1 through an opening 20L.

The first member 3112 includes recovery ports 23L provided at a position where they can face a substrate P. In this embodiment, the first member 3112 includes a porous member 24L. The recovery ports 23L include holes of the porous member 24L.

The second member 3212 includes a supply port 50L that supplies the liquid LQ and a recovery port 52L that recovers the liquid LQ. The second member 3212 forms an immersion space LS2 in a portion of the periphery of an immersion space LS1.

In this embodiment, the third member 3312 is supported by the second member 3212. In this embodiment, the second member 3212 and the third member 3312 are connected to each other by a connection member 76. In this embodiment, the third member 3312 includes a suction port 77 provided at a position where it can face the substrate P.

In this embodiment, the liquid immersion member 3012 includes a driving device 78 that moves the second member 3212 in the Z-axis direction. The driving device 78 is controlled by a controller 4. The controller 4 can control the driving device 78 to move the second member 3212 in the Z-axis direction such that the distance between the lower surface 15L of the second member 3212 and the upper surface of the substrate P (object) is reduced. In addition, the controller 4 can control the driving device 78 to move the second member 3212 in the Z-axis direction such that the distance between the lower surface 15L of the second member 3212 and the upper surface of the substrate P (object) increases.

In this embodiment, the third member 3312 is connected to the second member 3212. When the second member 3212 is moved in the Z-axis direction, the third member 3312 is moved such that the lower surface 16L of the third member 3312 and the upper surface of the substrate P (object) increases or decreases.

The third member 3312 may also not be connected to the second member 3212. In addition, a driving device that can move the third member 3312 in the Z-axis direction may be provided separately from the driving device 78 that moves the second member 3212 in the Z-axis direction. The third member 3312 may be moved independently from the second member 3212 by the driving device which can move the third member 3312. The second member 3212 may be moved in the Z-axis direction and the position of the third member 3312 may be fixed. The third member 3312 may be moved in the Z-axis direction and the position of the second member 3212 may be fixed.

In this embodiment, the position of the first member 3112 is fixed. In addition, a driving device that can move the first member 3112 may be provided and the first member 3112 may be moved in the Z-axis direction by the driving device.

In this embodiment, the controller 4 controls the positions of the second member 3212 and the third member 3312 in the Z-axis direction such that the second member 3212 and the third member 3312 do not contact the substrate P (object). In this embodiment, the controller 4 controls the position of the second member 3212 in the Z-axis direction such that the distance between the lower surface 15L of the second member 3212 and the upper surface of the substrate P (object) is less than the distance between the lower surface 14L of the first member 3112 and the upper surface of the substrate P (object).

For example, when the distance between the lower surface 14L of the first member 3112 and the upper surface of the substrate P (object) is set to 0.5 mm to 1.0 mm, the controller 4 may control the driving device such that the distance between the lower surface 15L of the second member 3212 and the upper surface of the substrate P (object) is in the range of 0.1 mm to 0.2 mm.

As described above, in this embodiment, the liquid LQ which has flowed from the space SP1 and the liquid LQ in the immersion space LS2 are recovered from the recovery ports 52L of the second member 3212. Therefore, it is possible to prevent the occurrence of an exposure defect or occurrence of a defective device.

### Thirteenth Embodiment

Next, a thirteenth embodiment will be described. In the following description, components which are the same as or similar to those in the above-described embodiments are denoted by the same reference numerals and a description thereof is abbreviated or omitted here.

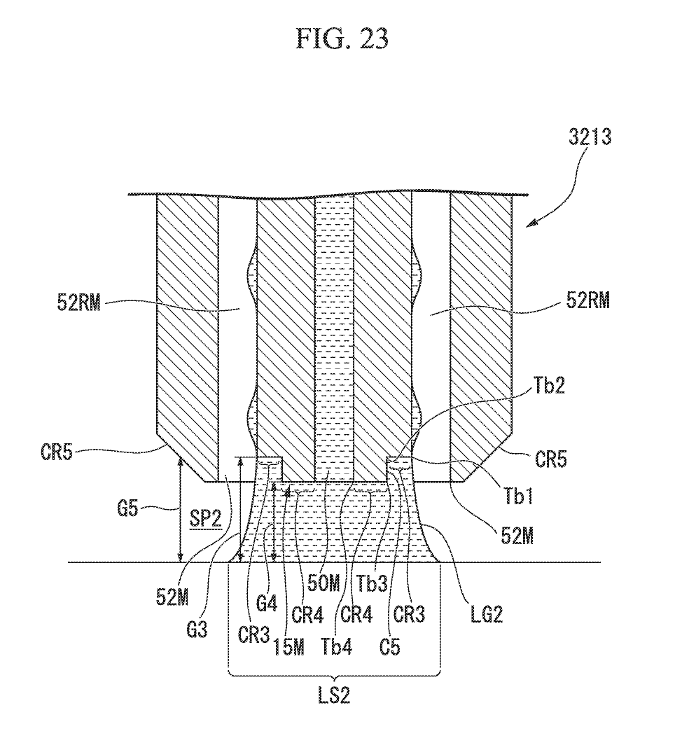

FIG. 23 is a diagram illustrating an example of a second member 3213 according to the thirteenth embodiment. In FIG. 23, the second member 3213 includes a supply port 50M that is provided so as to face the upper surface of a substrate P and supplies a liquid LQ and recovery ports 52M that are provided so as to face the upper surface of the substrate P and recover the liquid LQ. In this embodiment, the supply port 50M and the recovery ports 52M are provided in a lower surface 15M of the second member 3213 which can face the upper surface of the substrate P.

In this embodiment, the recovery port 52M is arranged in at least a portion of the periphery of the supply port 50M. In this embodiment, the liquid LQ is recovered from the recovery port 52M in parallel with at least a portion of the supply of the liquid LQ from the supply port 50M. In this way, an immersion space LS2 is formed by the liquid LQ between the second member 3213 and the substrate P (object). The recovery port 52M recovers the liquid LQ flowing from the space SP1 and the liquid LQ in an immersion space LS2.

In this embodiment, the lower surface 15M of the second member 3213 includes a region CR3 that is provided in at least a portion of the periphery of the recovery port 52M and faces the upper surface of the substrate P (object) with a gap G3 therebetween and a region CR4 that is provided outside the region CR3 with respect to the recovery port 52M and faces the upper surface of the substrate P (object) with a gap G4 less than the gap G3 therebetween.

In this embodiment, the region CR3 is arranged between the recovery port 52M and the supply port 50M. The region CR3 is arranged in a portion of the periphery of the recovery port 52M. In this embodiment, an end portion Tb1 of the region CR3 is arranged in a portion of the periphery of the recovery port 52M. An end portion Tb2 of the region CR3 is connected to an end portion Tb3 of the region CR4 by a connection surface C5. In the XY plane, at least a portion of the region CR4 is arranged between the end portion Tb3 of the region CR3 and the supply port 50M. An end portion Tb3 of the region CR4 is connected to the lower end of a connection surface C3. An end portion Tb4 of the region CR4 is arranged in at least a portion of the periphery of the supply port 50M.

In this embodiment, the lower surface 15M of the second member 3213 includes a region CR5 that is provided in at least a portion of the periphery of the recovery port 52M and that faces the upper surface of the substrate P (object) with a gap G5 therebetween. The dimensions of the gap G5 are more than those of the gap G4. In this embodiment, the distance between a portion of the region CR5 and the upper surface of the substrate P is more than that between the region CR3 and the upper surface of the substrate P and the distance between a portion of the region CR5 and the upper surface of the substrate P is less than that between the region CR3 and the upper surface of the substrate P. In this embodiment, the region CR5 is inclined upward to the outside in the radiation direction having the supply port 50M as the center.

In this embodiment, the region CR3 is substantially perpendicular to the connection surface C5.

The region CR4 is arranged closer to the center of the immersion space LS2 than the region CR3, with the immersion space LS2 being formed. In addition, the region CR4 is arranged closer to the supply port 50M than the region CR3, with the immersion space LS2 being formed. The region CR3 is arranged closer to an interface LG2 of the liquid LQ in the immersion space LS2 than the region CR4. In this embodiment, the interface LG2 of the liquid LQ in the immersion space LS2 is formed between the region CR3 and the upper surface of the substrate P (object). In addition, the interface LG2 of the liquid LQ in the immersion space LS2 may be formed between the recovery port 52M (the inner surface of an internal passageway 52RM connected to the recovery port 52M) and the upper surface of the substrate P (object).

In this embodiment, since the distance between the lower surface 15M (region CR3) and the upper surface of the substrate P (object) in the vicinity of the interface LG2 of the liquid LQ in the immersion space LS2 is more than the distance between the lower surface 15M (region CR4) and the upper surface of the substrate P (object) at the center of the immersion space LS2, the velocity gradient of the liquid LQ between the region CR3 and the upper surface of the substrate P (in the vicinity of the interface LG2) is reduced. Therefore, the viscosity of the liquid LQ between the region CR3 and the upper surface of the substrate P (in the vicinity of the interface LG2) is reduced. As a result, even when the substrate P (object) is moved in the XY plane with the immersion space LS2 being formed, the deformation of the interface LG2 of the liquid LQ is prevented. Therefore, the liquid LQ in the immersion space LS2 is prevented from flowing from the space SP2 or from being formed as a thin film on the substrate P (object). For example, when the substrate P (object) is moved in the +Y direction with the immersion space LS2 being formed, the deformation of the liquid LQ in the immersion space LS2 in the Y-axis direction (the deformation of the interface LG2) is prevented. For example, when the substrate P (object) is moved in the Y-axis direction with the immersion space LS2 being formed, an increase in the distance between an intersection point between the lower surface 15M and the interface LG2 in the Y-axis direction and an intersection point between the upper surface of the substrate P and the interface LG2 is prevented.

As described above, according to this embodiment, since there is a difference in level between the region CR3 and the region CR4 in a portion of the periphery of the recovery port 52M, it is possible to prevent the deformation of the interface LG2 of the liquid LQ in the immersion space LS2 and prevent the outflow of the liquid LQ.

### Fourteenth Embodiment

Next, a fourteenth embodiment will be described. In the following description, components which are the same as or similar to those in the above-described embodiments are denoted by the same reference numerals and a description thereof is abbreviated or omitted here.

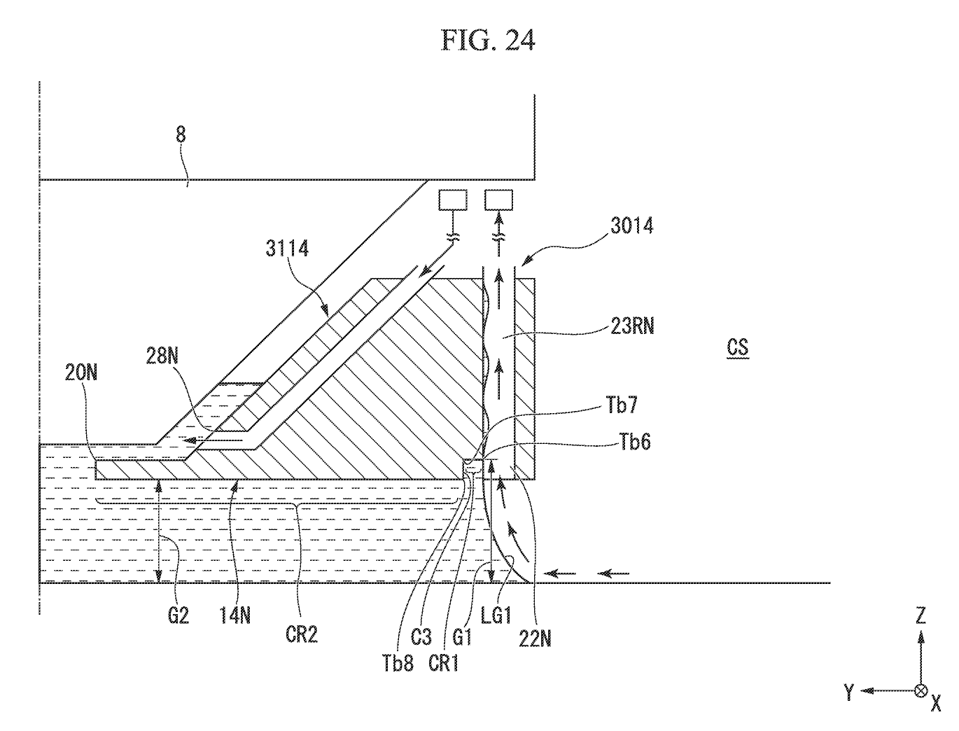

FIG. 24 is a diagram illustrating an example of a liquid immersion member 3014 according to a fourteenth embodiment. In FIG. 24, the liquid immersion member 3014 includes a first member 3114. In this embodiment, the liquid immersion member 3014 does not include a second member. That is, in this embodiment, an immersion space LS2 is not formed. In addition, the liquid immersion member 3014 may include the second member or it may form an immersion space LS2. Recovery ports of the second member may recover a liquid LQ flowing from a space SP1 and the liquid LQ in the immersion space LS2.

The first member 3114 includes a supply port 28N that supplies the liquid LQ to an optical path K and a recovery port 22N that is provided so as to face the upper surface of a substrate P and recovers a fluid (the liquid LQ and/or gas). The recovery port 22N is provided in the lower surface 14N of the first member 3114 which can face the substrate P. In this embodiment, the recovery port 22N recovers both the liquid LQ in an immersion space LS1 and gas around the immersion space LS1. For example, when the recovery port 22N recovers the fluid, at least a portion of the gas in a space CS flows into the recovery port 22N. When the fluid is recovered from the recovery port 22N in parallel with the supply of the liquid LQ from the supply port 28N, the immersion space LS1 is formed.

In this embodiment, the lower surface 14N of the first member 3114 includes a region CR1 that is arranged in at least a portion of the periphery of the recovery port 22N and faces the upper surface of the substrate P (object) with a gap G1 therebetween and a region CR2 that is provided outside the region CR1 with respect to the recovery port 22N and faces the upper surface of the substrate P (object) with a gap G2 less than the gap G1 therebetween.

In this embodiment, the region CR1 is arranged between the supply port 28N and the recovery port 22N in a radiation direction for the optical path K. The region CR1 is arranged in a portion of the periphery of the recovery port 22N. In this embodiment, an end portion Tb6 of the region CR1 is arranged in a portion of the periphery of the recovery port 22N. An end portion Tb7 of the region CR1 is connected to an end portion Tb8 of the region CR2 through a connection surface C3. In the XY plane, at least a portion of the region CR2 is arranged between the end portion Tb7 of the region CR1 and an opening 20N (supply port 28N). The end portion Tb8 of the region CR2 is connected to the lower end of the connection surface C3. An end portion Tb9 of the region CR2 is arranged in at least a portion of the periphery of the opening 20N.

In this embodiment, the region CR1 is substantially perpendicular to the connection surface C3.

The region CR2 is arranged closer to the center of the immersion space LS1 than the region CR1, with the immersion space LS1 being formed. In addition, the region CR2 is arranged closer to the opening 20N (supply port 28N) than the region CR1, with the immersion space LS1 being formed. The region CR1 is arranged closer to the interface LG1 of the liquid LQ in the immersion space LS1 than the region CR2. In this embodiment, the interface LG1 of the liquid LQ in the immersion space LS1 is formed between the region CR1 and the upper surface of the substrate P (object). The interface LG1 of the liquid LQ in the immersion space LS1 may be formed between the recovery port 22N (the inner surface of an internal passageway 23RN connected to the recovery port 22N) and the upper surface of the substrate P (object).

In this embodiment, since the distance between the lower surface 14N (region CR1) and the upper surface of the substrate P (object) in the vicinity of the interface LG1 of the liquid LQ in the immersion space LS1 is more than the distance between the lower surface 14N (region CR2) and the upper surface of the substrate P (object) at the center of the immersion space LS1, the velocity gradient of the liquid LQ between the region CR1 and the upper surface of the substrate P (in the vicinity of the interface LG1) is reduced. Therefore, the viscosity of the liquid LQ between the region CR1 and the upper surface of the substrate P (in the vicinity of the interface LG1) is reduced. As a result, even when the substrate P (object) is moved in the XY plane with the immersion space LS1 being formed, the deformation of the interface LG1 of the liquid LQ is prevented. Therefore, the liquid LQ in the immersion space LS1 is prevented from flowing from the space SP1 or from being formed as a thin film on the substrate P (object). For example, when the substrate P (object) is moved in the +Y direction with the immersion space LS1 being formed, the deformation of the liquid LQ in the immersion space LS1 in the Y-axis direction (the deformation of the interface LG1) is prevented. For example, when the substrate P (object) is moved in the Y direction with the immersion space LS1 being formed, an increase in the distance between an intersection point between the lower surface 14N and the interface LG1 in the Y-axis direction and an intersection point between the upper surface of the substrate P and the interface LG1 is prevented.

As described above, according to this embodiment, since there is a difference in level between the region CR1 and the region CR2 in a portion of the periphery of the recovery port 22N, it is possible to prevent the deformation of the interface LG1 of the liquid LQ in the immersion space LS1 and prevent the outflow of the liquid LQ.

### Fifteenth Embodiment

Next, a fifteenth embodiment will be described. In the following description, components which are the same as or similar to those in the above-described embodiments are denoted by the same reference numerals and a description thereof is abbreviated or omitted here.

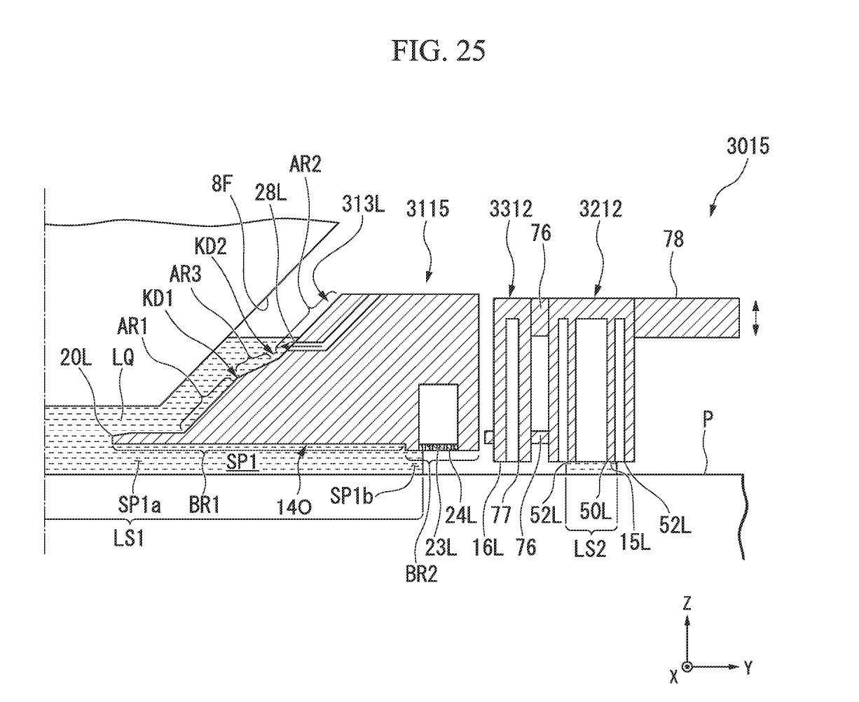

FIG. 25 is a diagram illustrating an example of a liquid immersion member 3015 according to a fifteenth embodiment. The fifteenth embodiment is a modification of the twelfth embodiment.

The liquid immersion member 3015 includes a first member 3115, a second member 3212, and a third member 3312 that is provided between the first member 3112 and the second member 3212.

In this embodiment, a lower surface 14O of the first member 3115 which faces an object, such as a substrate P, includes a region BR1 and a region BR2 that is provided outside the region BR1 with respect to the optical path K of exposure light EL emitted from an emission surface 7. In this embodiment, recovery ports 23L are provided in the region BR2. The region BR1 is arranged at a position (position on the +Z side) higher than the region BR2. That is, the distance between the region BR1 and the upper surface of the substrate P is more than that between the region BR2 and the upper surface of the substrate P. In this embodiment, the distance between the region BR1 and the upper surface of the substrate P is in the range of, for example, about 0.5 mm to 1.0 mm. The distance between the region BR2 and the upper surface of the substrate P is in the range of, for example, about 0.1 mm to 0.2 mm. There is a difference in level between the region BR1 and the region BR2.

A space SP1a which is filled with a liquid LQ in an immersion space LS1 is formed between the region BR1 and the substrate P. A space SP1b smaller than the space SP1a is formed between the region BR2 and the substrate P. The liquid LQ in the immersion space LS1 comes into contact with the region BR1. In addition, the liquid LQ in the immersion space LS1 comes into contact with at least a portion of the region BR2.

In this embodiment, since the region BR1 is fanned such that the distance from the upper surface of the object is more than that between the upper surface of the object and the region BR1, for example, the transmission of the vibration of an object, such as a substrate stage 2P, to the first member 3115 is prevented. In other words, the influence of the movement of the object on the first member 3115 is reduced.

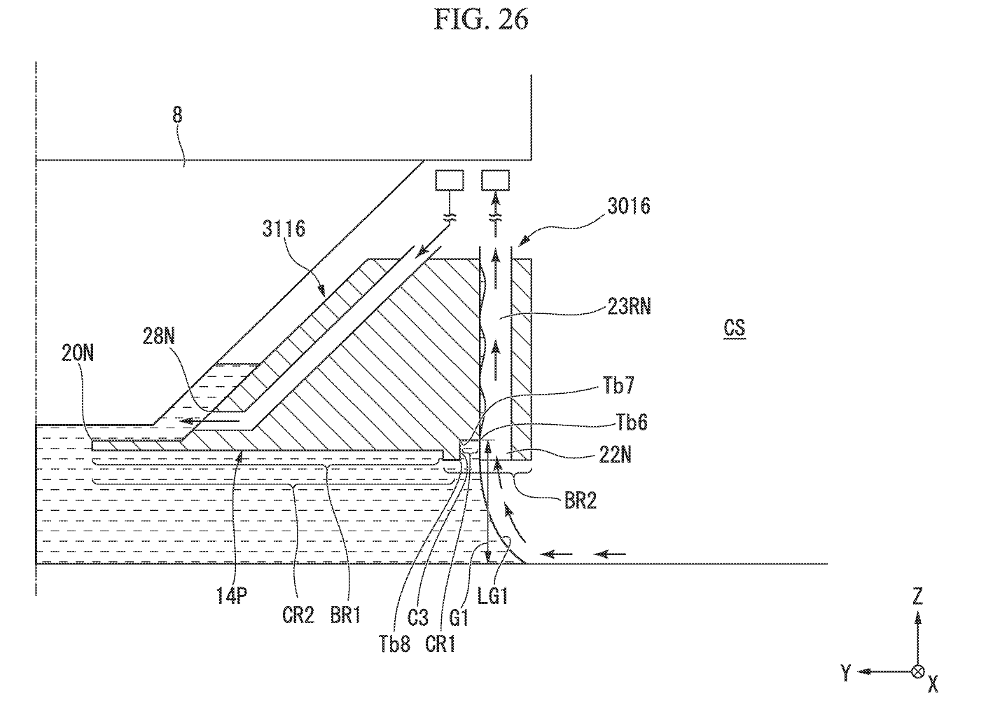

In this embodiment, the regions BR1 and BR2 are provided in the liquid immersion member 3012 according to the twelfth embodiment. However, the regions BR1 and BR2 may be provided in the lower surface of the first member (for example, 31) of the liquid immersion member (for example, 3) according to the first to eleventh, thirteenth, and fourteenth embodiments. For example, as shown in FIG. 26, the regions BR1 and BR2 may be provided in a lower surface 14P of a first member 3116.

In the above-described embodiments, the second members (32, 3212, 3213) may be movable. For example, the second members (32, 3212, 3213) may be movable in the Z-axis direction.

### Sixteenth Embodiment

Next, a sixteenth embodiment will be described. In the following description, components which are the same as or similar to those in the above-described embodiments are denoted by the same reference numerals and a description thereof is abbreviated or omitted here.

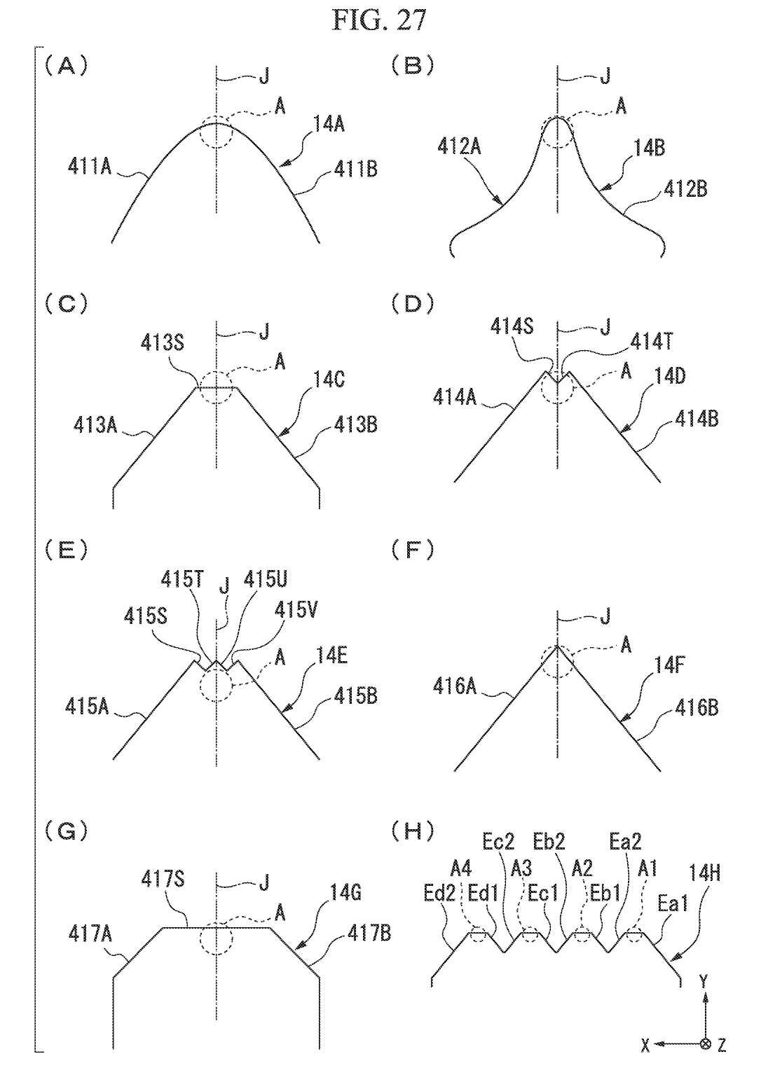

FIGS. 27(A) to 27(H) show examples of the outer shapes of the lower surfaces 14A to 14H of a first member. In addition, FIGS. 27(A) to 27(H) show portions of the lower surfaces 14A to 14H.

As shown in FIG. 27(A), the outer shape of the lower surface 14A may be an ellipse or a circle. The edge of the lower surface 14A includes a portion 411A that extends from the +X side of an axis J to a guide space A and a portion 411B that extends from the −X side of the axis J to the guide space A. The gap between the portion 411A and the portion 411B in the X-axis direction in the XY plane is reduced toward the guide space A. In this embodiment, at least a part of the portions 411A and 411B is bent.

The edge of the lower surface 14B shown in FIG. 27(B) includes a portion 412A that extends from the +X side of the axis J to the guide space A and a portion 41213 that extends from the −X side of the axis J to the guide space A. The gap between the portion 412A and the portion 412B in the X-axis direction in the XY plane is reduced toward the guide space A. In this embodiment, the portions 412A and 412E are bent inward in a concave shape.

The edge of the lower surface 14C shown in FIG. 27(C) includes a portion 413A that extends from the +X side of the axis J to the guide space A and a portion 413B that extends from the −X side of the axis J to the guide space A. The gap between the portion 413A and the portion 413B in the X-axis direction in the XY plane is reduced toward the guide space A. Each of the portion 413A and the portion 413B has a linear shape. The lower surface 14C includes an edge 413S that connects the leading end of the portion 413A and the leading end of the portion 413B. The edge 413S has a linear shape which is substantially parallel to the X axis.

The edge of the lower surface 14D shown in FIG. 27(D) includes a portion 414A that extends from the +X side of the axis J to the guide space A and a portion 414B that extends from the −X side of the axis Jr to the guide space A. The gap between the portion 414A and the portion 414B in the X-axis direction in the XY plane is reduced toward the guide space A. Each of the portion 414A and the portion 414B has a linear shape. The lower surface 14D includes edges 414S and 414T that connect the leading end of the portion 414A and the leading end of the portion 414B. The edge 414S and the edge 414T extend in different directions. The edge 414S and the edge 414T form a concave portion which is recessed with respect to the immersion space LS2.

The edge of the lower surface 14E shown in FIG. 27(E) includes a portion 415A and a portion 415B. In addition, the lower surface 14E includes edges 415S, 415T, 415U, and 415V that connect the leading end of the portion 415A and the leading end of the portion 415B. The edge 415S and the edge 415T form a first concave portion which is recessed with respect to the immersion space LS2 and the edge 415U and the edge 415V form a second concave portion.

The edge of the lower surface 14F shown in FIG. 27(F) includes a portion 416A that extends from the +X side of the axis J to the guide space A and a portion 41613 that extends from the −X side of the axis J to the guide space A. The gap between the portion 416A and the portion 416B in the X-axis direction in the XY plane is reduced toward the guide space A. Each of the portion 416A and the portion 416B has a linear shape. The angle formed between the portion 416A and the portion 416E is acute.

The edge of the lower surface 14G shown in FIG. 27(G) includes a portion 417A that extends from the +X side of the axis J to the guide space A and a portion 417B that extends from the −X side of the axis J to the guide space A. The gap between the portion 417A and the portion 417B in the X-axis direction in the XY plane is reduced toward the guide space A. In addition, the lower surface 14G includes an edge 4175 that connects the leading end of the portion 417A and the leading end of the portion 417B. The edge 4175 has a linear shape which is substantially parallel to the X axis.

The edge of the lower surface 14H shown in FIG. 27(H) includes portions Ea1 and Ea2 that extend to a first guide space A1, portions Eb1 and Eb2 that extend to a second guide space A2, portions Ec1 and Ec2 that extend to a third guide space A3, and portions Ed1 and Ed2 that extend to a fourth guide space A4.

### Seventeenth Embodiment

Next, a seventeenth embodiment will be described. In the following description, components which are the same as or similar to those in the above-described embodiments are denoted by the same reference numerals and a description thereof is abbreviated or omitted here.

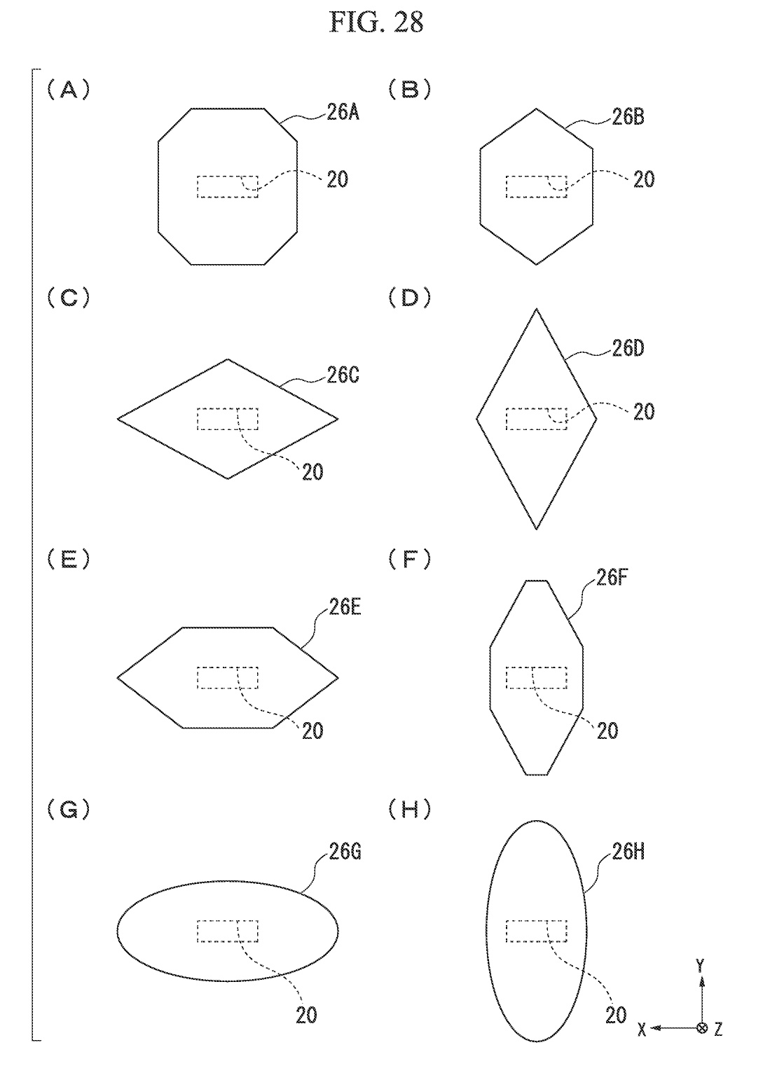

FIGS. 28(A) to 28(H) show lower surfaces 26A to 26H of a first member. As shown in FIG. 28(A), the outer shape of the lower surface 26A may be an octagon. As shown in FIG. 28(B), the outer shape of the lower surface 26B may be a hexagon. As shown in FIGS. 28(C) and 28(D), the outer shape of the lower surfaces 26C and 26D may be a diamond. The dimensions of the lower surface 26C shown in FIG. 28(C) in the X-axis direction are more than those of the lower surface 26C in the Y-axis direction. The dimensions of the lower surface 26D shown in FIG. 28(D) in the X-axis direction are less than those of the lower surface 26D in the Y-axis direction. As shown in FIG. 28(E), the outer shape of the lower surface 26E may be a hexagon that is long in the X-axis direction. As shown in FIG. 28(F), the outer shape of the lower surface 26F may be an octagon that is long in the Y-axis direction. As shown in FIGS. 28(G) and 28(H), the outer shape of the lower surfaces 26G and 26H may be an ellipse. The dimensions of the lower surface 26G shown in FIG. 28(G) in the X-axis direction are more than those of the lower surface 26G in the Y-axis direction. The dimensions of the lower surface 26H shown in FIG. 28(H) in the X-axis direction are less than those of the lower surface 2611 in the Y-axis direction.

### Eighteenth Embodiment

Next, an eighteenth embodiment will be described. In the following description, components which are the same as or similar to those in the above-described embodiments are denoted by the same reference numerals and a description thereof is abbreviated or omitted here.

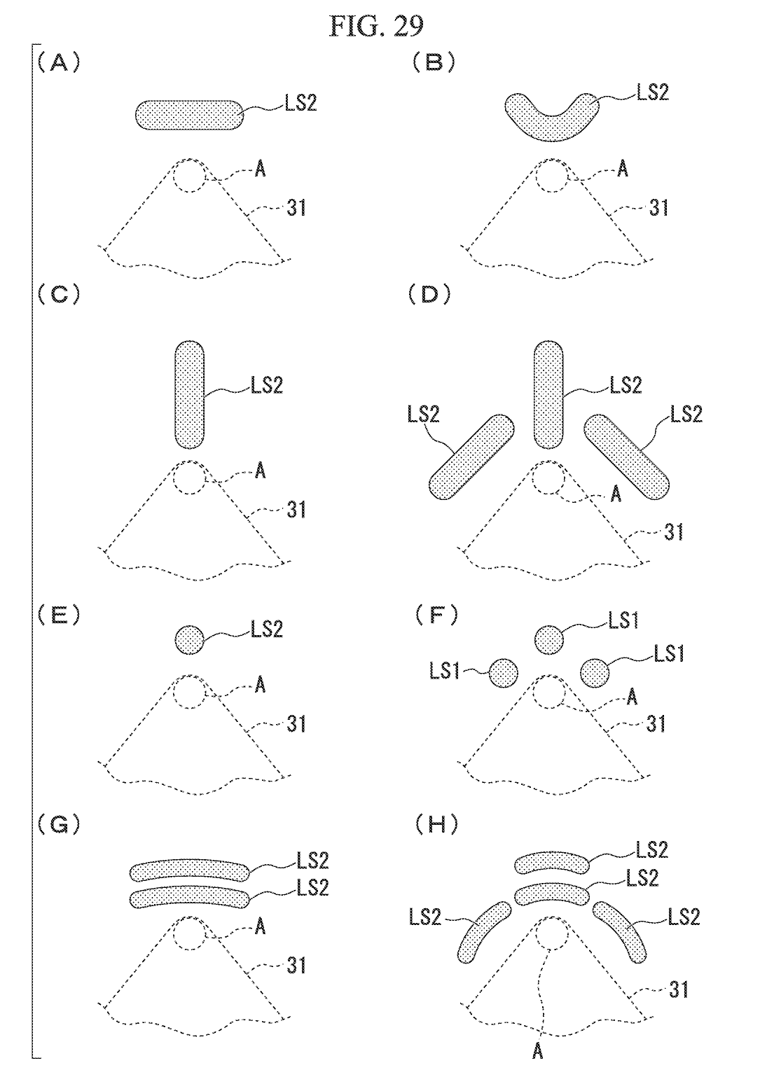

FIGS. 29(A) to 29(H) show examples of the shape of an immersion space LS2 in the XY plane. As shown in FIG. 29(A), the shape of the immersion space LS2 in the XY plane is a linear shape (strip shape) which extends in the Y-axis direction. As shown in FIG. 29(B), the immersion space LS2 may be arranged such that the center of the immersion space LS2 is closer to the first member 31 than both ends thereof in the XY plane. As shown in FIG. 29(C), the shape of the immersion space LS2 in the XY plane may be a linear shape (strip shape) that extends in the X-axis direction. As shown in FIG. 29(D), a plurality of immersion spaces LS2 may be arranged adjacent to a guide space A. In FIG. 29(D), each of the plurality of immersion spaces LS2 extends in a strip shape in the XY plane. As shown in FIG. 29(E), the shape of the immersion space LS2 in the XY plane may be a circle. As shown in FIG. 29(F), a plurality of circular immersion spaces LS2 in the XY plane are arranged adjacent to the guide space A. As shown in FIG. 29(G), a plurality of immersion spaces LS2 may be in a radiation direction for the optical path K. As shown in FIG. 29(H), a plurality of immersion spaces LS2 may be arranged in the radiation direction for the optical path K and a plurality of immersion spaces LS2 may be arranged in the circumferential direction of the optical path K.

The lower surface (for example, 14A to 14H) described with reference to FIG. 27, the lower surface (for example, 26A to 26H) described with reference to FIG. 28, and the immersion space LS2 described with reference to FIG. 29 may be appropriately combined with each other. For example, the lower surface 14A shown in FIG. 27(A), the lower surface 26B shown in FIG. 28(B), and the immersion space LS2 shown in FIG. 29(C) may be appropriately combined with each other.

In the above-described embodiment embodiments, at least a portion of the lower surface (for example, 15) of the second member (for example, 32) which is arranged outside the recovery port (for example, 52) in the radiation direction for the optical path K may repel the liquid LQ. For example, at least a portion of the lower surface (for example, 15) may be a liquid-repellant film. The liquid-repellant film may be, for example, a film including fluorine or a film including silicon. For example, the contact angle of the lower surface (for example, 15) with respect to the liquid LQ may be greater than 90 degrees, 100 degrees, or 110 degrees.

In the above-described embodiments, at least a portion of the lower surface (for example, 15) of the second member (for example, 32) between the supply port (for example, 50) and the recovery port (for example, 52) may be lyophilic to the liquid LQ. For example, at least a portion of the lower surface (for example, 15) may be a lyophilic film. For example, the contact angle of the lower surface (for example, 15) with respect to the liquid LQ may be smaller than 90 degrees, 80 degrees, or 70 degrees.

In the above-described embodiments, the kind of liquid in the immersion space LS2 is the same as that of liquid LQ in the immersion space LS1. However, different kinds of liquids may be used. For example, the liquid for forming the immersion space LS2 may have a higher viscosity than the liquid for forming the immersion space LS1. In addition, the liquid for forming the immersion space LS2 has a lower transmittance for the exposure light EL than the liquid for forming the immersion space LS1. The temperature of the liquid supplied form the supply port of the second member (for example, 32) may be different from the temperature of the liquid supplied from the supply port of the first member (for example, 31).

In the above-described embodiments, the liquid immersion member includes the guide portion 40. However, the liquid immersion member may also not include the guide portion 40.

In the above-described embodiments, the immersion space LS2 is formed in a portion of the space around the immersion space LS1. However, the immersion space LS2 may be formed around the immersion space LS1. In other words, the immersion space LS2 may be formed in an annular shape so as to surround the immersion space LS1. In this way, the immersion space LS2 can capture the liquid LQ flowing from the guide portion (for example, 40). In addition, even when the guide portion (for example, 40) is not provided, it is possible to capture the liquid LQ from the immersion space LS1 with the annular immersion space LS2.

In the above-described embodiments, at least a portion of the liquid supply device 27S, the liquid supply device 28S, and the liquid supply device 50S may be shared. For example, the liquid supply device 28S may supply the liquid LQ to all of the supply ports 27, 28, and 50. Alternatively, the liquid supply device 28S may supply the liquid LQ to the supply ports 27 and 28 and the liquid supply device 50S may supply the liquid Q to the supply port 50.

In the above-described embodiments, the “radiation direction for the optical path K” may be regarded as a radiation direction for the optical axis AX of the projection optical system PL in the vicinity of the projection region PR.

As described above, the controller 4 includes a computer system including, for example, a CPU. In addition, the controller 4 includes an interface which is capable of performing communication between the computer system and an external apparatus. The storage device 5 includes a memory (for example, a RAM), a hard disk, and a storage medium, such as a CD-ROM. An operating system (OS) that controls the computer system is installed and a program for controlling the exposure apparatus EX is stored in the storage device 5.

Furthermore, the controller 4 may be connected to an input apparatus that can input an input signal. The input apparatus includes input devices, such as a keyboard and a mouse, or a communication device which can input data from the external apparatus. In addition, a display device, such as a liquid crystal display, may be provided.

Various kinds of information including the program stored in the storage device 5 can be read by the controller 4 (computer system). The storage device 5 stores a program that causes the controller 4 to control an immersion exposure apparatus EX that exposes a substrate with the exposure light EL through a first liquid which is filled in the optical path of the exposure light between the substrate and the emission surface of an optical member which emits the exposure light.

According to the above-described embodiments, the program stored in the storage device 5 may cause the controller 4 to perform: forming a first immersion space of a first liquid in an optical path space on an emission surface side and at least a portion of a first space on a first lower surface side, using a first member that is provided in at least a portion of the periphery of an optical member such that the optical path of exposure light between the optical member and a substrate is filled with the first liquid and includes a first lower surface which can face the substrate facing an emission surface; exposing the substrate through the first liquid in the first immersion space; forming a second immersion space of a second liquid in at least a portion of a second space on a second lower surface side, using a second member that is provided outside the first member with respect to the optical path and includes a second lower surface which can face the substrate; and restricting the movement of the first liquid from the first space to the second immersion space.

According to the above-described embodiments, the program stored in the storage device 5 may cause the controller 4 to perform: forming a first immersion space of a first liquid in an optical path space on an emission surface side and at least a portion of a first space on a first lower surface side, using a first member that is provided in at least a portion of the periphery of an optical member such that the optical path of exposure light between the optical member and a substrate is filled with the first liquid and includes a first lower surface which can face the substrate facing the emission surface; exposing the substrate through the first liquid in the first immersion space; forming a second immersion space of a second liquid in at least a portion of a second space on a second lower surface side, using a second member that is provided outside the first member with respect to the optical path and includes a second lower surface which can face the substrate; and dividing the first liquid moved from the first space to the second immersion space using a third member.

According to the above-described embodiments, the program stored in the storage device 5 may cause the controller 4 to perform: forming a first immersion space of a first liquid in an optical path space on an emission surface side and at least a portion of a first space on a first lower surface side, using a first member that is provided in at least a portion of the periphery of an optical member such that the optical path of exposure light between the optical member and a substrate is filled with the first liquid and includes a first lower surface which can face the substrate facing the emission surface; exposing the substrate through the first liquid in the first immersion space; forming a second immersion space of a second liquid in at least a portion of a second space on a second lower surface side, using a second member that is provided outside the first member with respect to the optical path and includes a second lower surface which can face the substrate; and suctioning the first liquid moved from the first space to the second immersion space from a suction port of a third member.

According to the above-described embodiments, the program stored in the storage device 5 may cause the controller 4 to perform: forming a first immersion space of a first liquid in an optical path space on an emission surface side and at least a portion of a first space on a first lower surface side, using a first member that is provided in at least a portion of the periphery of an optical member such that the optical path of exposure light between the optical member and a substrate is filled with the first liquid and includes a first lower surface which can face the substrate facing the emission surface; exposing the substrate through the first liquid in the first immersion space; forming a second immersion space of a second liquid in at least a portion of a second space on a second lower surface side, using a second member that is provided outside the first member with respect to the optical path and includes a second lower surface which can face the substrate; and capturing the first liquid moved from the first space to the second immersion space using a third member.

According to the above-described embodiments, the program stored in the storage device 5 may cause the controller 4 to perform: forming a first immersion space of a first liquid in an optical path space on an emission surface side and at least a portion of a first space on a first lower surface side, using a first member that is provided in at least a portion of the periphery of an optical member such that the optical path of exposure light between the optical member and a substrate is filled with the first liquid and includes a first lower surface which can face the substrate facing the emission surface; exposing the substrate through the first liquid in the first immersion space; forming a second immersion space of a second liquid in at least a portion of a second space on a second lower surface side, using a second member that is provided outside the first member with respect to the optical path and includes a second lower surface which can face the substrate; and guiding the first liquid moved from the first space to the second immersion space using a guide member.

According to the above-described embodiments, the program stored in the storage device 5 may cause the controller 4 to perform: forming a first immersion space of a first liquid in an optical path space on an emission surface side and at least a portion of a first space on a first lower surface side, using a first member that is provided in at least a portion of the periphery of an optical member such that the optical path of exposure light between the optical member and a substrate is filled with the first liquid and includes a first lower surface which can face the substrate facing the emission surface; recovering the first liquid from a first recovering port that is provided in the first member so as to face an upper surface of the object; and exposing the substrate through the first liquid in the first immersion space. The first lower surface may include a first region that is provided in at least a portion of the periphery of the first recovery port and faces the upper surface of the object with a first gap therebetween and a second region that is provided outside the first region with respect to the first recovery port and faces the upper surface of the object with a second gap less than the first gap therebetween.

According to the above-described embodiments, the program stored in the storage device 5 may cause the controller 4 to perform: forming a first immersion space of a first liquid in an optical path space on an emission surface side and at least a portion of a first space on a first lower surface side, using a first member that is provided in at least a portion of the periphery of an optical member such that the optical path of exposure light between the optical member and a substrate is filled with the first liquid and includes a first lower surface which can face the substrate facing the emission surface; forming a second immersion space of a second liquid in at least a portion of a second space on a second lower surface side, using a second member that is provided outside the first member with respect to the optical path and includes a second lower surface which can face the substrate; recovering the first liquid and/or the second liquid from a second recovery port that is provided in the second member so as to face an upper surface of the object; and exposing the substrate through the first liquid in the first immersion space. The second lower surface may include a third region that is provided in at least a portion of a periphery of the second recovery port and faces the upper surface of the object with a third gap therebetween and a fourth region that is provided outside the third region with respect to the second recovery port and faces the upper surface of the object with a fourth gap less than the third gap therebetween.

When the program stored in the storage device 5 is read to the controller 4, various devices of the exposure apparatus EX, such as the substrate stage 2P, the measurement stage 2C, and the liquid immersion member 3 cooperate with each other to perform various kinds of processes, such as the immersion exposure of the substrate P, with the first immersion space LS1 being formed.

Furthermore, in the above-described embodiments, the optical path K on the side of the emission surface 7 (imaging surface) of the termination optical element 8 in the projection optical system PL is filled with the liquid LQ. However, the projection optical system PL may be a projection optical system in which the optical path K on the incident (object surface side) side of the termination optical element 8 is filled with the liquid LQ, as disclosed in, for example, the pamphlet of PCT International Publication No. WO2004/019128.

Furthermore, in the above-described embodiments, the liquid LQ is water. However, the liquid LQ may be a liquid other than water. It is preferable that the liquid LQ be transparent with respect to the exposure light EL, have a high refractive index with respect to the exposure light EL, and be stable with respect to the projection optical system PL or a film made of, for example, a photosensitive material (photoresist) that forms the surface of the substrate P. For example, the liquid LQ may be a fluorine-based liquid, such as hydro fluoro ether (HFE), perfluorinated polyether (PFPE), or Fomblin oil. In addition, the liquid LQ may be any of various kinds of fluids, such as, for example, a supercritical fluid.

In the above-described embodiments, the substrate P includes a semiconductor wafer for fabricating semiconductor devices. However, the substrate P may include, for example, a glass substrate for display devices, a ceramic wafer for thin film magnetic heads, or the original plate (synthetic quartz or a silicon wafer) of a mask or a reticle used by an exposure apparatus.

In the above-described embodiments, the exposure apparatus EX is a step-and-scan exposure apparatus (scanning stepper) in which the mask M and the substrate P are synchronously moved and the pattern of the mask M is scanned and exposed. However, the exposure apparatus EX may be, for example, a step-and-repeat projection exposure apparatus (stepper) which collectively expose the pattern of the mask M, with the mask M and the substrate P being stationary, and sequentially moves the substrate P in steps.

In addition, the exposure apparatus EX may be an exposure apparatus (a stitch-type one-shot exposure apparatus) which transfers a reduced image of a first pattern onto the substrate P using the projection optical system, with the first pattern and the substrate P being substantially stationary, and collectively exposes a reduced image of a second pattern onto the substrate P so as to partially overlap the first pattern, the second pattern and the substrate P being substantially stationary. In addition, the stitch-type exposure apparatus may be a step-and-stitch exposure apparatus that transfers at least two patterns onto the substrate P so as to partially overlap each other and sequentially moves the substrate P.

The exposure apparatus EX may be an exposure apparatus that combines the patterns of two masks on a substrate through a projection optical system and double exposes one shot region on the substrate substantially at the same time using one scanning exposure operation, as disclosed in, for example, the specification of U.S. Pat. No. 6,611,316. In addition, the exposure apparatus EX may be, for example, a proximity-type exposure apparatus or a mirror projection aligner.

In addition, the exposure apparatus EX may be a twin-stage exposure apparatus which includes a plurality of substrate stages, as disclosed in, for example, the specifications of U.S. Pat. Nos. 6,341,007, 6,208,407, and 6,262,796. For example, when the exposure apparatus EX includes two substrate stages, an object that can be arranged so as to face the emission surface 7 includes at least one of one (2P) of the two substrate stages, a substrate held by a substrate holding portion on the one substrate stage (2P), the other substrate stage (2P′), and a substrate held by a substrate holding portion on the other substrate stage (2P′).

The exposure apparatus EX may include a plurality of substrate stages and measurement stages.

The exposure apparatus EX may be a semiconductor device manufacturing exposure apparatus that exposes a semiconductor device pattern on the substrate P, an exposure apparatus for manufacturing, for example, liquid crystal display devices or displays, or an exposure apparatus for manufacturing thin-film magnetic heads, imaging devices (CCDs), micromachines, MEMS, DNA chips, or reticles or masks.

Furthermore, in the above-described embodiments, the light transmissive mask is used in which a predetermined light-shielding pattern (or a phase pattern or a dimming pattern) is formed on a light transmissive substrate. However, instead of the mask, a variable shaped mask (also called an electronic mask, an active mask, or an image generator) may be used which forms a transmissive pattern, a reflective pattern, or a light emission pattern on the basis of the electronic data of the pattern to be exposed, as disclosed in, for example, the specification of U.S. Pat. No. 6,778,257. In addition, instead of a variable shaped mask including a non-emission-type image display device, a pattern forming apparatus including a self-emitting image display device may be used.

In the above-described embodiments, the exposure apparatus EX includes the projection optical system PL. However, the components according to the above-described embodiments may be applied to an exposure apparatus and an exposure method that do not use the projection optical system PL. For example, the components according to the above-described embodiments may be applied to an exposure apparatus and an exposure method in which an immersion space is formed between a substrate and an optical member, such as a lens, and exposure light is emitted to the substrate through the optical member.

In addition, the exposure apparatus EX may be an exposure apparatus (lithographic system) that forms interference fringes on the substrate P and exposes a line-and-space pattern on the substrate P, as disclosed in, for example, the pamphlet of PCT International Publication No, WO2001/035168.

The exposure apparatus LX according to the above-described embodiments is manufactured by assembling various subsystems including each of the above-mentioned components so that predetermined mechanical, electrical, and optical accuracies are maintained. In order to ensure these various accuracies, adjustment for achieving optical accuracy for various optical systems, adjustment for achieving mechanical accuracy for various mechanical systems, and adjustment for achieving electrical accuracy for various electrical systems are performed before and after assembly. A process of assembling the exposure apparatus from each subsystem includes, for example, the connection of mechanical components, the wiring and connection of electric circuits, and the piping and connection of the pneumatic circuits among the various subsystems. Naturally, before the process of assembling the exposure apparatus from these various subsystems, there are also the processes of assembling each individual subsystem. After the process of assembling the exposure apparatus from the various subsystems is completed, overall adjustment is performed to ensure various kinds of accuracy of the entire exposure apparatus. Furthermore, it is preferable to manufacture the exposure apparatus in a clean room in which, for example, the temperature and the cleanliness level are controlled.

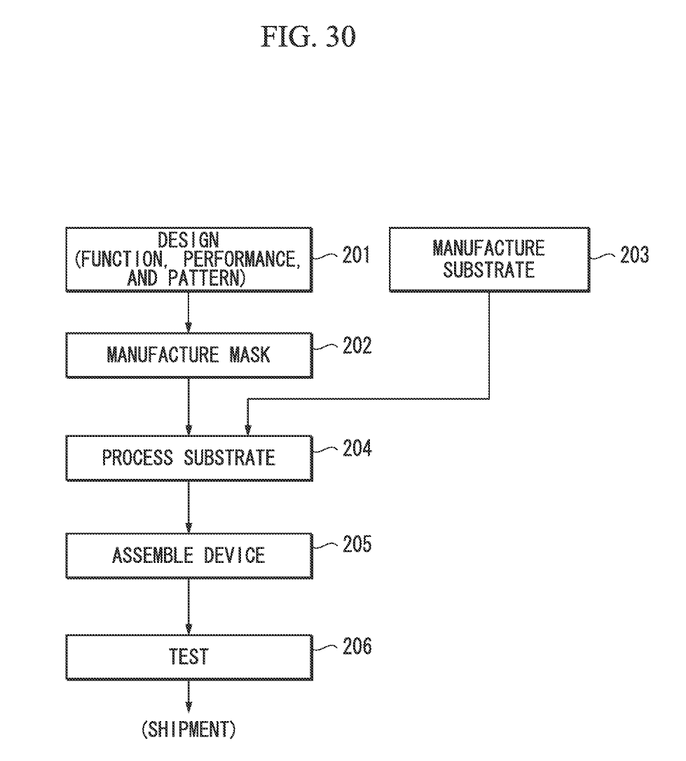

As shown in FIG. 30, a microdevice, such as a semiconductor device, is manufactured through, for example, a step 201 of designing the function and performance of the microdevice, a step 202 of manufacturing a mask (reticle) based on this design step, a step 203 of manufactures a substrate which is a base of the device, a substrate processing step 204 including substrate processing (exposure process) that includes exposing the substrate with exposure light emitted from the pattern of the mask and developing the exposed substrate, according to the above-described embodiments, and a device assembly step 205 (including fabrication processes, such as a dicing process, a bonding process, and a packaging processes), and a test step 206.

The requirements of the above-described embodiments may be appropriately combined with each other. In addition, in some cases, some components may also not be used. Furthermore, each disclosure of every Japanese unexamined patent application publication and United States patent related to the exposure apparatus recited in each of the above-described embodiments and the modifications is hereby incorporated by reference in its entirety to the extent permitted by the national laws and regulations.

1. A liquid immersion member that is provided in at least a portion of a surrounding of an optical member including an emission surface from which exposure light is emitted in an immersion exposure apparatus, the member comprising:
a first member that is provided in at least a portion of the surrounding of the optical member, that includes a first lower surface which can face an object facing the emission surface, and that forms a first immersion space of a first liquid in an optical path space on an emission surface side and at least a portion of a first space on a first lower surface side;
a second member that is provided outside the first member with respect to the optical path, that includes a second lower surface which can face the object, and that forms a second immersion space of a second liquid in at least a portion of a second space on a second lower surface side; and
a third member that restricts the movement of the first liquid from the first space to the second immersion space.

2. The liquid immersion member according to claim 1,
wherein the first liquid moved from the first space to the second immersion space is divided.

3. A liquid immersion member that is provided in at least a portion of a surrounding of an optical member including an emission surface from which exposure light is emitted in an immersion exposure apparatus, the member comprising:
a first member that is provided in at least a portion of the surrounding of the optical member, that includes a first lower surface which can face an object facing the emission surface, and that forms a first immersion space of a first liquid in an optical path space on an emission surface side and at least a portion of a first space on a first lower surface side;
a second member that is provided outside the first member with respect to the optical path, that includes a second lower surface which can face the object, and that forms a second immersion space of a second liquid in at least a portion of a second space on a second lower surface side; and
a third member that divides the first liquid moved from the first space to the second immersion space.

4. The liquid immersion member according to claim 1,
wherein the third member includes a suction port that suctions at least a portion of the first liquid.

5. A liquid immersion member that is provided in at least a portion of a surrounding of an optical member including an emission surface from which exposure light is emitted in an immersion exposure apparatus, the member comprising:
a first member that is provided in at least a portion of the surrounding of the optical member, that includes a first lower surface which can face an object facing the emission surface, and that forms a first immersion space of a first liquid in an optical path space on an emission surface side and at least a portion of a first space on a first lower surface side;
a second member that is provided outside the first member with respect to the optical path, that includes a second lower surface which can face the object, and that forms a second immersion space of a second liquid in at least a portion of a second space on a second lower surface side; and
a third member including a suction port that suctions the first liquid moved from the first space to the second immersion space.

6. The liquid immersion member according to claim 1,
wherein the third member is arranged between the first member and the second member so as to come into contact with the first liquid.

7. The liquid immersion member according to claim 1,
wherein the third member captures the first liquid.

8. A liquid immersion member that is provided in at least a portion of a surrounding of an optical member including an emission surface from which exposure light is emitted in an immersion exposure apparatus, the member comprising:
a first member that is provided in at least a portion of the surrounding of the optical member, that includes a first lower surface which can face an object facing the emission surface, and that forms a first immersion space of a first liquid in an optical path space on an emission surface side and at least a portion of a first space on a first lower surface side;
a second member that is provided outside the first member with respect to the optical path, that includes a second lower surface which can face the object, and that forms a second immersion space of a second liquid in at least a portion of a second space on a second lower surface side; and
a third member that captures the first liquid moved from the first space to the second immersion space.

9. The liquid immersion member according to claim 1,
wherein a third lower surface of the third member is arranged so as to be closer to the object than the first lower surface.

10. The liquid immersion member according to claim 1,
wherein the third member includes a porous member.

11. The liquid immersion member according to claim 1,
wherein at least a portion of the third member repels the first liquid.

12. The liquid immersion member according to claim 1,
wherein the third member includes a guide member that guides the first liquid from the first space to the second immersion space.

13. A liquid immersion member that is provided in at least a portion of a surrounding of an optical member including an emission surface from which exposure light is emitted in an immersion exposure apparatus, the member comprising:
a first member that is provided in at least a portion of the surrounding of the optical member, that includes a first lower surface which can face an object facing the emission surface, and that forms a first immersion space of a first liquid in an optical path space on an emission surface side and at least a portion of a first space on a first lower surface side;
a second member that is provided outside the first member with respect to the optical path, that includes a second lower surface which can face the object, and that forms a second immersion space of a second liquid in at least a portion of a second space on a second lower surface side; and
a guide member that guides the first liquid from the first space to the second immersion space.

14. The liquid immersion member according to claim 12,
wherein the guide member is arranged between the first member and the second member so as to come into contact with the first liquid.

15. The liquid immersion member according to claim 12,
wherein a lower surface of the guide member is arranged so as to be closer to the object than the first lower surface.

16. The liquid immersion member according to claim 12,
wherein the guide member includes a porous member.

17. The liquid immersion member according to claim 12,
wherein at least a portion of a surface of the guide member repels the first liquid.

18. The liquid immersion member according to claim 1,
wherein the first immersion space is formed in at least a portion of the first space so as to be substantially separated from the second immersion space.

19. The liquid immersion member according to claim 1, further comprising:
a guide portion that guides at least a portion of the first liquid in the first immersion space to a guide space which is provided in a portion of the surrounding of the optical path,
wherein the at least a portion of the first liquid in the first immersion space is moved to the second immersion space through the guide space.

20. The liquid immersion member according to claim 19,
wherein at least a part of the guide portion is arranged in the first member.

21. The liquid immersion member according to claim 1, further comprising:
a first recovery port that is provided in the first member so as to face an upper surface of the object and that recovers the first liquid,
wherein the first lower surface includes a first region that is provided in at least a portion of a surrounding of the first recovery port and that faces the upper surface of the object with a first gap therebetween and a second region that is provided outside the first region with respect to the first recovery port and that faces the upper surface of the object with a second gap less than the first gap therebetween.

22. A liquid immersion member that is provided in at least a portion of a surrounding of an optical member including an emission surface from which exposure light is emitted in an immersion exposure apparatus, the member comprising:
a first member that is provided in at least a portion of the surrounding of the optical member, that includes a first lower surface which can face an object facing the emission surface, and that forms a first immersion space of a first liquid in an optical path space on an emission surface side and at least a portion of a first space on a first lower surface side; and
a first recovery port that is provided in the first member so as to face an upper surface of the object and that recovers the first liquid,
wherein the first lower surface includes a first region that is provided in at least a portion of a surrounding of the first recovery port and that faces the upper surface of the object with a first gap therebetween and a second region that is provided outside the first region with respect to the first recovery port and that faces the upper surface of the object with a second gap less than the first gap therebetween.

23. The liquid immersion member according to claim 22, further comprising:
a second member that is provided outside the first member with respect to the optical path, that includes a second lower surface which can face the object, and that forms a second immersion space of a second liquid in at least a portion of a second space on a second lower surface side; and
a second recovery port that is provided in the second member so as to face the upper surface of the object and that recovers the first liquid and/or the second liquid,
wherein the second lower surface includes a third region that is provided in at least a portion of a surrounding of the second recovery port and that faces the upper surface of the object with a third gap therebetween and a fourth region that is provided outside the third region with respect to the second recovery port and that faces the upper surface of the object with a fourth gap less than the third gap therebetween.

24. The liquid immersion member according to any claim 1, further comprising:
a second recovery port that is provided in the second member so as to face the upper surface of the object and recovers the first liquid and/or the second liquid,
wherein the second lower surface includes a third region that is provided in at least a portion of a surrounding of the second recovery port and that faces the upper surface of the object with a third gap therebetween and a fourth region that is provided outside the third region with respect to the second recovery port and that faces the upper surface of the object with a fourth gap less than the third gap therebetween.

25. A liquid immersion member that is provided in at least a portion of a surrounding of an optical member including an emission surface from which exposure light is emitted in an immersion exposure apparatus, the member comprising:
a first member that is provided in at least a portion of the surrounding of the optical member, that includes a first lower surface which can face an object facing the emission surface, and that forms a first immersion space of a first liquid in an optical path space on an emission surface side and at least a portion of a first space on a first lower surface side;
a second member that is provided outside the first member with respect to the optical path, that includes a second lower surface which can face the object, and that forms a second immersion space of a second liquid in at least a portion of a second space on a second lower surface side; and
a second recovery port that is provided in the second member so as to face an upper surface of the object and that recovers the first liquid and/or the second liquid,
wherein the second lower surface includes a third region that is provided in at least a portion of a surrounding of the second recovery port and that faces the upper surface of the object with a third gap therebetween and a fourth region that is provided outside the third region with respect to the second recovery port and that faces the upper surface of the object with a fourth gap less than the third gap therebetween.

26. The liquid immersion member according to claim 23,
wherein the second recovery port recovers the first liquid moved from the first space and the second liquid in the second immersion space.

27. The liquid immersion member according to claim 1,
wherein the second member includes a second recovery port that recovers the second liquid, and
the second recovery port recovers the first liquid moved from the first space and the second liquid in the second immersion space.

28. The liquid immersion member according to claim 1,
wherein the first lower surface includes a recovery surface including a first recovery port that recovers the first liquid and an inclined plane that is provided outside the recovery surface with respect to the optical path so as to face the first space and is inclined upward to the outside in a radiation direction for the optical path.

29. The liquid immersion member according to claim 28,
wherein the inclined plane repels the first liquid.

30. The liquid immersion member according claim 28, further comprising:
a third recovery port that is provided in the inclined plane and can recover the first liquid.

31. The liquid immersion member according to claim 30,
wherein the recovery surface includes a lower surface of a first porous member including a plurality of the first recovery ports, and
the inclined plane includes a lower surface of a second porous member including a plurality of the third recovery ports.

32. The liquid immersion member according to claim 31,
wherein the first porous member and the second porous member are integrated with each other.

33. The liquid immersion member according to claim 1,
wherein the first member includes a first outer surface which is connected to an outer edge of the first lower surface and that faces at least a portion of the second member, and
the first recovery port which can recover the first liquid is provided in an outer edge region including at least the outer edge of the first lower surface.

34. The liquid immersion member according to claim 33,
wherein the first member includes a first porous member and a second porous member that is connected to an outer edge region of a lower surface of the first porous member, and
the first recovery port provided in the outer edge region includes a hole of the second porous member.

35. The liquid immersion member according to claim 34,
wherein the first member includes a first porous member and a second porous member at least a portion of which is connected to an outer edge region of an upper surface of the first porous member, and
the first recovery port provided in the outer edge region of the first lower surface includes a hole of the second porous member which is provided outside the outer edge of the first porous member.

36. The liquid immersion member according to claim 34,
wherein the first porous member and at least a portion of the second porous member are welded to each other.

37. The liquid immersion member according to claim 33,
wherein the first recovery port is provided in at least a portion of the first outer surface.

38. An immersion exposure apparatus that exposes a substrate with exposure light through a first liquid, the apparatus comprising:
the liquid immersion member according to claim 1.

39. A device manufacturing method comprising:
exposing a substrate using the immersion exposure apparatus according to claim 38; and
developing the exposed substrate.

40. An exposure method that exposes a substrate with exposure light through a first liquid which is filled in an optical path of the exposure light between the substrate and an emission surface of an optical member from which the exposure light is emitted in an immersion exposure apparatus, the method comprising:
forming a first immersion space of a first liquid in an optical path space on an emission surface side and at least a portion of a first space on a first lower surface side, using a first member that is provided in at least a portion of a surrounding of the optical member such that the optical path of the exposure light between the optical member and the substrate is filled with the first liquid and that includes a first lower surface which can face the substrate facing the emission surface;
exposing the substrate through the first liquid in the first immersion space;
forming a second immersion space of a second liquid in at least a portion of a second space on a second lower surface side, using a second member that is provided outside the first member with respect to the optical path and that includes a second lower surface which can face the substrate; and
restricting the movement of the first liquid from the first space to the second immersion space.

41. An exposure method that exposes a substrate with exposure light through a first liquid which is filled in an optical path of the exposure light between the substrate and an emission surface of an optical member from which the exposure light is emitted in an immersion exposure apparatus, the method comprising:
forming a first immersion space of a first liquid in an optical path space on an emission surface side and at least a portion of a first space on a first lower surface side, using a first member that is provided in at least a portion of a surrounding of the optical member such that the optical path of the exposure light between the optical member and the substrate is filled with the first liquid and that includes a first lower surface which can face the substrate facing the emission surface;
exposing the substrate through the first liquid in the first immersion space;
forming a second immersion space of a second liquid in at least a portion of a second space on a second lower surface side, using a second member that is provided outside the first member with respect to the optical path and that includes a second lower surface which can face the substrate; and
dividing the first liquid moved from the first space to the second immersion space using a third member.

42. An exposure method that exposes a substrate with exposure light through a first liquid which is filled in an optical path of the exposure light between the substrate and an emission surface of an optical member from which the exposure light is emitted in an immersion exposure apparatus, the method comprising:
forming a first immersion space of a first liquid in an optical path space on an emission surface side and at least a portion of a first space on a first lower surface side, using a first member that is provided in at least a portion of a surrounding of the optical member such that the optical path of the exposure light between the optical member and the substrate is filled with the first liquid and that includes a first lower surface which can face the substrate facing the emission surface;
exposing the substrate through the first liquid in the first immersion space;
forming a second immersion space of a second liquid in at least a portion of a second space on a second lower surface side, using a second member that is provided outside the first member with respect to the optical path and that includes a second lower surface which can face the substrate; and
suctioning the first liquid moved from the first space to the second immersion space from a suction port of a third member.

43. An exposure method that exposes a substrate with exposure light through a first liquid which is filled in an optical path of the exposure light between the substrate and an emission surface of an optical member from which the exposure light is emitted in an immersion exposure apparatus, the method comprising:
forming a first immersion space of a first liquid in an optical path space on an emission surface side and at least a portion of a first space on a first lower surface side, using a first member that is provided in at least a portion of a surrounding of the optical member such that the optical path of the exposure light between the optical member and the substrate is filled with the first liquid and that includes a first lower surface which can face the substrate facing the emission surface;
exposing the substrate through the first liquid in the first immersion space;
forming a second immersion space of a second liquid in at least a portion of a second space on a second lower surface side, using a second member that is provided outside the first member with respect to the optical path and that includes a second lower surface which can face the substrate; and
capturing the first liquid moved from the first space to the second immersion space using a third member.

44. An exposure method that exposes a substrate with exposure light through a first liquid which is filled in an optical path of the exposure light between the substrate and an emission surface of an optical member from which the exposure light is emitted in an immersion exposure apparatus, the method comprising:
forming a first immersion space of a first liquid in an optical path space on an emission surface side and at least a portion of a first space on a first lower surface side, using a first member that is provided in at least a portion of a surrounding of the optical member such that the optical path of the exposure light between the optical member and the substrate is filled with the first liquid and that includes a first lower surface which can face the substrate facing the emission surface;
exposing the substrate through the first liquid in the first immersion space;
forming a second immersion space of a second liquid in at least a portion of a second space on a second lower surface side, using a second member that is provided outside the first member with respect to the optical path and that includes a second lower surface which can face the substrate; and
guiding the first liquid moved from the first space to the second immersion space using a guide member.

45. An exposure method that exposes a substrate with exposure light through a first liquid which is filled in an optical path of the exposure light between the substrate and an emission surface of an optical member from which the exposure light is emitted in an immersion exposure apparatus, the method comprising:
forming a first immersion space of a first liquid in an optical path space on an emission surface side and at least a portion of a first space on a first lower surface side, using a first member that is provided in at least a portion of a surrounding of the optical member such that the optical path of the exposure light between the optical member and the substrate is filled with the first liquid and that includes a first lower surface which can face the substrate facing the emission surface;
recovering the first liquid from a first recovery port that is provided in the first member so as to face an upper surface of the object; and
exposing the substrate through the first liquid in the first immersion space,
wherein the first lower surface includes a first region that is provided in at least a portion of a surrounding of the first recovery port and that faces the upper surface of the object with a first gap therebetween and a second region that is provided outside the first region with respect to the first recovery port and that faces the upper surface of the object with a second gap less than the first gap therebetween.

46. An exposure method that exposes a substrate with exposure light through a first liquid which is filled in an optical path of the exposure light between the substrate and an emission surface of an optical member from which the exposure light is emitted in an immersion exposure apparatus, the method comprising:
forming a first immersion space of a first liquid in an optical path space on an emission surface side and at least a portion of a first space on a first lower surface side, using a first member that is provided in at least a portion of a surrounding of the optical member such that the optical path of the exposure light between the optical member and the substrate is filled with the first liquid and that includes a first lower surface which can face the substrate facing the emission surface;
forming a second immersion space of a second liquid in at least a portion of a second space on a second lower surface side, using a second member that is provided outside the first member with respect to the optical path and that includes a second lower surface which can face the substrate;
recovering the first liquid and/or the second liquid from a second recovery port that is provided in the second member so as to face an upper surface of the object; and
exposing the substrate through the first liquid in the first immersion space,
wherein the second lower surface includes a third region that is provided in at least a portion of a surrounding of the second recovery port and that faces the upper surface of the object with a third gap therebetween and a fourth region that is provided outside the third region with respect to the second recovery port and that faces the upper surface of the object with a fourth gap less than the third gap therebetween.

47. A device manufacturing method comprising:
exposing a substrate using the exposure method according to claim 41; and
developing the exposed substrate.

48. A program that causes a computer to control an immersion exposure apparatus that exposes a substrate with exposure light through a first liquid which is filled in an optical path of the exposure light between the substrate and an emission surface of an optical member from which the exposure light is emitted and to perform:
forming a first immersion space of a first liquid in an optical path space on an emission surface side and at least a portion of a first space on a first lower surface side, using a first member that is provided in at least a portion of a surrounding of the optical member such that the optical path of the exposure light between the optical member and the substrate is filled with the first liquid and that includes a first lower surface which can face the substrate facing the emission surface;
exposing the substrate through the first liquid in the first immersion space;
forming a second immersion space of a second liquid in at least a portion of a second space on a second lower surface side, using a second member that is provided outside the first member with respect to the optical path and that includes a second lower surface which can face the substrate; and
restricting the movement of the first liquid from the first space to the second immersion space.

49. A program that causes a computer to control an immersion exposure apparatus that exposes a substrate with exposure light through a first liquid which is filled in an optical path of the exposure light between the substrate and an emission surface of an optical member from which the exposure light is emitted and to perform:
forming a first immersion space of a first liquid in an optical path space on an emission surface side and at least a portion of a first space on a first lower surface side, using a first member that is provided in at least a portion of a surrounding of the optical member such that the optical path of the exposure light between the optical member and the substrate is filled with the first liquid and that includes a first lower surface which can face the substrate facing the emission surface;
exposing the substrate through the first liquid in the first immersion space;
forming a second immersion space of a second liquid in at least a portion of a second space on a second lower surface side, using a second member that is provided outside the first member with respect to the optical path and that includes a second lower surface which can face the substrate; and
dividing the first liquid moved from the first space to the second immersion space using a third member.

50. A program that causes a computer to control an immersion exposure apparatus that exposes a substrate with exposure light through a first liquid which is filled in an optical path of the exposure light between the substrate and an emission surface of an optical member from which the exposure light is emitted and to perform:
forming a first immersion space of a first liquid in an optical path space on an emission surface side and at least a portion of a first space on a first lower surface side, using a first member that is provided in at least a portion of a surrounding of the optical member such that the optical path of the exposure light between the optical member and the substrate is filled with the first liquid and that includes a first lower surface which can face the substrate facing the emission surface;
exposing the substrate through the first liquid in the first immersion space;
forming a second immersion space of a second liquid in at least a portion of a second space on a second lower surface side, using a second member that is provided outside the first member with respect to the optical path and that includes a second lower surface which can face the substrate; and
suctioning the first liquid moved from the first space to the second immersion space from a suction port of a third member.

51. A program that causes a computer to control an immersion exposure apparatus that exposes a substrate with exposure light through a first liquid which is filled in an optical path of the exposure light between the substrate and an emission surface of an optical member from which the exposure light is emitted and to perform:
forming a first immersion space of a first liquid in an optical path space on an emission surface side and at least a portion of a first space on a first lower surface side, using a first member that is provided in at least a portion of a surrounding of the optical member such that the optical path of the exposure light between the optical member and the substrate is filled with the first liquid and that includes a first lower surface which can face the substrate facing the emission surface;
exposing the substrate through the first liquid in the first immersion space;
forming a second immersion space of a second liquid in at least a portion of a second space on a second lower surface side, using a second member that is provided outside the first member with respect to the optical path and that includes a second lower surface which can face the substrate; and
capturing the first liquid moved from the first space to the second immersion space using a third member.

52. A program that causes a computer to control an immersion exposure apparatus that exposes a substrate with exposure light through a first liquid which is filled in an optical path of the exposure light between the substrate and an emission surface of an optical member from which the exposure light is emitted and to perform:
forming a first immersion space of a first liquid in an optical path space on an emission surface side and at least a portion of a first space on a first lower surface side, using a first member that is provided in at least a portion of a surrounding of the optical member such that the optical path of the exposure light between the optical member and the substrate is filled with the first liquid and that includes a first lower surface which can face the substrate facing the emission surface;
exposing the substrate through the first liquid in the first immersion space;
forming a second immersion space of a second liquid in at least a portion of a second space on a second lower surface side, using a second member that is provided outside the first member with respect to the optical path and that includes a second lower surface which can face the substrate; and
guiding the first liquid moved from the first space to the second immersion space using a guide member.

53. A program that causes a computer to control an immersion exposure apparatus that exposes a substrate with exposure light through a first liquid which is filled in an optical path of the exposure light between the substrate and an emission surface of an optical member from which the exposure light is emitted and to perform:
forming a first immersion space of a first liquid in an optical path space on an emission surface side and at least a portion of a first space on a first lower surface side, using a first member that is provided in at least a portion of a surrounding of the optical member such that the optical path of the exposure light between the optical member and the substrate is filled with the first liquid and that includes a first lower surface which can face the substrate facing the emission surface;
recovering the first liquid from a first recovery port that is provided in the first member so as to face an upper surface of the object; and
exposing the substrate through the first liquid in the first immersion space,
wherein the first lower surface includes a first region that is provided in at least a portion of a surrounding of the first recovery port and faces the upper surface of the object with a first gap therebetween and a second region that is provided outside the first region with respect to the first recovery port and that faces the upper surface of the object with a second gap less than the first gap therebetween.

54. A program that causes a computer to control an immersion exposure apparatus that exposes a substrate with exposure light through a first liquid which is filled in an optical path of the exposure light between the substrate and an emission surface of an optical member from which the exposure light is emitted and to perform:
forming a first immersion space of a first liquid in an optical path space on an emission surface side and at least a portion of a first space on a first lower surface side, using a first member that is provided in at least a portion of a surrounding of the optical member such that the optical path of the exposure light between the optical member and the substrate is filled with the first liquid and that includes a first lower surface which can face the substrate facing the emission surface;
forming a second immersion space of a second liquid in at least a portion of a second space on a second lower surface side, using a second member that is provided outside the first member with respect to the optical path and that includes a second lower surface which can face the substrate;
recovering the first liquid and/or the second liquid from a second recovery port that is provided in the second member so as to face an upper surface of the object; and
exposing the substrate through the first liquid in the first immersion space,
wherein the second lower surface includes a third region that is provided in at least a portion of a surrounding of the second recovery port and that faces the upper surface of the object with a third gap therebetween and a fourth region that is provided outside the third region with respect to the second recovery port and that faces the upper surface of the object with a fourth gap less than the third gap therebetween.

55. A computer readable recording medium that stores the program according to claim 49.
